(19) United States
(12) Patent Application Publication
(10) Pub. No.: US 2025/0040118 A1
(43) Pub. Date: Jan. 30, 2025

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Jeong Hoon KWON, Gyeonggi-do (KR)

(21) Appl. No.: 18/782,030

(22) Filed: Jul. 24, 2024

(30) Foreign Application Priority Data
Jul. 25, 2023 (KR) 10-2023-0096907
Jul. 23, 2024 (KR) 10-2024-0097113

(51) Int. Cl. H10B 12/00

(52) U.S. Cl. CPC H10B 12/03; H10B 12/30

(57) ABSTRACT

A method for fabricating a semiconductor device including high-integrated memory cells may include forming a cell mold in which a plurality of mold layers are stacked, over a lower structure; forming a line-shape vertical opening in the cell mold, which is vertically oriented in a stack direction of the cell mold; forming a storage opening that horizontally extends from the line-shape vertical opening; and forming a data storage element in the storage opening.

### CROSS-REFERENCE TO RELATED APPLICATIONS

The present application claims priority under 35 U.S.C 119 (a) to Korean Patent Application No. 10-2023-0096907 and No. 10-2024-0097113, respectively filed on Jul. 25, 2023 and Jul. 23, 2024, which are incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to cope with the large capacity and miniaturization of a memory device, a technology has been proposed to provide a 3D memory device in which a plurality of memory cells are stacked.

### SUMMARY

Embodiments of the present disclosure are directed to a semiconductor device including highly integrated memory cells, and a method for fabricating the semiconductor device.

In accordance with an embodiment of the present disclosure, a method for fabricating a semiconductor device may include forming a cell mold in which a plurality of mold layers are stacked, over a lower structure; forming a line-shape vertical opening in the cell mold, which is vertically oriented in a stack direction of the cell mold; forming a storage opening that horizontally extends from the line-shape vertical opening; and forming a data storage element in the storage opening.

In accordance with an embodiment of the present disclosure, a method for fabricating a semiconductor device may include forming a cell mold in which a first sacrificial layer, a semiconductor layer and a second sacrificial layer are sequentially stacked, over a lower structure; forming a line-shape vertical opening, which is vertically oriented in a stack direction of the cell mold, by removing a first part of the cell mold; forming a hole-shape vertical opening, which is vertically oriented in the stack direction of the cell mold, by removing a second part of the cell mold; forming a switching element that is horizontally oriented from the hole-shape vertical opening; forming a vertical conducive line coupled to the switching element in the hole-shape vertical opening; forming a storage opening that horizontally extends from the line-shape vertical opening; and forming a data storage element in the storage opening.

In accordance with an embodiment of the present disclosure, a method for fabricating a three-dimensional (3D) capacitor may include forming a mold in which first silicon nitride, a semiconductor layer and second silicon nitride are sequentially stacked over a lower structure; forming cell isolation layers, which are vertically oriented in a stack direction of the mold, in the mold; forming a line-shape vertical opening that is vertically oriented in the stack direction of the mold, by removing a part of the mold and parts of the cell isolation layers; forming a storage opening by horizontally recessing the first silicon nitride, the semiconductor layer and the second silicon nitride from the line-shape vertical opening; forming a first electrode in the storage opening; forming a dielectric layer on the first electrode; and forming a second electrode on the dielectric layer.

In accordance with an embodiment of the present disclosure, a method for fabricating a semiconductor device may include forming a cell mold including a horizontal layer over a lower structure; forming first cell isolation layers and second cell isolation layers in the cell mold; forming a first line-shape vertical opening disposed between the second cell isolation layers by etching a first part of the cell mold; forming a horizontal conductive line horizontally spaced apart from the first line-shape vertical opening and overlapping with the horizontal layer; forming a vertical extension portion by cutting a part of the horizontal layer from the first line-shape vertical opening; and forming a vertical conductive line coupled to one side surface of the horizontal layer in the vertical extension portion and self-aligned with one side surfaces of the second cell isolation layers. The method further comprising: forming a second line-shape vertical opening disposed between the first cell isolation layers by removing a second part of the cell mold; forming a storage opening horizontally extending from the second line-shape vertical opening and exposing the other side surface of the horizontal layer; and forming a data storage element coupled to the other side surface of the horizontal layer in the storage opening, after forming the vertical conductive line. The cell mold includes a first sacrificial layer and a second sacrificial layer, which are vertically disposed with the horizontal layer interposed therebetween, and forming the horizontal conductive line includes replacing a part of the first sacrificial layer and a part of the second sacrificial layer with the horizontal conductive line from the first line-shape vertical opening. The second cell isolation layers include two second cell isolation segments, and the first line-shape vertical opening is formed between the second cell isolation segments. The first cell isolation layers include two first cell isolation segments.

In accordance with an embodiment of the present disclosure, a method for fabricating a semiconductor device may include forming a cell mold including a horizontal layer over a lower structure; forming first cell isolation layers and second cell isolation layers in the cell mold; forming a first line-shape vertical opening disposed between the second cell isolation layers by etching a first part of the cell mold; forming a horizontal conductive line horizontally spaced apart from the first line-shape vertical opening and overlapping with the horizontal layer; and forming a vertical conductive line coupled in common to horizontally neighboring horizontal layers with the first line-shape vertical opening interposed therebetween. The method further comprising: forming a second line-shape vertical opening disposed between the first cell isolation layers by removing a second part of the cell mold; forming a storage opening horizontally extending from the second line-shape vertical opening and exposing the other side surface of the horizontal layer; and forming a data storage element coupled to the other side surface of the horizontal layer in the storage opening, after forming the vertical conductive line. The second cell isolation layers include two second cell isolation segments, and the first line-shape vertical opening is formed between the second cell isolation segments. The first cell isolation layers include two first cell isolation segments. The cell mold includes a first sacrificial layer and a second sacrificial layer, which are vertically disposed with the horizontal layer interposed therebetween, and wherein forming the horizontal conductive line includes replacing a part of the first sacrificial layer and a part of the second sacrificial layer with the horizontal conductive layer from the first line-shape vertical opening.

In accordance with an embodiment of the present disclosure, a semiconductor device may include a horizontal layer disposed over a lower structure and having a first edge and a second edge; first cell isolation layers disposed on a periphery of the second edge of the horizontal layer and vertically extending from the lower structure; second cell isolation layers disposed on a periphery of the first edge of the horizontal layer and vertically extending from the lower structure; a vertical conductive line coupled to the first edge of the horizontal layer and self-aligned with one side surfaces of the second cell isolation layers; and a data storage element coupled to the second edge of the horizontal layer and disposed between the first cell isolation layers.

These and other features and advantages of the present invention will become apparent to those skilled in the art of the disclosure from the following detailed description in conjunction with the following drawings.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view illustrating the memory cell illustrated in FIG. 1A.

FIG. 1C is a plan view illustrating a switching element illustrated in FIG. 1A.

FIG. 1D is a schematic cross-sectional view illustrating a memory cell in accordance with an embodiment of the present disclosure.

FIG. 2 is a schematic plan view illustrating a semiconductor device in accordance with an embodiment of the present disclosure.

FIG. 3A is a schematic perspective view illustrating a memory cell array illustrated in FIG. 2.

FIG. 3B is a schematic cross-sectional view illustrating the memory cell array illustrated in FIG. 2.

FIGS. 4A to 26B illustrate various views of a semiconductor device formed according to a method for fabricating the semiconductor device in accordance with an embodiment of the present disclosure.

FIGS. 27A and 27B illustrate various views of a semiconductor device formed according to a method for fabricating the semiconductor device in accordance with an embodiment of the present disclosure.

FIG. 28A is a schematic plan view illustrating a semiconductor device in accordance with an embodiment of the present invention disclosure.

FIG. 28B is a cross-sectional view illustrating the semiconductor device taken along line A-A′ illustrated in FIG. 28A.

FIGS. 28C and 28E are views for describing electrical connection of a first vertical conductive line and a second vertical conductive line.

FIG. 28F is a view for describing an isolation structure of the first vertical conductive line and the second vertical conductive line.

FIGS. 29A to 46B illustrate various views of a semiconductor device formed according to a method for fabricating the semiconductor device in accordance with an embodiment of the present disclosure.

FIGS. 47A to 47C illustrate various views of a semiconductor device formed according to a method for fabricating the semiconductor device in accordance with an embodiment of the present disclosure.

FIG. 48 is a schematic plan view illustrating a semiconductor device in accordance with an embodiment of the present disclosure.

FIGS. 49A and 49B illustrate various views of a semiconductor device formed according to a method for fabricating the semiconductor device in accordance with an embodiment of the present disclosure.

FIG. 50A is a schematic plan view illustrating a semiconductor device in accordance with an embodiment of the present disclosure.

FIG. 50B is a cross-sectional view illustrating the semiconductor device taken along line A-A′ illustrated in FIG. 50A.

FIG. 50C is a schematic perspective view illustrating the semiconductor device illustrated in FIG. 50A.

FIG. 51A is a schematic plan view illustrating a semiconductor device in accordance with an embodiment of the present disclosure.

FIG. 51B is a cross-sectional view illustrating the semiconductor device taken along line A-A′ illustrated in FIG. 51A.

FIG. 51C is a schematic perspective view illustrating the semiconductor device illustrated in FIG. 51A.

FIG. 52A is a schematic plan view illustrating a semiconductor device in accordance with an embodiment of the present disclosure.

FIG. 52B is a cross-sectional view illustrating the semiconductor device taken along line A-A′ illustrated in FIG. 52A.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the embodiments of the present disclosure.

Embodiments described below relate to three-dimensional (3D) memory cells, and memory cells vertically stacked for increasing memory cell density and reducing parasitic capacitance.

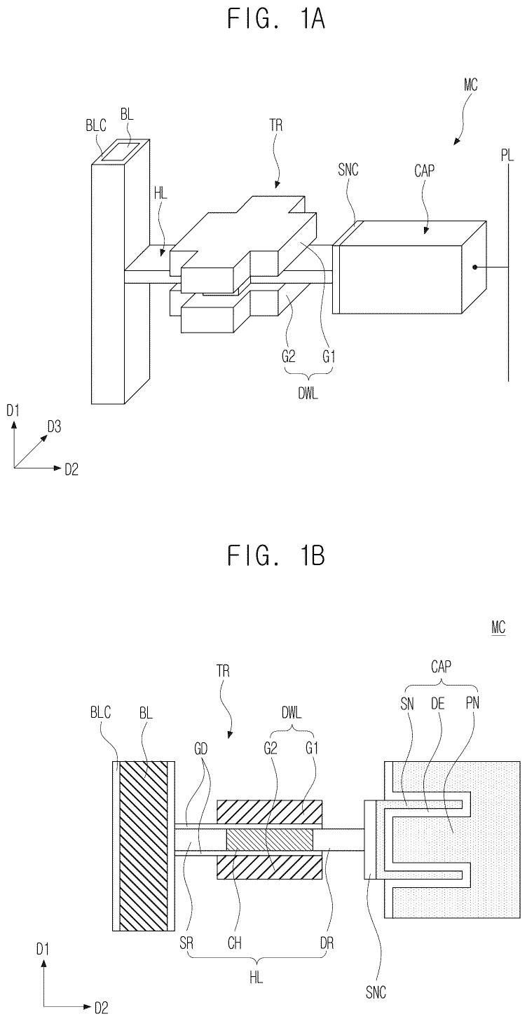

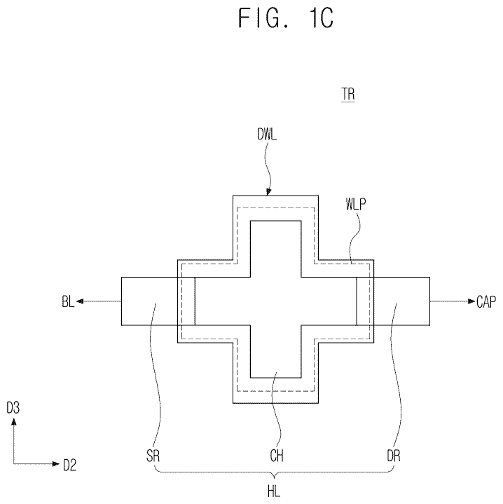

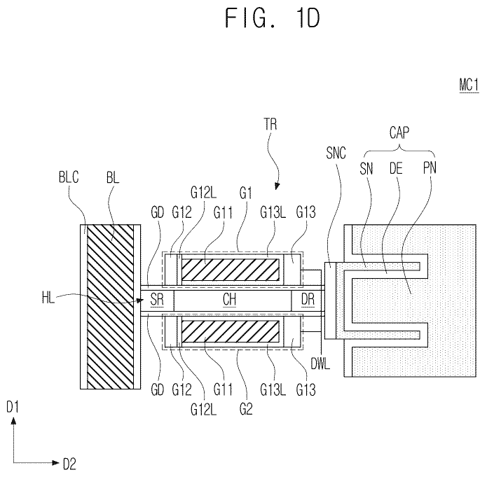

FIG. 1A is a schematic perspective view illustrating a memory cell MC in accordance with an embodiment of the present disclosure. FIG. 1B is a schematic cross-sectional view illustrating the memory cell MC illustrated in FIG. 1A. FIG. 1C is a plan view illustrating a switching element TR illustrated in FIG. 1A.

Referring to FIGS. 1A to 1C, the memory cell MC may include a first conductive line BL, the switching element TR, and a data storage element CAP.

A first conductive line BL may be vertically oriented in a first direction D1. The first conductive line BL may include a bit line. The first conductive line BL may be referred to as a vertical conductive line, a vertically-oriented bit line, a vertically-extending bit line, or a pillar-shape bit line. The first conductive line BL may include a conductive material. The first conductive line BL may include a silicon-based material, a metal, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include polysilicon or titanium nitride (TIN) doped with an N-type impurity. The first conductive line BL may include a stack (TiN/W) of titanium nitride and tungsten.

The switching element TR may have a function of controlling a voltage (or current) supply to the data storage element CAP during a data write operation and a data read operation performed on the data storage element CAP. The switching element TR may include a horizontal layer HL, an inter-level dielectric layer GD, and a second conductive line DWL. The second conductive line DWL may include a horizontal conductive line or a horizontal word line, and the horizontal layer HL may include an active layer. The switching element TR may include a transistor, and in this case, the second conductive line DWL may function as a gate electrode. The switching element TR may be referred to as an access element or a selection element. The second conductive line DWL may be referred to as a horizontal gate electrode or a horizontal word line.

The horizontal layer HL may extend in a second direction D2 that intersects with the first direction D1. The second conductive line DWL may extend in a third direction D3 that intersects with the first direction D1 and the second direction D2. The first direction D1 may be a vertical direction, the second direction D2 may be a first horizontal direction, and the third direction D3 may be a second horizontal direction. The horizontal layer HL may extend in the first horizontal direction, i.e., the second direction D2, and the second conductive line DWL may extend in the second horizontal direction, i.e., the third direction D3.

The horizontal layer HL may be horizontally oriented in the second direction D2 from the first conductive line BL. The second conductive line DWL may have a double structure. For example, the second conductive line DWL may include an upper (or top) horizontal line G1 and a lower (or bottom) horizontal line G2 facing each other with the horizontal layer HL interposed therebetween. The inter-level dielectric layer GD may be formed on upper (or top) and lower (or bottom) surfaces of the horizontal layer HL. The upper horizontal line G1 may be disposed in the upper portion (or top portion) of the horizontal layer HL, and the lower horizontal line G2 may be disposed in the lower portion (or bottom portion) of the horizontal layer HL. The second conductive line DWL may include a pair of the upper horizontal line G1 and the lower horizontal line G2. In the second conductive line DWL, the same driving voltage may be applied to the upper horizontal line G1 and the lower horizontal line G2. For example, the upper horizontal line G1 and the lower horizontal line G2 may form a pair to be coupled to one memory cell MC. According to another embodiment of the present disclosure, different driving voltages may be applied to the upper horizontal line G1 and the lower horizontal line G2. In this case, one horizontal line among the upper horizontal line G1 and the lower horizontal line G2 may function as a back gate or a shield gate.

Referring to FIG. 1C, each of the upper horizontal line G1 and the lower horizontal line G2 may have a width in the second direction D2, for example, the width of an overlapping portion that overlaps with the horizontal layer HL, which is greater than the width of a non-overlapping portion that does not overlap with the horizontal layer HL. Due to the difference in the widths, the second conductive line DWL may have notch-shape sidewalls.

The second conductive line DWL may include a channel overlapping portion WLP. The channel overlapping portion WLP may have a cross shape as illustrated or a rhombus shape.

From a top view perspective, the horizontal layer HL may have a cross shape as illustrated or a rhombus shape. According to another embodiment of the present disclosure, the side surfaces of the horizontal layer HL may have a bent shape or a rounded (or curved) shape.

The horizontal layer HL may include a semiconductor material. For example, the horizontal layer HL may include polysilicon, monocrystalline silicon, germanium, or silicon-germanium. According to another embodiment of the present disclosure, the horizontal layer HL may include an oxide semiconductor material. For example, the oxide semiconductor material may include Indium Gallium Zinc Oxide (IGZO). According to another embodiment of the present disclosure, the horizontal layer HL may include a conductive metal oxide. According to another embodiment of the present disclosure, the horizontal layer HL may include a two-dimensional material, for example, MoS₂, WS₂, or MoSe₂.

The upper and lower surfaces of the horizontal layer HL may be flat. The upper and lower surfaces of the horizontal layer HL may be parallel to each other in the second direction D2.

The horizontal layer HL may include a channel CH, a first doped region SR between the channel CH and the first conductive line BL, and a second doped region DR between the channel CH and the data storage element CAP. When the horizontal layer HL is formed of an oxide semiconductor material, the channel CH may be formed of an oxide semiconductor material, and the first and second doped regions SR and DR may be omitted. The horizontal layer HL may also be referred to as an active layer, a thin-body, or a thin body layer. The channel CH and the channel overlapping portion WLP of the second conductive line DWL may overlap with each other. The channel CH may have a cross shape as illustrated or a rhombus shape. The size of the channel overlapping portion WLP of the second conductive line DWL may be greater than that of the channel CH. The channel overlapping portion WLP of the second conductive line DWL may fully overlap with the channel CH.

The first and second doped regions SR and DR may be doped with impurities of the same conductivity type. The first and second doped regions SR and DR may be doped with an N-type or a P-type conductive impurity. The first and second doped regions SR and DR may include at least one impurity selected from arsenic (As), phosphorus (P), boron (B), indium (In), and a combination thereof. The first doped region SR may be coupled to the first conductive line BL. The second doped region DR may be coupled to the data storage element CAP. The first and second doped regions SR and DR may be referred to as first and second source/drain regions.

The inter-level dielectric layer GD may be disposed between the horizontal layer HL and the second conductive line DWL. The inter-level dielectric layer GD may be referred to as a gate dielectric layer. The inter-level dielectric layer GD may include silicon oxide, silicon nitride, metal oxide, metal oxynitride, metal silicate, a high-k material, a ferroelectric material, an anti-ferroelectric material, or a combination thereof. The inter-level dielectric layer GD may include SiO₂, Si₃N₄, HfO₂, Al₂O₃, ZrO₂, AlON, HfON, HfSiO, HfSiON, HfZrO, or a combination thereof. The inter-level dielectric layer GD may be formed by a thermal oxidation process of a semiconductor material.

The second conductive line DWL may include a metal, a metal-based material, a semiconductor material, or a combination thereof. The second conductive line DWL may include titanium nitride, tungsten, polysilicon, molybdenum, molybdenum nitride, or a combination thereof. For example, the second conductive line DWL may include a TiN/W stack in which titanium nitride and tungsten are sequentially stacked. The second conductive line DWL may include an N-type work function material or a P-type work function material. The N-type work function material may have a low work function of approximately 4.5 eV or lower, and the P-type work function material may have a high work function of approximately 4.5 eV or higher. The second conductive line DWL may include a stack of a low work function material and a high work function material.

The data storage element CAP may include a memory element, such as a capacitor. The data storage element CAP may be horizontally disposed in the second direction D2 from the switching element TR. The data storage element CAP may include a first electrode SN horizontally extending from the horizontal layer HL in the second direction D2. The data storage element CAP may further include a second electrode PN over the first electrode SN, and a dielectric layer DE between the first and second electrodes SN and PN. The first electrode SN, the dielectric layer DE, and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner and outer surfaces of the first electrode SN. The second electrode PN may be disposed in the inner space of the first electrode SN over the dielectric layer DE. Some of the outer surfaces of the first electrode SN may be electrically coupled to the second doped region DR of the horizontal layer HL.

The data storage element CAP may have a three-dimensional structure. The first electrode SN may have a three-dimensional structure, and the first electrode SN having the three-dimensional structure may have a horizontal three-dimensional structure that is oriented in the second direction D2. As an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the horizontal layer HL. The dielectric layer DE and the second electrode PN may be disposed on the cylindrical inner surfaces of the first electrode SN.

According to another embodiment of the present disclosure, the first electrode SN may have a pillar shape or a pylinder shape. The pylinder shape may refer to a structure in which a pillar shape and a cylindrical shape are merged.

The first and second electrodes SN and PN may include metal, noble metal, metal nitride, conductive metal oxide, conductive noble metal oxide, metal carbide, metal silicide, or a combination thereof. For example, the first and second electrodes SN and PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TIN) stack, or a combination thereof. The second electrode PN may also include a combination of a metal, a metal-based material and a silicon-based material. For example, the second electrode PN may be a stack (TiN/SiGe/WN) of titanium nitride/silicon germanium/tungsten nitride. In the titanium nitride/silicon germanium/tungsten nitride (TiN/SiGe/WN) stack, silicon germanium may be a gap-fill material that fills the inside of the first electrode SN, and titanium nitride (TiN) may serve as the second electrode PN of the data storage element CAP, and tungsten nitride may be a low-resistance material.

The dielectric layer DE may be referred to as a capacitor dielectric layer or a memory layer. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present disclosure, the dielectric layer DE may be formed of a composite layer including two or more layers of the above-described high-k material.

The dielectric layer DE may be formed of zirconium-based oxide (Zr-based oxide). The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. Each of the ZA stack and the ZAZ stack may be referred to as a zirconium oxide-based layer (ZrO₂-based layer). According to another embodiment of the present disclosure, the dielectric layer DE may be formed of hafnium-based oxide (Hf-based oxide). The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. Each of the HA stack and the HAH stack may be referred to as a hafnium oxide-based layer (HfO₂-based layer). In the ZA stack, ZAZ stack, HA stack, and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material that has a greater band gap energy than the high-k material. The dielectric layer DE may include silicon oxide (SiO₂) as a high band gap material other than aluminum oxide (Al₂O₃). Since the dielectric layer DE includes a high band gap material, leakage current may be suppressed. The high band gap material may be thinner than the high-k material. According to another embodiment of the present disclosure, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above-described stack structures, aluminum oxide (Al₂O₃) may be thinner than zirconium oxide (ZrO₂) and hafnium oxide (HfO₂).

According to another embodiment of the present disclosure, the dielectric layer DE may include a high-k material and a high band gap material, and the dielectric layer DE may have a laminated structure in which a plurality of high-k materials and a plurality of high band gap materials are stacked, or an intermixed structure in which a high-k material and a high band gap material are intermixed.

According to another embodiment of the present disclosure, the dielectric layer DE may include a ferroelectric material, an anti-ferroelectric material, or a combination thereof. For example, the dielectric layer DE may include HfZrO.

According to another embodiment of the present disclosure, the dielectric layer DE may include a combination of a high-k material and a ferroelectric material, a combination of a high-k material and an anti-ferroelectric material, or a combination of a high-k material or a ferroelectric material and an anti-ferroelectric material.

According to another embodiment of the present disclosure, an interface control layer may be further formed between the first electrode SN and the dielectric layer DE to improve leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

For example, the memory cell MC may include a thyristor, and the first conductive line BL may be a cathode line, and the data storage element CAP may be replaced with an anode line. Accordingly, the horizontal layer HL may include four semiconductor layers that are stacked in the second direction D2. The thyristor may include a first diode and a second diode that are coupled in series. When a forward bias having the same voltage is applied to the thyristor, the thyristor may have a high conductance state in which a large amount of current flows, or a low conductance state in which a small amount of current flows or no current flows. The memory cell MC according to an embodiment of the present disclosure may have a “1” state and a “0” state by using the high conductance state and the low conductance state of the thyristor, respectively.

Referring back to FIGS. 1A and 1B, the memory cell MC may further include a first contact node BLC and a second contact node SNC. The first contact node BLC may surround the outer wall of the first conductive line BL. The second contact node SNC may be disposed between the horizontal layer HL and the first electrode SN. The first contact node BLC may include a metal, a metal-based material or a semiconductor material. The second contact node SNC may include a metal, a metal-based material or a semiconductor material. For example, the first and second contact nodes BLC and SNC may each include titanium, titanium nitride, tungsten, or a combination thereof. In addition, the first and second contact nodes BLC and SNC may each include doped polysilicon, and the first and second doped regions SR and DR may include impurities diffused from the first contact node BLC and the second contact node SNC, respectively.

FIG. 1D is a schematic cross-sectional view illustrating a memory cell MC1 in accordance with an embodiment of the present disclosure. The memory cell MC1 illustrated in FIG. 1D may be similar to the memory cell MC illustrated in FIGS. 1A to 1C. Hence, as for detailed descriptions of overlapping components, the above-described embodiments may be referred to.

The memory cell MC1 may include a first conductive line BL, a switching element TR, and a data storage element CAP. The switching element TR may include a horizontal layer HL, an inter-level dielectric layer GD, and a second conductive line DWL. The horizontal layer HL may include a first doped region SR, a second doped region DR, and a channel CH disposed between the first and second doped regions SR, and DR. The data storage element CAP may include a first electrode SN, a second electrode PN, and a dielectric layer DE.

The memory cell MC1 may further include a first contact node BLC between the first conductive line BL and the horizontal layer HL and a second contact node SNC between the horizontal layer HL and the data storage element CAP. The first and second contact nodes BLC and SNC may each include doped polysilicon. The first and second doped regions SR and DR may include impurities diffused from the first contact node BLC and the second contact node SNC, respectively.

The second conductive line DWL may include an upper horizontal line G1 and a lower horizontal line G2. Each of the upper horizontal line G1 and the lower horizontal line G2 may include a first work function electrode G11, a second work function electrode G12, and a third work function electrode G13. The first work function electrode G11, the second work function electrode G12, and the third work function electrode G13 may be horizontally disposed in a second direction D2. The first work function electrode G11, the second work function electrode G12, and the third work function electrode G13 may be in direct contact with one another. The second work function electrode G12 may be adjacent to the first conductive line BL, and the third work function electrode G13 may be adjacent to the data storage element CAP. The horizontal layer HL may have a smaller thickness than the first, second, and third work function electrodes G11, G12, and G13.

The first work function electrode G11, the second work function electrode G12, and the third work function electrode G13 may be formed of different work function materials. The first work function electrode G11 may have a higher work function than the second and third work function electrodes G12 and G13. The first work function electrode G11 may include a high work function material. The first work function electrode G11 may have a work function higher than a mid-gap work function of silicon. The second and third work function electrodes G12 and G13 may each include a low work function material. The second and third work function electrodes G12 and G13 may each have a work function lower than the mid-gap work function of silicon. Specifically, the high work function material may have a work function higher than 4.5 eV, and the low work function material may have a work function lower than 4.5 eV. The first work function electrode G11 may include a metal, a metal-based material, and the second and third work function electrodes G12 and G13 may each include a semiconductor material.

The second and third work function electrodes G12 and G13 may each include N-type dopant doped polysilicon. The first work function electrode G11 may include metal, metal nitride, or a combination thereof. The first work function electrode G11 may include tungsten, titanium nitride, or a combination thereof. A barrier material may be further formed between the second and third work function electrodes G12 and G13 and the first work function electrode G11.

According to an embodiment of the present disclosure, in each of the upper and lower horizontal lines G1 and G2 of the second conductive line DWL, the second work function electrode G12, the first work function electrode G11 and the third work function electrode G13 may be horizontally disposed in this order in the second direction D2. The first work function electrode G11 may include metal, and the second work function electrode G12 and the third work function electrode G13 may each include polysilicon.

Each of the upper and lower horizontal lines G1 and G2 of the second conductive line DWL may have a poly Si-metal-poly Si (PMP) structure horizontally disposed in the second direction D2. In the PMP structure, the first work function electrode G11 may be a metal, a metal-based material, and the second and third work function electrodes G12 and G13 may each be N-type dopant doped polysilicon. The N-type dopant may include phosphorus or arsenic.

A first barrier layer G12L may be disposed between the first work function electrode G11 and the second work function electrode G12 to physically separate the first and second work function electrodes G11 and G12. A second barrier layer G13L may be disposed between the first work function electrode G11 and the third work function electrode G13 to physically separate the first and third work function electrodes G11 and G13. The first and second barrier layers G12L and G13L may each include titanium nitride, tantalum nitride, tungsten nitride, or molybdenum nitride. The second barrier layer G13L may cover a top surface, a bottom surface and one side surface of the first work function electrode G11.

The first work function electrode G11 may have a larger volume than the second and third work function electrodes G12 and G13, and thus the second conductive line DWL may have a low resistance. The first work function electrodes G11 of the upper and lower horizontal lines G1 and G2 may vertically overlap in a first direction D1 with the horizontal layer HL interposed therebetween. The second and third work function electrodes G12 and G13 of the upper and lower horizontal lines G1 and G2 may vertically overlap in the first direction D1 with the horizontal layer HL interposed therebetween. An overlapping area between the first work function electrode G11 and the horizontal layer HL may be greater than an overlapping area between the second and third work function electrodes G12 and G13 and the horizontal layer HL. The second and third work function electrodes G12 and G13 and the first work function electrode G11 may extend in a third direction D3, and the second and third work function electrodes G12 and G13 and the first work function electrode G11 may directly contact each other.

As described above, each of the upper and lower horizontal lines G1 and G2 may have a triple electrode structure (also referred to as triple work function electrode structure) including the first, second and third work function electrodes G11, G12, and G13. The second conductive line DWL may have a pair of the first work function electrodes G11, a pair of the second work function electrodes G12 and a pair of the third work function electrodes G13, which extend in the third direction D3 crossing the horizontal layer HL, with the horizontal layer HL interposed therebetween. The first work function electrodes G11, the second work function electrodes G12 and the third work function electrodes G13 may vertically overlap with the channel CH.

The second conductive lines DWL may include a channel overlapping portion WLP as illustrated in FIG. 1C. The channel overlapping portion WLP may have a cross shape as illustrated or a rhombus shape. The channel overlapping portion WLP may fully overlap with the channel CH. The second conductive line DWL may have notch-shape sidewalls by the channel overlapping portion WLP. The channel overlapping portion WLP may include the first work function electrodes G11, the second work function electrodes G12, and the third work function electrodes G13, and the first work function electrodes G11, the second work function electrodes G12, and the third work function electrodes G13 may vertically overlap with the channel CH.

In the second direction D2, the first work function electrode G11 having a high work function is disposed at the center of the second conductive line DWL, and the second and third work function electrodes G12 and G13 each having a low work function are disposed at both ends of the second conductive line DWL. Accordingly, leakage current such as gate induced drain leakage (GIDL) may be alleviated.

As the first work function electrode G11 having a high work function is disposed at the center of the second conductive line DWL, a threshold voltage of the switching element TR may increase. Since the second work function electrode G12 of the second conductive line DWL has a low work function, a low electric field may be formed between the first conductive line BL and the second conductive line DWL. Since the third work function electrode G13 of the second conductive line DWL has a low work function, a low electric field may be formed between the data storage element CAP and the second conductive line DWL.

As described above, the memory cell MC1 may include the second conductive line DWL having a triple work function electrode structure. Each of the upper and lower horizontal lines G1 and G2 of the second conductive line DWL may include the first work function electrode G11, the second work function electrode G12, and the third work function electrode G13. The first work function electrode G11 may overlap with the channel CH, the second work function electrode G12 may be adjacent to the first conductive line BL and the first doped region SR, and the third work function electrode G13 may be adjacent to the data storage element CAP and the second doped region DR. Due to a low work function of the second work function electrode G12, a low electric field is formed between the second conductive line DWL and the first conductive line BL, thereby making it possible to reduce leakage current. Due to a low work function of the third work function electrode G13, a low electric field is formed between the second conductive line DWL and the data storage element CAP, thereby making it possible to reduce leakage current. Due to a high work function of the first work function electrode G11, a high threshold voltage of the switching element TR may be formed, and a low electric field may be formed, thereby making it possible to reduce the height of the memory cell MC1, which is advantageous in terms of integration.

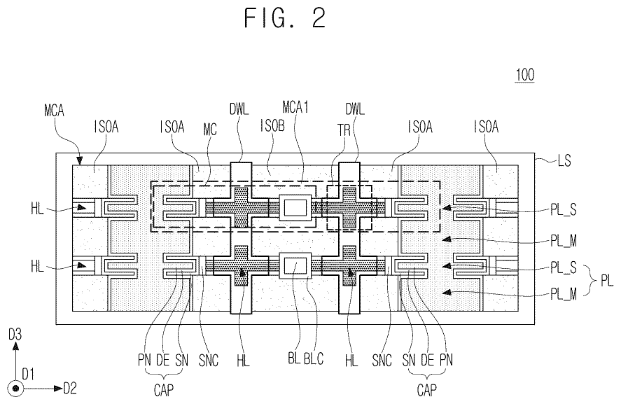

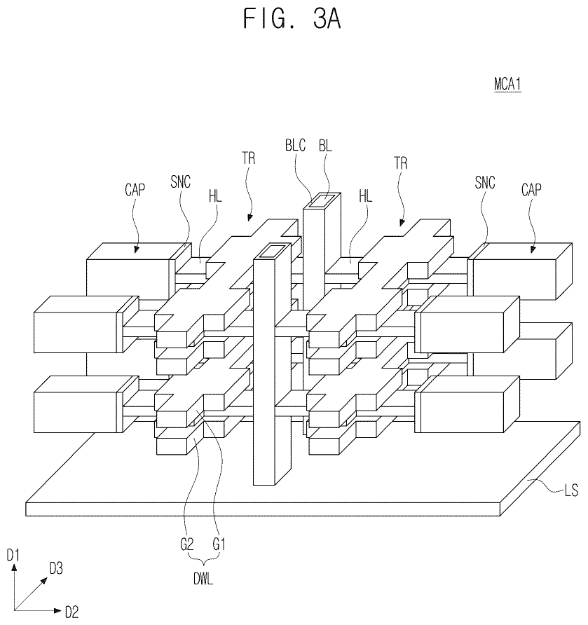

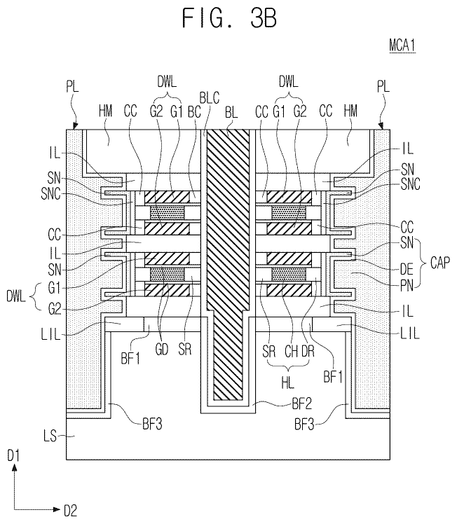

FIG. 2 is a schematic plan view illustrating a semiconductor device 100 in accordance with an embodiment of the present disclosure. FIG. 3A is a schematic perspective view illustrating a first memory cell array MCA1 illustrated in FIG. 2. FIG. 3B is a schematic cross-sectional view illustrating the first memory cell array MCA1 illustrated in FIG. 2.

Referring to FIGS. 2, 3A and 3B, the semiconductor device 100 may include a memory cell array MCA. The memory cell array MCA may include a plurality of memory cells MC. As for each memory cell MC, FIGS. 1A to 1C may be referred to. Each memory cell MC may include a first conductive line BL, a switching element TR, and a data storage element CAP.

The memory cell array MCA may include a three-dimensional array of the memory cells MC. The three-dimensional array of the memory cells MC may include a column array of the memory cells MC and a row array of the memory cells MC. The column array of the memory cells MC may include a plurality of memory cells MC that are stacked in a first direction D1, and the row array of the memory cells MC may include a plurality of memory cells MC that are horizontally disposed in a second direction D2 and a third direction D3. The memory cell array MCA may include sub-memory cell arrays MCA1 disposed adjacent to one another in the second direction D2. The sub-memory cell arrays MCA1 may have a mirror-type structure in which two memory cells MC share the first conductive line BL. According to another embodiment of the present disclosure, the semiconductor device 100 may further include sub-memory cell arrays having a mirror-type structure in which two memory cells MC share a second electrode PN of the data storage element CAP. The memory cell array MCA may include a plurality of sub-memory cell arrays MCA1 in which the memory cells MC are vertically stacked in the first direction D1. The memory cell array MCA may include a plurality of sub-memory cell arrays MCA1 that are horizontally disposed in the third direction D3.

Inter-cell dielectric layers IL may be disposed between the memory cells MC that are stacked in the first direction D1. The inter-cell dielectric layers IL may each include silicon oxide.

Cell isolation layers ISOA and ISOB may be disposed between the memory cells MC disposed adjacent to each other in the third direction D3. The cell isolation layers ISOA and ISOB may include silicon oxide, silicon carbon oxide (SiCO), silicon nitride, or a combination thereof. The cell isolation layers ISOA and ISOB may include first cell isolation layers ISOA and second cell isolation layers ISOB. The first and second cell isolation layers ISOA and ISOB may vertically extend in the first direction D1. The first and second cell isolation layers ISOA and ISOB may have a pillar structure vertically extending in the first direction D1. The first and second cell isolation layers ISOA and ISOB may be alternately and repeatedly disposed in the second direction D2. The first cell isolation layers ISOA may be disposed between the data storage elements CAP in the third direction D3. The second cell isolation layers ISOB may be disposed between the first conductive lines BL in the third direction D3. Second conductive lines DWL may be disposed between the first cell isolation layers ISOA and the second cell isolation layers ISOB in the second direction D2.

The memory cell array MCA may be disposed over a lower structure LS.

The memory cell array MCA may include a plurality of second conductive lines DWL that are vertically stacked in the first direction D1. The memory cell array MCA may include a plurality of horizontal layers HL that are vertically stacked in the first direction D1. The memory cell array MCA may include a plurality of data storage elements CAP that are vertically stacked in the first direction D1. The memory cell array MCA may include a plurality of first conductive lines BL that are spaced apart from one another in the third direction D3.

Each of the second conductive lines DWL may include a channel overlapping portion WLP as illustrated in FIG. 1C. The channel overlapping portion WLP may have a cross shape or a rhombus shape. The channel overlapping portion WLP may fully overlap with a channel CH. The second conductive line DWL extending in the third direction D3 may include a plurality of channel overlapping portions WLP. As the channel overlapping portions WLP and channel non-overlapping portions (reference numeral omitted) are alternately repeated in the third direction D3, the second conductive line DWL may have notch-shape sidewalls.

A plurality of first passivation layers BF1 may be disposed between the lowermost second conductive line DWL among the plurality of second conductive lines DWL and the lower structure LS. A second passivation layer BF2 may be disposed between the first conductive line BL and the lower structure LS. Third passivation layers BF3 may be disposed between the data storage element CAP and the lower structure LS. The first to third passivation layers BF1, BF2 and BF3 may each include a dielectric material. The first to third passivation layers BF1, BF2 and BF3 may each include silicon oxide. The first conductive line BL, the second conductive lines DWL, and the data storage elements CAP may be electrically disconnected from the lower structure LS by the first to third passivation layers BF1, BF2 and BF3. The first to third passivation layers BF1, BF2 and BF3 may be referred to as bottom dielectric layers or bottom passivation layers. A lowermost-level inter-cell dielectric layer LIL may be disposed between the first passivation layers BF1 and the data storage element CAP.

The first conductive lines BL may vertically extend in the first direction D1 from the upper portion of the lower structure LS. The horizontal layers HL may extend in the second direction D2 that intersects with the first direction D1. The second conductive lines DWL may extend in the third direction D3 that intersects with the first direction D1 and the second direction D2.

From a top view perspective, the horizontal layers HL may each have a cross shape or rhombus shape. According to another embodiment of the present disclosure, the side surfaces of the horizontal layer HL may have a bent shape or a rounded (or curved) shape. As illustrated in FIG. 1B, the horizontal layer HL may include the channel CH, a first doped region SR between the channel CH and the first conductive line BL, and a second doped region DR between the channel CH and the data storage element CAP.

A first capping layer BC may be disposed between the second conductive line DWL and the first conductive line BL. A second capping layer CC may be disposed between the second conductive line DWL and a first electrode SN of the data storage element CAP. The first capping layer BC may be disposed between an upper horizontal line G1 and the first conductive line BL. In addition, the first capping layer BC may be disposed between a lower horizontal line G2 and the first conductive line BL. The second capping layer CC may be disposed between the upper horizontal line G1 and the first electrode SN of the data storage element CAP. In addition, the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may each include a dielectric material. The first and second capping layers BC and CC may each include silicon oxide, silicon nitride, silicon carbon oxide, an air gap, or a combination thereof. The first capping layer BC may include silicon oxide, and the second capping layer CC may include a stack of silicon oxide and silicon nitride.

The horizontal layers HL of switching elements TR horizontally disposed in the third direction D3 may share one second conductive line DWL. The horizontal layers HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line DWL.

The first cell isolation layers ISOA may be disposed between the first electrodes SN of the data storage elements CAP in the third direction D3. The first electrodes SN may be isolated from one another by the first cell isolation layers ISOA. The second electrodes PN of the data storage elements CAP may be coupled to a common plate PL.

Referring to FIG. 2, portions of the second electrodes PN may divide the first cell isolation layer ISOA. The second electrodes PN of the data storage elements CAP may be merged to become the common plate PL. The second electrodes PN of the data storage elements CAP horizontally disposed in the third direction D3 may be merged with each other. The second electrodes PN of the data storage elements CAP vertically disposed in the first direction D1 may be merged with each other. The common plate PL may horizontally extend in the third direction D3 and vertically extend in the first direction D1. The common plate PL may include a sharing portion PL_S sharing the memory cells MC disposed adjacent to each other in the second direction D2 and a merging portion PL_M disposed between the first cell isolation layers ISOA. The common plate PL may have a cross shape extending in the third direction D3 by combination of a plurality of sharing portions PL_S and a plurality of merging portions PL_M. The first cell isolation layers ISOA may be divided into a plurality of first cell isolation segments ISOA1 and a plurality of second cell isolation segments ISOA2 by the merge portions PL_M of the common plate PL. The first and second cell isolation segments ISOA1 and ISOA2 may each have the same size or a smaller size than the second cell isolation layers ISOB. The first electrodes SN of the data storage element CAP may be disposed between the first cell isolation segments ISOA1 in the third direction D3. The first electrodes SN of the data storage element CAP may be disposed between the second cell isolation segments ISOA2 in the third direction D3.

The first cell isolation layers ISOA may be disposed between the data storage elements CAP in the third direction D3. The second cell isolation layers ISOB may be disposed between the first conductive be disposed between the first cell isolation layers ISOA and the second cell isolation layers ISOB in the second direction D2. The first cell isolation layers ISOA may each have a larger size than the second cell isolation layers ISOB.

The lower structure LS may include a semiconductor substrate, a metal interconnection structure, a dielectric structure, a conductive structure, a bonding pad structure, another memory, or a peripheral circuit portion.

For example, the lower structure LS may include a structure in which the peripheral circuit portion, the metal interconnection structure, and the bonding pad structure are stacked in the mentioned order. The memory cell array MCA and the peripheral circuit portion of the lower structure LS may be bonded by wafer bonding.

The peripheral circuit portion of the lower structure LS may be disposed at a lower level than the memory cell array MCA. This may be referred to as a cell-over-peripheral (COP) structure. The peripheral circuit portion may include at least one control circuit for driving the memory cell array MCA. The at least one control circuit of the peripheral circuit portion may include an N-channel transistor, a P-channel transistor, a CMOS circuit, or a combination thereof. The at least one control circuit of the peripheral circuit portion may include an address decoder circuit, a read circuit, and a write circuit. The at least one control circuit of the peripheral circuit portion may include a planar channel transistor, a recess channel transistor, a buried gate transistor, and a fin channel transistor (FinFET).

For example, the peripheral circuit portion may include sub-word line drivers and a sense amplifier. The second conductive lines DWL may be coupled to the sub-word line drivers. The first conductive line BL may be coupled to the sense amplifier.

According to another embodiment of the present disclosure, the peripheral circuit portion may be disposed at a higher level than the memory cell array MCA. This may be referred to as a peripheral-over-cell (POC) structure.

According to another embodiment of the present disclosure, the memory cell array MCA may include a dynamic random-access memory (DRAM), an embedded DRAM, a NAND, a ferroelectric RAM (FeRAM), a spin transfer torque RAM (STTRAM), a phase-change RAM (PCRAM), or a resistive RAM (ReRAM).

According to another embodiment of the present disclosure, the individual memory cell MC may be replaced by the memory cell MC1 illustrated in FIG. 1D.

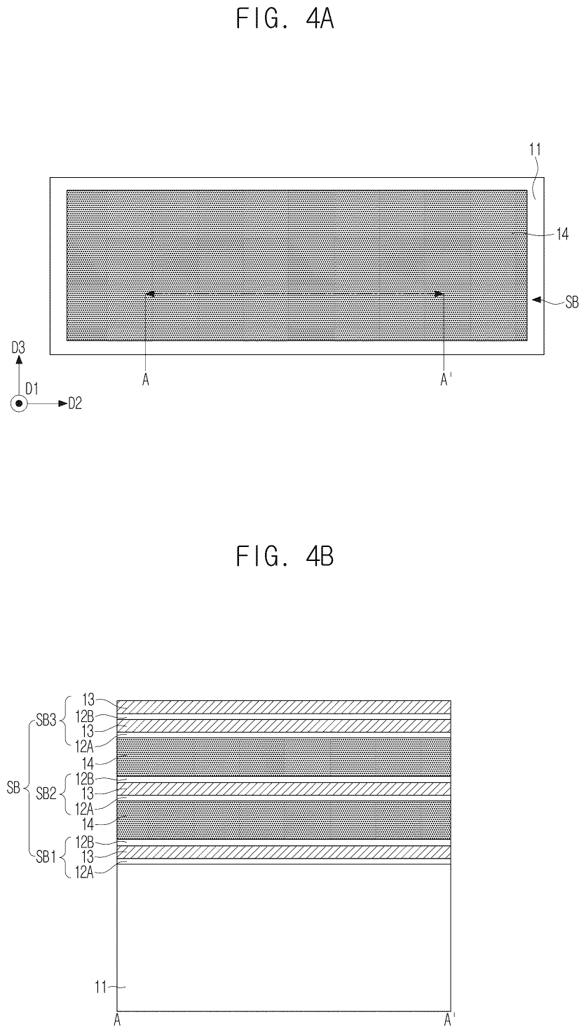

FIG. 4A to 27B illustrate various views of a semiconductor device formed according to a method for fabricating the semiconductor device in accordance with an embodiment of the present disclosure.

FIG. 4A is a plan view illustrating a structure with a fourth layer 14 for describing a method for forming a stack body SB. FIG. 4B is a cross-sectional view illustrating a structure taken along line A-A′ illustrated in FIG. 4A.

As illustrated in FIGS. 4A and 4B, the stack body SB may be formed over a lower structure 11. The lower structure 11 may be a material appropriate for semiconductor processing. The lower structure 11 may include at least one or more of a conductive material, a dielectric material and a semiconductive material. Diverse materials may be formed over the lower structure 11. The lower structure 11 may include a semiconductor substrate. The lower structure 11 may be formed of a material containing silicon. The lower structure 11 may include silicon, monocrystalline silicon, polysilicon, amorphous silicon, silicon germanium, monocrystalline silicon germanium, polycrystalline silicon germanium, carbon-doped silicon, a combination thereof, or multi-layers thereof. The lower structure 11 may also include another semiconductor material such as germanium. The lower structure 11 may also include a III/V-group semiconductor substrate, for example, a compound semiconductor substrate such as GaAs. The lower structure 11 may include a silicon-on-insulator (SOI) substrate.

The stack body SB may include a plurality of sub-stacks that are alternately stacked on one another. Each of the sub-stacks may include a first layer 12A, a second layer 13, a third layer 12B, and a fourth layer 14 that are stacked in the mentioned order. The first layer 12A and the third layer 12B may be formed of the same material, such as silicon germanium. The second layer 13 may include monocrystalline silicon. The fourth layer 14 may include monocrystalline silicon. The first layer 12A, the second layer 13, the third layer 12B, and the fourth layer 14 may be formed by an epitaxial growth process. The first layer 12A may be thinner than the second layer 13, and the fourth layer 14 may be thicker than the second layer 13.

The stack body SB may include a plurality of fourth layers 14, a first sacrificial layer stack SB1, a second sacrificial layer stack SB2, and a third sacrificial layer stack SB3. The stack body SB may include the first sacrificial layer stack SB1, the fourth layer 14, the second sacrificial layer stack SB2, the fourth layer 14, and the third sacrificial layer stack SB3 that are stacked in the mentioned order. The second layer 13 may be disposed at the uppermost level of the stack body SB. Each of the first to third stacks SB1 to SB3 may be a three-layer stack of the first layer 12A/the second layer 13/the third layer 12B. For example, when the first layer 12A and the third layer 12B include a silicon germanium layer and the second layer 13 includes a monocrystalline silicon layer, the first to third stacks SB1 to SB3 may include a stack (SiGe/Si/SiGe) of a first silicon germanium layer/monocrystalline silicon layer/a second silicon germanium layer.

The second layer 13 may include a first monocrystalline silicon layer, and the fourth layer 14 may include a second monocrystalline silicon layer. The second monocrystalline silicon layer may be thicker than the first monocrystalline silicon layer. Accordingly, in the stack body SB, the first stack SB1 may be disposed below the second monocrystalline silicon layer, and the second stack SB2 may be disposed over the second monocrystalline silicon layer. Each of the first and second stacks SB1 and SB2 may include a stack of a first silicon germanium layer/a first monocrystalline silicon layer/a second silicon germanium layer. The second monocrystalline silicon layer may be thicker than the first monocrystalline silicon layer.

The first layer 12A, the second layer 13, and the third layer 12B may be referred to as sacrificial layers, and the fourth layer 14 may be referred to as a recess target layer.

As described above with reference to FIGS. 2 to 3D, when memory cells MC are stacked, the first sacrificial layer stack SB1, the fourth layer 14, the second sacrificial layer stack SB2, the fourth layer 14, and the third sacrificial layer stack SB3 may be alternately stacked several times.

According to another embodiment of the present disclosure, the second layer 13 may include an oxide semiconductor material or a two-dimensional material.

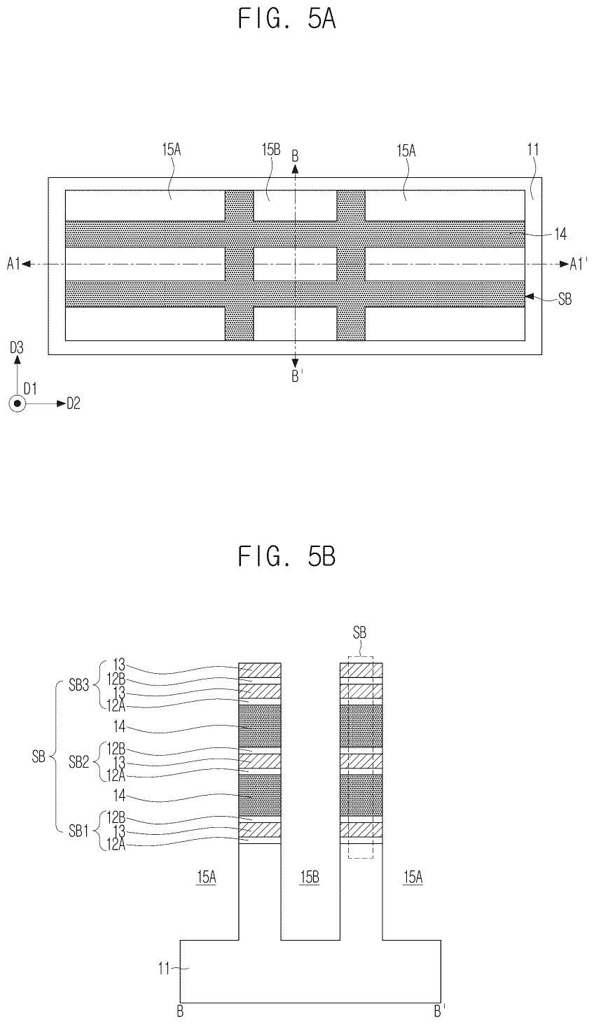

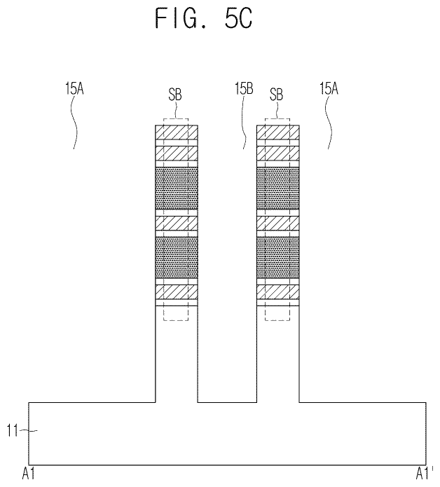

FIG. 5A is a plan view illustrating a structure with the fourth layer 14 for describing a method for forming sacrificial isolation openings 15A and 15B. FIG. B is a cross-sectional view illustrating a structure taken along line B-B′ illustrated in FIG. 5A. FIG. 5C is a cross-sectional view illustrating a structure taken along line A1-A1′ illustrated in FIG. 5A.

Referring to FIGS. 5A to 5C, a portion of the stack body SB may be etched to form a plurality of sacrificial isolation openings 15A and 15B. The sacrificial isolation openings 15A and 15B, which are initial openings for isolation, may include large openings 15A and small openings 15B. The size of the large openings 15A may be larger than that of the small openings 15B. From a top view perspective, the large openings 15A and the small openings 15B may each have a rectangular shape. According to another embodiment of the present disclosure, the large openings 15A and the small openings 15B may each have a circular shape or an oval shape. From a top view perspective, the sacrificial isolation openings 15A and 15B may be referred to as sacrificial isolation trenches. The large openings 15A may be alternately disposed with the small openings 15B in a second direction D2. A plurality of large openings 15A may be disposed in a third direction D3. A plurality of small openings 15B may be disposed in the third direction D3.

After the stack body SB is etched, portions of the lower structure 11 may be etched. Accordingly, the bottom surfaces of the sacrificial isolation openings 15A and 15B may extend inside the lower structure 11. The bottom surfaces of the sacrificial isolation openings 15A and 15B may each include a U-shape profile. The fourth layer 14 may have a mesh-shape pattern by the sacrificial isolation openings 15A and 15B.

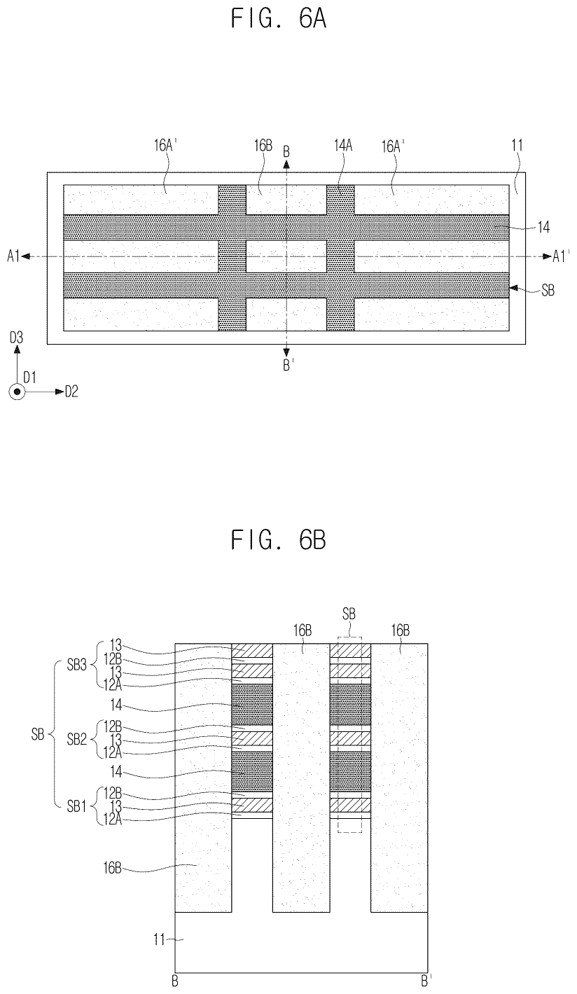

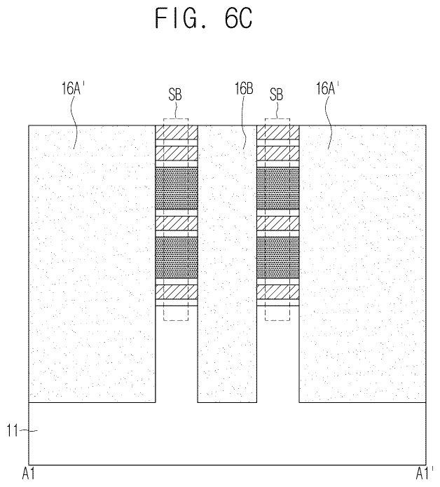

FIG. 6A is a plan view illustrating a structure with the fourth layer 14 for describing a method for forming sacrificial cell isolation layers 16A′ and 16B. FIG. 6B is a cross-sectional view illustrating a structure taken along line B-B′ illustrated in FIG. 6A. FIG. 6C is a cross-sectional view illustrating a structure taken along line A1-A1′ illustrated in FIG. 6A.

As illustrated in FIGS. 6A to 6C, the sacrificial cell isolation layers 16A′ and 16B may be formed to fill the sacrificial isolation openings 15A and 15B. The sacrificial cell isolation layers 16A′ and 16B may include preliminary first sacrificial cell isolation layers 16A′ and second sacrificial cell isolation layers 16B. The preliminary first sacrificial cell isolation layers 16A′ may fill the large openings 15A, and the second sacrificial cell isolation layers 16B may fill the small openings 15B.

The preliminary first sacrificial cell isolation layers 16A′ and the second sacrificial cell isolation layers 16B may include the same material. The preliminary first sacrificial cell isolation layers 16A′ and the second sacrificial cell isolation layers 16B may be formed of a dielectric material. For example, the preliminary first sacrificial cell isolation layers 16A′ and the second sacrificial cell isolation layers 16B may include silicon oxide, silicon nitride, silicon carbon oxide, silicon carbon nitride, or a combination thereof. Forming the preliminary first sacrificial cell isolation layers 16A′ and the second sacrificial cell isolation layers 16B may include forming a dielectric material on the stack body SB to fill the sacrificial isolation openings 15A and 15B and planarizing the dielectric material so that the uppermost layer of the stack body SB is exposed. The preliminary first sacrificial cell isolation layers 16A′ and the second sacrificial cell isolation layers 16B may have different sizes or different volumes. For example, the size or volume of the preliminary first sacrificial cell isolation layers 16A′ may be larger than that of the second sacrificial cell isolation layers 16B.

The preliminary first sacrificial cell isolation layers 16A′ may be alternately disposed with the second sacrificial cell isolation layers 16B in the second direction D2. A plurality of preliminary first sacrificial cell isolation layers 16A′ may be disposed in the third direction D3. A plurality of second sacrificial cell isolation layers 16B may be disposed in the third direction D3.

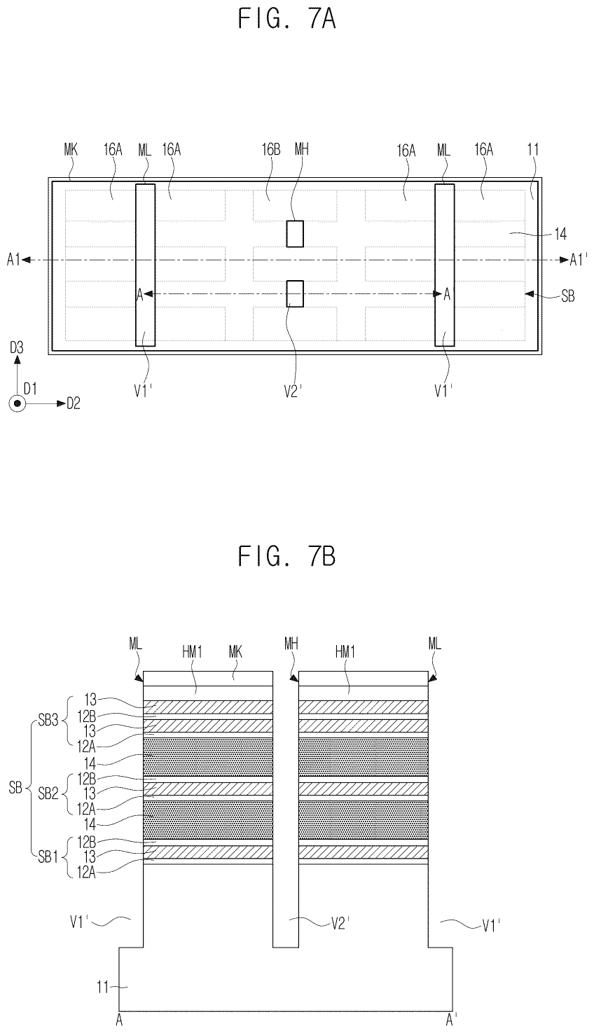

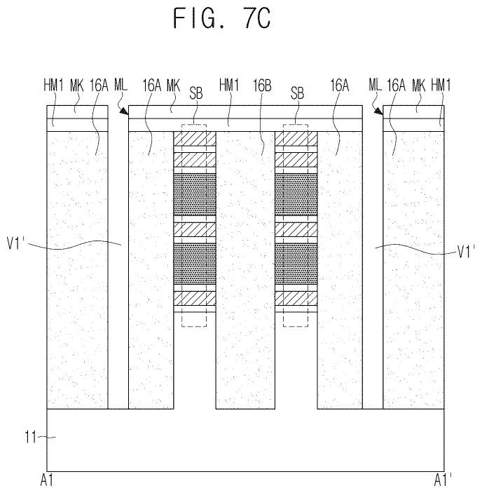

FIG. 7A is a plan view illustrating a structure with the fourth layer 14 for describing a method for forming sacrificial openings V1′ and V2′. FIG. 7B is a cross-sectional view illustrating a structure taken along line A-A′ illustrated in FIG. 7A. FIG. 7C is a cross-sectional view illustrating a structure taken along line A1-A1′ illustrated in FIG. 7A.

As illustrated in FIG. 7A to 7C, a first hard mask layer HM1 may be formed on the stack body SB, the preliminary first sacrificial cell isolation layers 16A′, and the second sacrificial cell isolation layers 16B. The first hard mask layer HM1 may include silicon nitride.

Subsequently, a mask layer MK may be formed on the first hard mask layer HM1. The mask layer MK, which is an etch mask layer, may include a hard mask material, photoresist, or a combination thereof. The mask layer MK may include hole-shape opening patterns MH and line-shape opening patterns ML. The line-shape opening patterns ML may extend in the third direction D3 and intersect the preliminary first sacrificial cell isolation layers 16A′.

Subsequently, the first hard mask layer HM1, the stack body SB and the preliminary first sacrificial cell isolation layers 16A′ may be etched using the mask layer MK as an etch barrier. Accordingly, a plurality of sacrificial openings V1′ and V2′ may be formed in the stack body SB. The sacrificial openings V1′ and V2′ may include first sacrificial openings V1′ and second sacrificial openings V2′. From a top view perspective, the first sacrificial openings V1′ may be line-shape openings, and the second sacrificial openings V2′ may be hole-shape openings. The first sacrificial openings V1′ may be formed by etching the stack body SB and the preliminary first sacrificial cell isolation layers 16A′. The second sacrificial openings V2′ may be formed by etching the stack body SB between the second sacrificial cell isolation layers 16B.

The first sacrificial openings V1′ may divide the preliminary first sacrificial cell isolation layers 16A′. The preliminary first sacrificial cell isolation layers 16A′ may be divided into first sacrificial cell isolation layers 16A by the first sacrificial openings V1′. Two second sacrificial openings V2′ may be disposed between the second sacrificial cell isolation layers 16B disposed adjacent to each other in the third direction D3.

As described above, line patterning and hole patterning may be simultaneously performed to form the sacrificial openings V1′ and V2′.

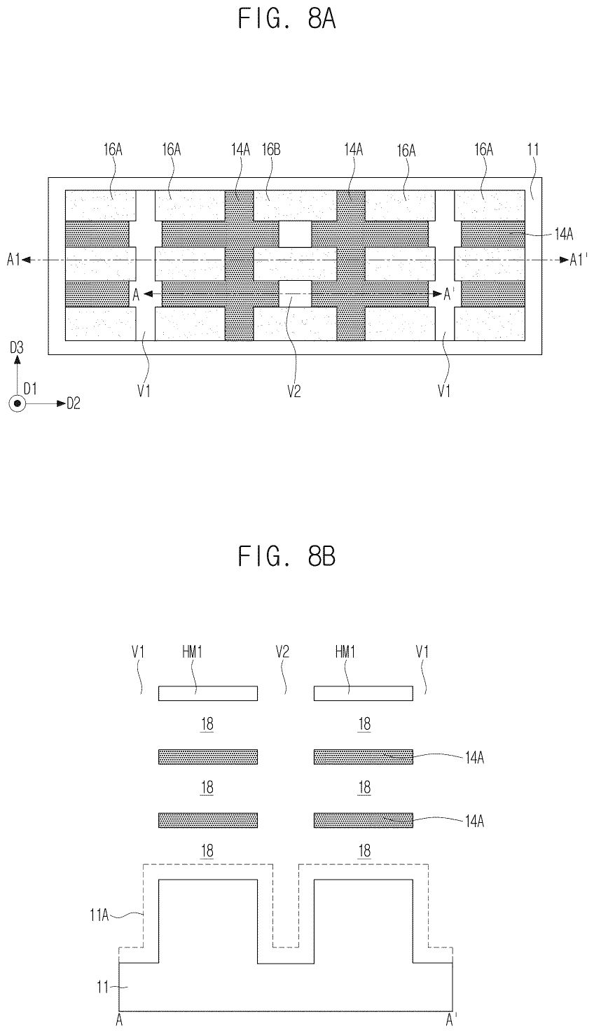

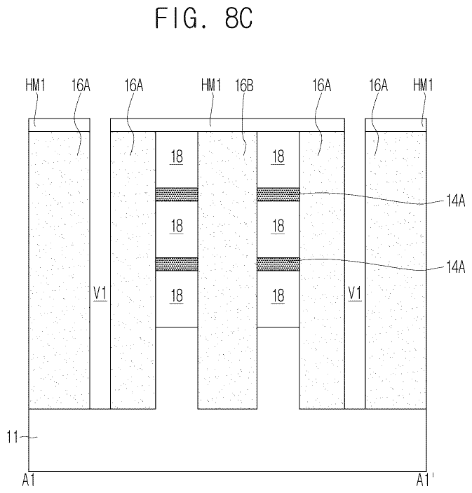

FIG. 8A is a plan view illustrating a structure with a preliminary horizontal layer 14A for describing a method for forming the preliminary horizontal layer 14A. FIG. 8B is a cross-sectional view illustrating a structure taken along line A-A′ illustrated in FIG. 8A. FIG. 8C is a cross-sectional view illustrating a structure taken along line A1-A1′ illustrated in FIG. 8A.

As illustrated in FIGS. 8A to 8C, a portion of the first hard mask layer HM1 may be trimmed.

Subsequently, the first and third layers 12A and 12B may be selectively removed through the sacrificial openings V1′ and V2′.

The first layers 12A and the third layers 12B may be selectively removed by using a difference in etch selectivity between the second and fourth layers 13 and 14 and the first and third layers 12A and 12B. The first layers 12A and the third layers 12B may be removed by a wet etching process or a dry etching process. For example, when the first layers 12A and the third layers 12B include a silicon germanium layer, and the second layers 13 and the fourth layers 14 include a silicon layer, the silicon germanium layers may be etched by using an etchant or an etching gas having a selectivity with respect to the silicon layers.

Subsequently, the second layers 13 and the fourth layers 14 may be recessed. To recess the second layers 13 and the fourth layers 14, a wet etching process or a dry etching process may be performed. According to an embodiment of the present disclosure, the fourth layers 14 may be partially etched while the second layers 13 are removed. As a result, the second layers 13 may be removed, and the fourth layers 14 may become thin, as indicated by reference numeral “14A”. The recess process of forming the thin fourth layers 14A, which are the preliminary horizontal layers 14A, may be referred to as a “thinning process” or a “trimming process” of the fourth layers 14. The preliminary horizontal layers 14A may be referred to as “thin-body active layers”. The preliminary horizontal layers 14A may each include a monocrystalline silicon layer. While the preliminary horizontal layers 14A are formed, the surface of the lower structure 11 may be recessed to a predetermined depth (refer to reference numeral “11A”). The recess process of forming the preliminary horizontal layers 14A may use, for example, HSC1 (Hot SC-1). HSC1 may include a solution of ammonium hydroxide (NH₄OH), hydrogen peroxide (H₂O₂), and water (H₂O) that are mixed at a ratio of approximately 1:4:20. The second layers 13 and the fourth layers 14 may be selectively etched by using HSC1.

The preliminary horizontal layers 14A may be formed by the recess process for the fourth layers 14 as described above, and horizontal recesses 18 may be formed between the preliminary horizontal layers 14A. Each of the upper and lower surfaces of the preliminary horizontal layers 14A may be flat.

After the preliminary horizontal layers 14A are formed, the sacrificial openings may be expanded as indicated by reference numeral “V1” and “V2”. The preliminary horizontal layers 14A may be spaced apart from each other by the sacrificial openings V1 and V2 in the second direction D2.

From a top view perspective, the preliminary horizontal layers 14A may have a cross shape, and the side surfaces of the preliminary horizontal layers 14A may have a bent shape or a round shape. The preliminary horizontal layers 14A may be spaced apart from each other by the sacrificial openings V1 and V2. The preliminary horizontal layers 14A may have a shape in which a plurality of cross shapes are merged in the third direction D3.

As described above, while the preliminary horizontal layers 14A are formed, the surface of the lower structure 11 may be recessed to a predetermined depth. As a result, the depths of the sacrificial openings V1 and V2 may increase.

The line-shape sacrificial openings V1 may be alternately disposed with the hole-shape sacrificial openings V2 between the preliminary horizontal layers 14A in the second direction D2. The line-shape sacrificial openings V1 may be disposed between the first sacrificial cell isolation layers 16A in the second direction D2, and the hole-shape sacrificial openings V2 may be disposed between the second sacrificial cell isolation layers 16B in the third direction D3.

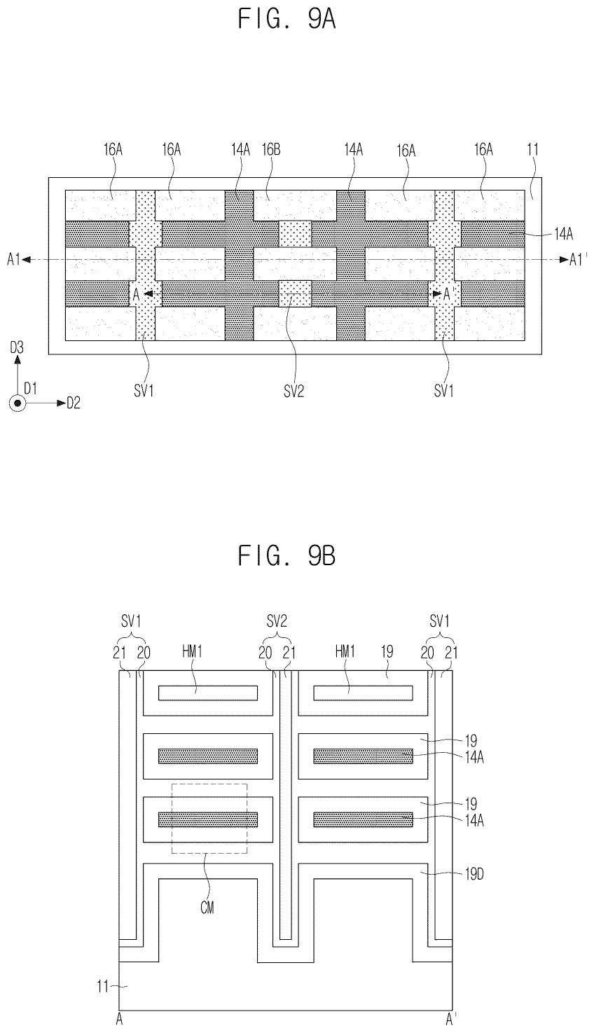

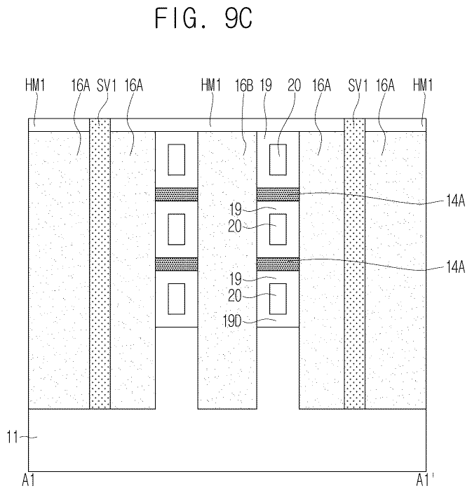

FIG. 9A is a plan view illustrating a structure for describing a method for forming a first dielectric layer 19 and a second dielectric layer 20. FIG. 9B is a cross-sectional view illustrating a structure taken along line A-A′ illustrated in FIG. 9A. FIG. 9C is a cross-sectional view illustrating a structure taken along line A1-A1′ illustrated in FIG. 9A.

As illustrated in FIGS. 9A to 9C, first dielectric layers 19 covering the preliminary horizontal layers 14A may be formed. The first dielectric layers 19 may each include silicon nitride. The first dielectric layers 19 may fully cover the upper surfaces, lower surfaces and side surfaces of the preliminary horizontal layers 14A.

While the first dielectric layers 19 are formed, a dummy dielectric layer 19D may be formed on the surface of the lower structure 11. A portion of each of the first dielectric layers 19 may fully cover the upper surface, lower surface and side surfaces of the first hard mask layer HM1.

Subsequently, second dielectric layers 20 may be formed on the first dielectric layers 19. Each of the second dielectric layers 20 may fill between the vertically neighboring first dielectric layers 19. The second dielectric layer 20 may include silicon oxide. A portion of the second dielectric layer 20 may be formed conformally on the surfaces of the sacrificial openings V1 and V2. The horizontal recesses 18 may be filled with the first dielectric layers 19 and the second dielectric layers 20.

Subsequently, sacrificial pillars 20 may be formed over the second dielectric layers 20 disposed in the sacrificial openings V1 and V2. Each of the sacrificial pillars 21, which is a sacrificial material, may include amorphous carbon. According to another embodiment of the present disclosure, a pillar capping layer may be further formed over the sacrificial pillar 21. The pillar capping layer may include a metal, a metal-based material, or a combination thereof. The pillar capping layer may include titanium nitride. Forming the sacrificial pillar 21 may include depositing a sacrificial material and planarizing the sacrificial material. The planarization process of forming the sacrificial pillar 21 may be performed until the uppermost-level first dielectric layer 19 is exposed.

The second dielectric layer 20 and the sacrificial pillar 21 may form first and second sacrificial pillar structures SV1 and SV2 that fill the sacrificial openings V1 and V2. The first sacrificial pillar structure SV1 may fill the line-shape sacrificial openings V1, and the second sacrificial pillar structure SV2 may fill the hole-shape sacrificial openings V2. The sacrificial pillar 21 may not be formed between the vertically stacked first dielectric layers 19. According to another embodiment of the present disclosure, the first and second sacrificial pillar structures SV1 and SV2 may include a dielectric material, a carbon-containing material, a metal, a metal-based material, or a combination thereof. According to another embodiment of the present disclosure, the first and second sacrificial pillar structures SV1 and SV2 may include silicon oxide, silicon nitride, titanium nitride, amorphous carbon, or a combination thereof. From a top view perspective, the first sacrificial pillar structure SV1 may be a line-shape sacrificial pillar extending in the third direction D3, and the second sacrificial pillar structure SV2 may be a hole-shape sacrificial pillar.

Referring to FIG. 9C, the first dielectric layer 19 may be formed between the preliminary horizontal layers 14A, and the second dielectric layer 20 may be disposed in the first dielectric layer 19. The first dielectric layer 19 may surround the second dielectric layer 20.

As described above, by forming the preliminary horizontal layers 14A, the first dielectric layers 19, and the second dielectric layers 20, a cell mold structure may be formed. The cell mold structure may include a plurality of cell molds CM. Each of the cell molds CM may include a plurality of mold layers. The mold layers may refer to the preliminary horizontal layers 14A, the first dielectric layers 19 and the second dielectric layers 20. In each of the cell molds CM, a first sacrificial layer, a semiconductor layer, and a second sacrificial layer may be stacked in the mentioned order. The first and second sacrificial layers may refer to the first dielectric layers 19, and the semiconductor layer may refer to the preliminary horizontal layer 14A.

According to another embodiment of the present disclosure, each of the cell molds CM may include an ONSNO (Oxide-Nitride-Silicon-Nitride-Oxide) stack. The ONSNO stack may refer to a structure in which first silicon oxide, first silicon nitride, a monocrystalline silicon layer, second silicon nitride, and second silicon oxide are sequentially stacked. The first and second silicon oxide may correspond to the second dielectric layers 20, and the first and second silicon nitride may correspond to the first dielectric layers 19, and the monocrystalline silicon layer may correspond to the preliminary horizontal layers 14A.

Through a series of the processes according to FIGS. 4A to 9C, the sub-stacks SB1, SB2, SB3 of the stack body SB may be replaced with cell molds CM. The first layers 12A, the second layers 13, and the third layers 12B may be replaced with the first dielectric layers 19 and the second dielectric layers 20. The fourth layers 14 may become the preliminary horizontal layers 14A. The first dielectric layers 19 may be referred to as trimming target layers.

FIG. 10A is a plan view illustrating a structure with isolation openings 22A and 22B for describing a method for forming the isolation openings 22A and 22B. FIG. 10B is a cross-sectional view illustrating a structure taken along line B-B′ illustrated in FIG. 10A. FIG. 10C is a cross-sectional view illustrating a structure taken along line A1-A1′ illustrated in FIG. 10A.

As illustrated in FIGS. 10A to 10C, the first and second sacrificial cell isolation layers 16A and 16B may be removed to form the isolation openings 22A and 22B. While the first and second sacrificial cell isolation layers 16A and 16B are removed, the first and second sacrificial pillar structures SV1 and SV2 may be covered by a mask layer (not illustrated). The side surfaces of the preliminary horizontal layers 14A and first dielectric layers 19 may be exposed by the isolation openings 22A and 22B in a line B-B′ direction.

FIG. 11A is a plan view illustrating a structure with horizontal layers 14B for describing a method for forming the horizontal layers 14B. FIG. 11B is a cross-sectional view illustrating a structure taken along line B-B′ illustrated in FIG. 11A. FIG. 11C is a cross-sectional view illustrating a structure taken along line A1-A1′ illustrated in FIG. 11A.

As illustrated in FIGS. 11A to 11C, the side surfaces of the preliminary horizontal layers 14A may be trimmed through the isolation openings 22A and 22B. Accordingly, the horizontal layers 14B may be formed. Horizontal layer level gaps 14R may be formed on both sides of the horizontal layers 14B. The horizontal layer level gaps 14R and the horizontal layers 14B may be disposed between the first dielectric layers 19. The horizontal layers 14B may be referred to as trimmed horizontal layer patterns.

While the horizontal layers 14B are formed, the surface of the lower structure 11, for example, the bottom surfaces of the isolation openings 22A and 22B, may be recessed to a predetermined depth.

The horizontal layers 14B may be disposed between the sacrificial pillar structures SV1 and SV2 in the second direction D2. From a top view perspective, the horizontal layers 14B may each have a cross shape. The horizontal layers 14B may each have a cross shape with a smaller size than the preliminary horizontal layers 14A. The preliminary horizontal layers 14A may each have a shape in which a plurality of cross shapes are merged, and the horizontal layers 14B may each have a shape in which the cross shapes are individually isolated in the third direction D3. The horizontal layer level gaps 14R may be formed between the horizontal layers 14B disposed in the third direction D3. The first and second sacrificial pillar structures SV1 and SV2 may be disposed between the horizontal layers 14B in the second direction D2.

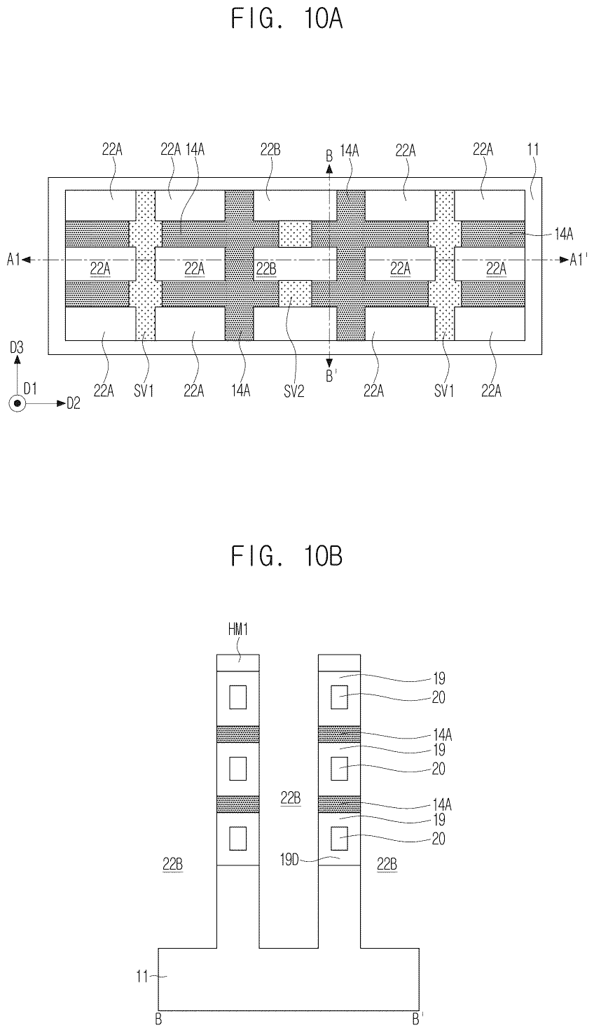

FIG. 12A is a plan view illustrating a structure with a horizontal layer level spacer 23 for describing a method for forming the horizontal layer level spacer 23. FIG. 12B is a cross-sectional view illustrating a structure taken along line B-B′ illustrated in FIG. 12A. FIG. 12C is a cross-sectional view illustrating a structure taken along line A1-A1′ illustrated in FIG. 12A.

As illustrated in FIGS. 12A to 12C, the horizontal layer level spacer 23 may be formed on the sidewalls of the horizontal layers 14B. The horizontal layer level spacer 23 may include a dielectric material, for example, silicon oxide. The horizontal layer level spacer 23 may fill the horizontal layer level gap 14R. The horizontal layers 14B disposed in the third direction D3 may be isolated from each other by the horizontal layer level spacer 23.

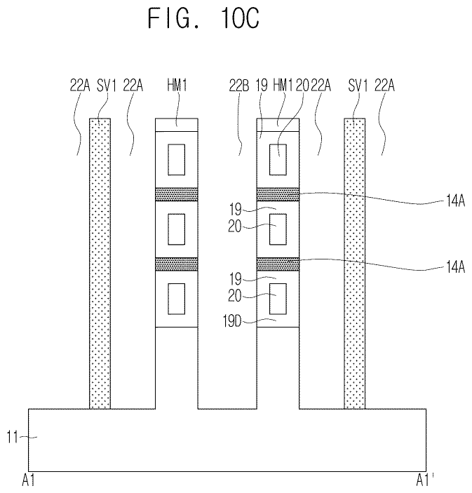

FIG. 13A is a plan view illustrating a structure with first dielectric layers 19A for describing a method for trimming the first dielectric layers 19A. FIG. 13B is a cross-sectional view illustrating a structure taken along line B-B′ illustrated in FIG. 13A. FIG. 13C is a cross-sectional view illustrating a structure taken along line A1-A1′ illustrated in FIG. 13A.

As illustrated in FIGS. 13A to 13C, a portion of each of the first dielectric layers 19 may be horizontally trimmed through the isolation openings 22A and 22B. After the trimming process, the first dielectric layers 19 may remain as indicated by reference numeral “19A”. Accordingly, when viewed from line B-B′, each of the second dielectric layers 20 may be disposed between a pair of the first dielectric layers 19A.

According to FIGS. 11A to 13C, the width of each of the first dielectric layers 19A in the third direction D3 may be greater than that of each of the horizontal layers 14B. Specifically, the trimming depth of each of the first dielectric layers 19 in the third direction D3 may be smaller than that of each of the preliminary horizontal layers 14A.

A pair of first dielectric layers 19A may vertically overlap with one horizontal layer 14B. The first dielectric layers 19A which are trimmed may be referred to as trimmed first dielectric layers.

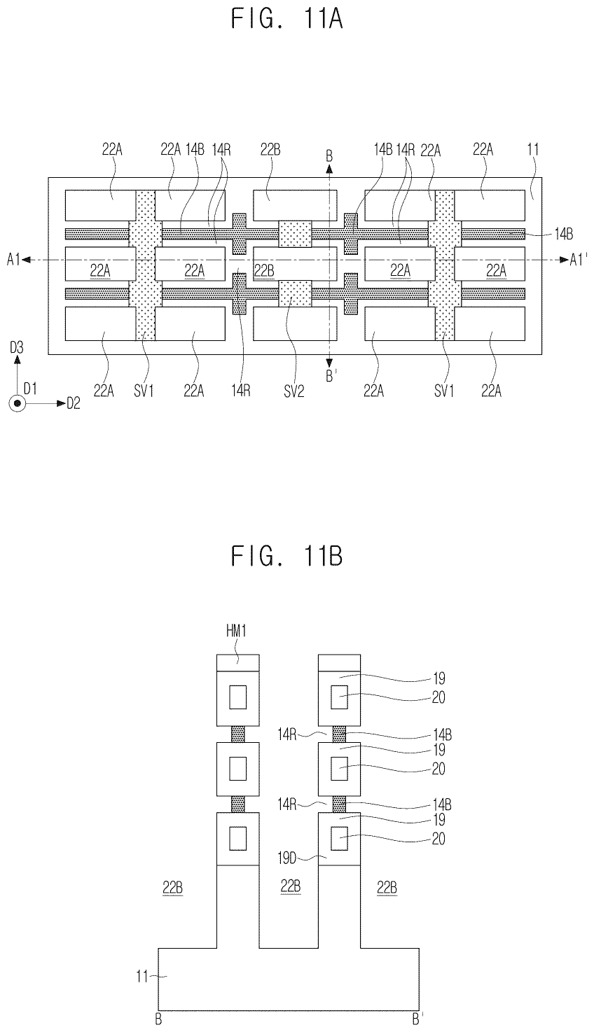

FIG. 14A is a plan view illustrating a structure with cell isolation layers 24A and 24B for describing a method for forming the cell isolation layers 24A and 24B. FIG. 14B is a cross-sectional view illustrating a structure taken along line B-B′ illustrated in FIG. 14A. FIG. 14C is a cross-sectional view illustrating a structure taken along line A1-A1′ illustrated in FIG. 14A. FIG. 14A is a plan view illustrating a structure with the first dielectric layers 19A to describe the method for forming the cell isolation layers 24A and 24B.

As illustrated in FIGS. 14A to 14C, the cell isolation layers 24A and 24B may be formed to fill the isolation openings 22A and 22B. The cell isolation layers 24A and 24B may include first cell isolation layers 24A and second cell isolation layers 24B. The first cell isolation layers 24A and the second cell isolation layers 24B may include the same material. The first cell isolation layers 24A and the second cell isolation layers 24B may be formed of a dielectric material. For example, the first cell isolation layers 24A and the second cell isolation layers 24B may include silicon oxide, silicon nitride, silicon carbon oxide, silicon carbon nitride, or a combination thereof. From a top view perspective, an outermost material of the first cell isolation layers 24A and second cell isolation layers 24B may include silicon carbon oxide.

Forming the first cell isolation layers 24A and the second cell isolation layers 24B may include forming a dielectric material that fills the isolation openings 22A and 22B and planarizing the dielectric material so that the surface of the uppermost-level first dielectric layer 19 is exposed. The first cell isolation layers 24A and the second cell isolation layers 24B may have different sizes or volumes. The first cell isolation layers 24A and the second cell isolation layers 24B may have a dual structure of silicon oxide and silicon carbon oxide. For example, silicon carbon oxide may be formed or deposited after silicon oxide is deposited. According to another embodiment of the present disclosure, the first and second cell isolation layers 24A and 24B may include an embedded air gap. The line-shape first sacrificial pillar structure SV1 may be disposed between the first cell isolation layers 24A, and the hole-shape second sacrificial pillar structure SV2 may be disposed between the second cell isolation layers 24B.

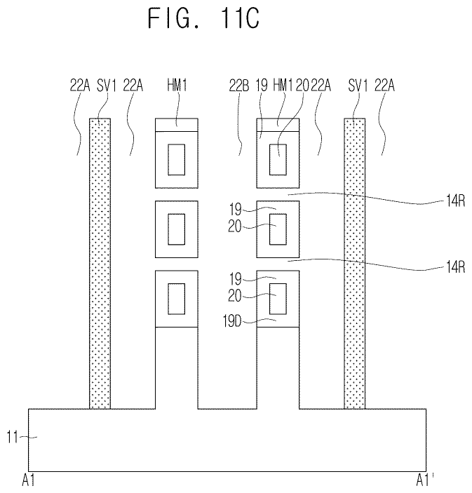

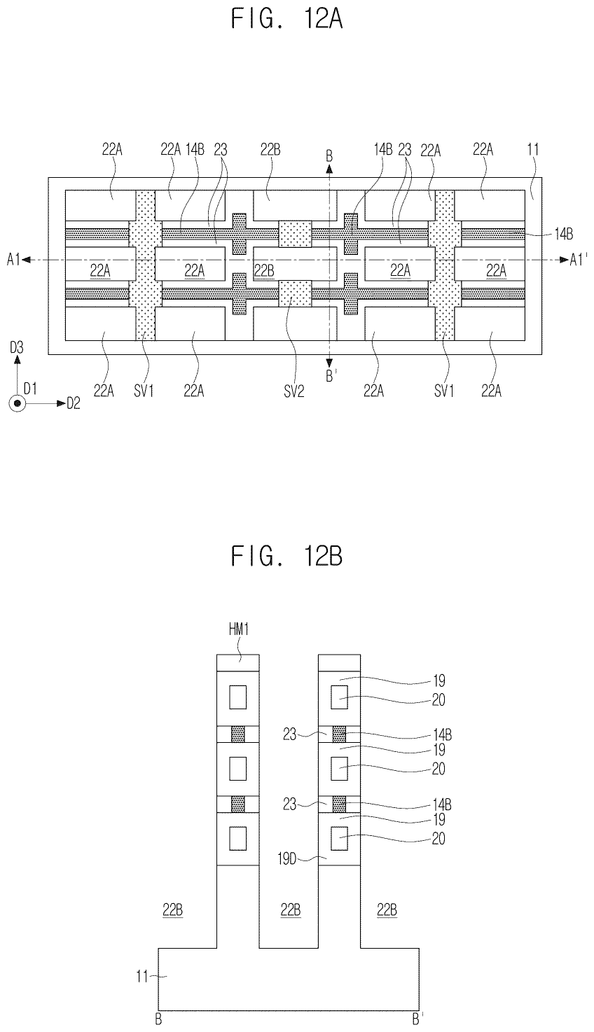

FIG. 15 is a plan view illustrating a structure with line-shape vertical sacrificial structures 29 for describing a method for forming the line-shape vertical sacrificial structures 29, and FIGS. 16A to 16D are cross-sectional views illustrating the structure taken along line A-A′ illustrated in FIG. 15.

As illustrated in FIG. 16A, the first hard mask layer HM1 and the uppermost-level first dielectric layer 19A may be removed to form a hard mask layer level recess 25.

As illustrated in FIG. 16B, a top dielectric layer 26 may be formed to fill the hard mask layer level recess 25. The top dielectric layer 26 may include silicon oxide.

As illustrated in FIG. 16C, the first sacrificial pillar structures SV1 may be removed to form initial line-shape vertical openings 27. The first dielectric layers 19A and the dummy dielectric layer 19D (shown in FIG. 16A) may be exposed by the initial line-shape vertical openings 27.

Subsequently, the second dielectric layers 20 may be horizontally recessed.

Subsequently, the first dielectric layers 19A and the dummy dielectric layer 19D may be selectively and horizontally recessed. Accordingly, first dielectric layer patterns 19B and dielectric layer level recesses 28 may be formed. Portions of the horizontal layers 14B may be exposed by the dielectric layer level recesses 28.

As illustrated in FIG. 16D, the line-shape vertical sacrificial structures 29 may be formed to fill the dielectric layer level recesses 28 and the initial line-shape vertical openings 27. The line-shape vertical sacrificial structures 29 may include a dielectric material. The line-shape vertical sacrificial structures 29 may include silicon oxide, silicon nitride, titanium nitride, amorphous carbon, or a combination thereof.

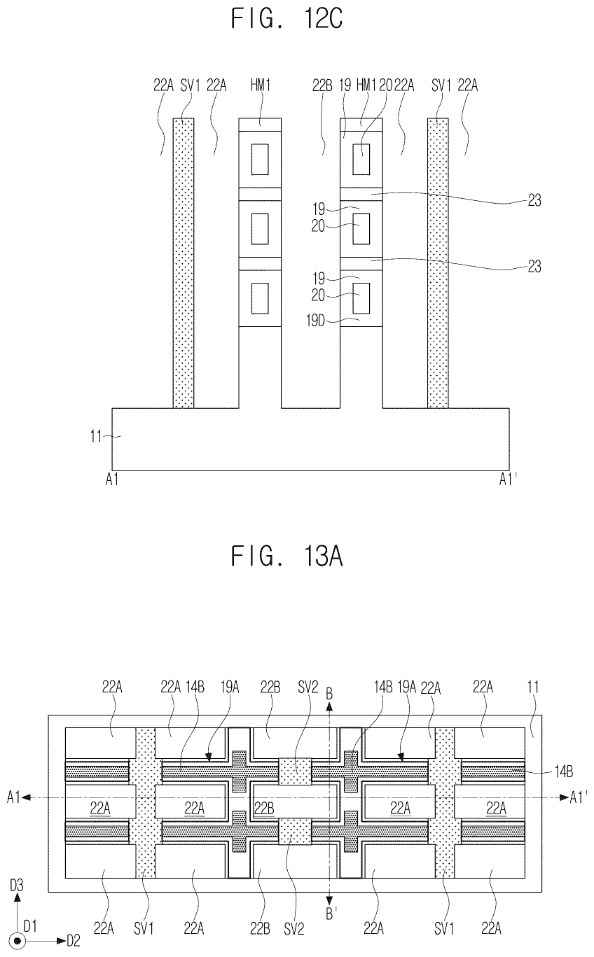

FIG. 17A is a plan view illustrating a structure with a vertical level path 30 for describing a method for forming the vertical level path 30. FIG. 17B is a cross-sectional view illustrating a structure taken along line A-A′ illustrated in FIG. 17A.

As illustrated in FIGS. 17A and 17B, the sacrificial pillar 21 of the second sacrificial pillar structure SV2 may be removed to form the vertical level path 30.

Subsequently, the dummy dielectric layer 19D below the vertical level path 30 may be removed to form a lower level gap 19D′.

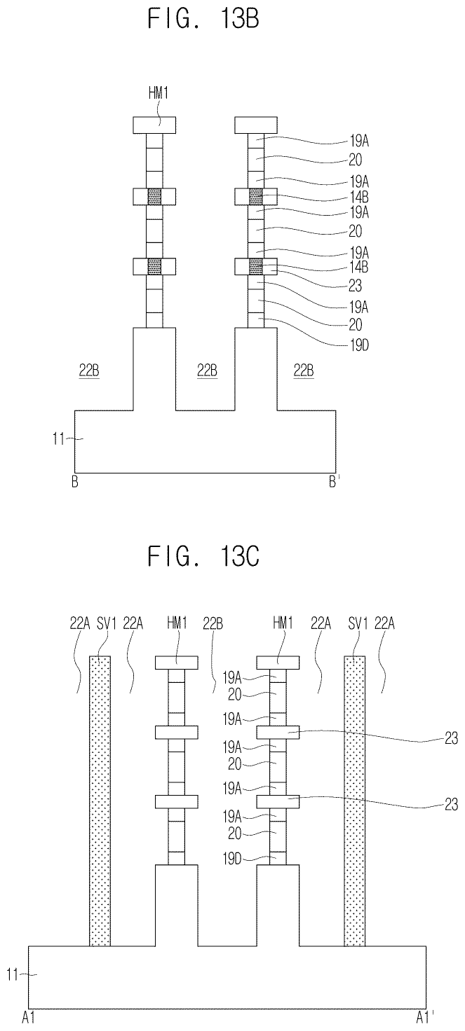

FIG. 18A is a plan view illustrating a structure with a hole-shape vertical opening 32 for describing a method for forming the hole-shape vertical opening 32. FIG. 18B is a cross-sectional view illustrating a structure taken along line A-A′ illustrated in FIG. 18A.

As illustrated in FIGS. 18A and 18B, the second dielectric layers 20 may be cut 31 through the vertical level path 30 to form the hole-shape vertical opening 32.

Subsequently, the first passivation layer BF1 may be formed to fill the lower level gap 19D′. The first passivation layer BF1 may include silicon oxide. Forming the first passivation layer BF1 may include depositing silicon oxide to fill the lower level gap 19D′ and etching the silicon oxide. Subsequently, the surface of the lower structure 11 may be oxidized to form the second passivation layer BF2.

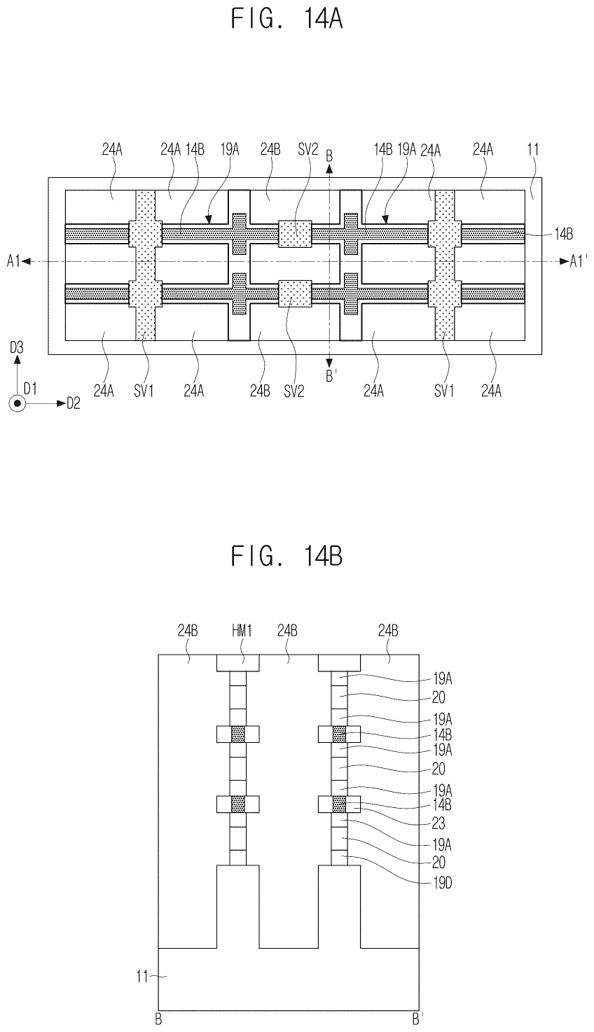

FIG. 19A is a plan view illustrating a structure with horizontal level recesses 33 for describing a method for forming the horizontal level recesses 33. FIG. 19B is a cross-sectional view illustrating a structure taken along line A-A′ illustrated in FIG. 19A.

As illustrated in FIGS. 19A and 19B, the first dielectric layer patterns 19B may be removed to form the horizontal level recesses 33. Portions of the horizontal layers 14B may be exposed by the horizontal level recesses 33.

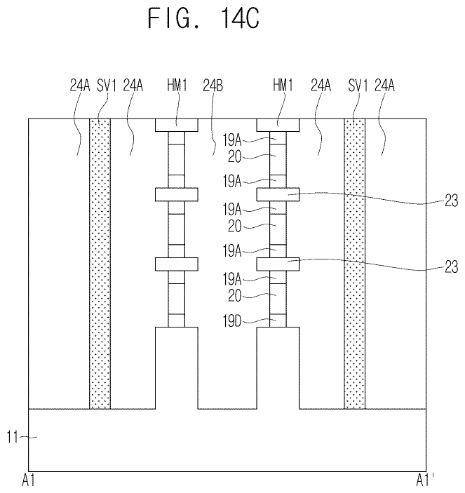

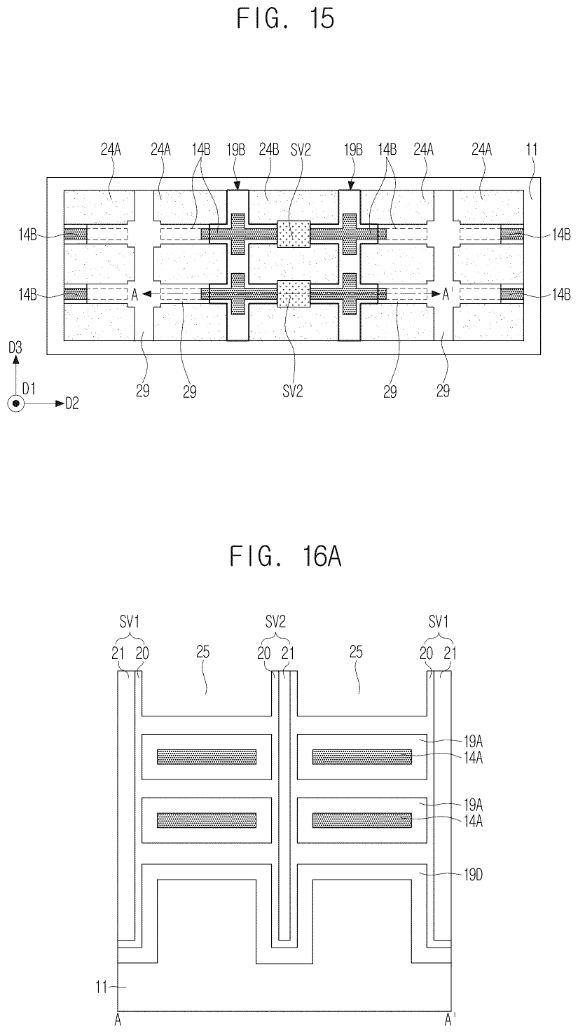

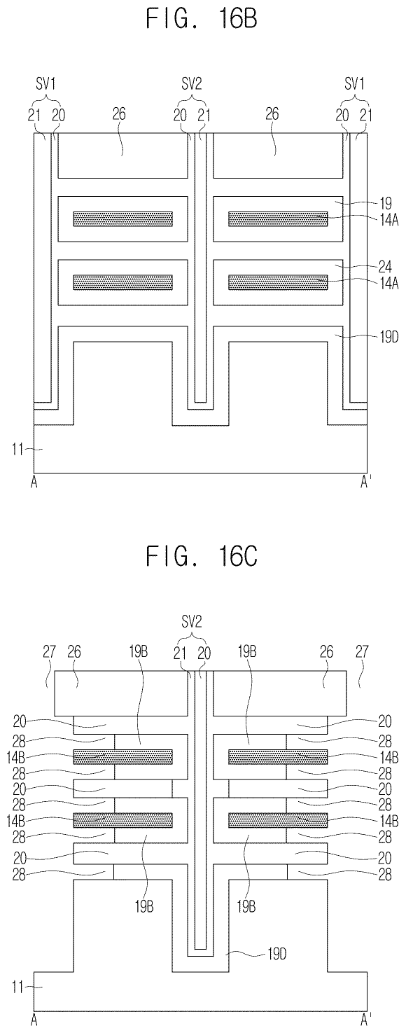

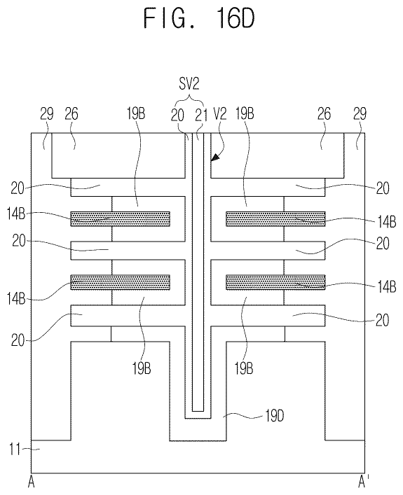

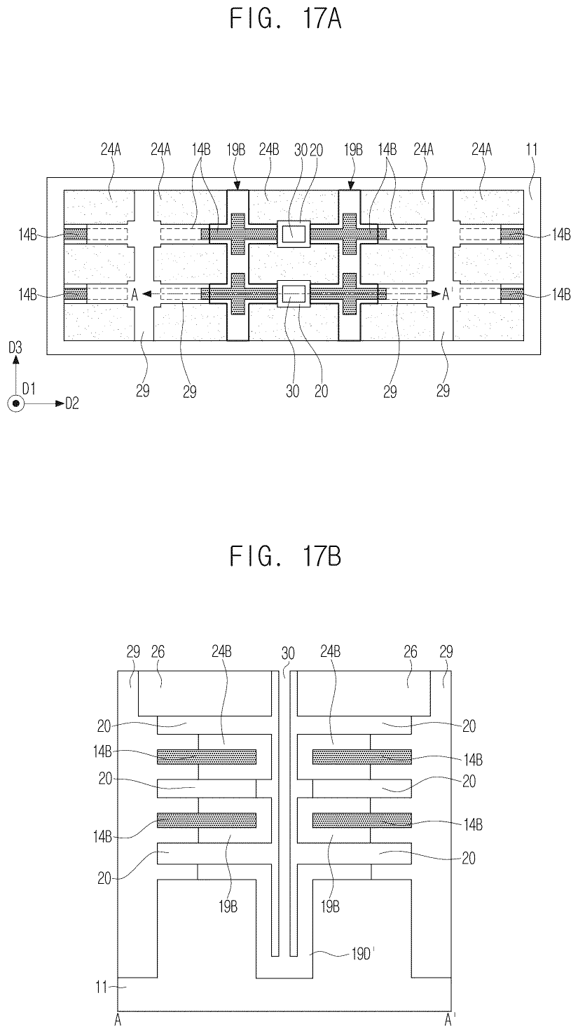

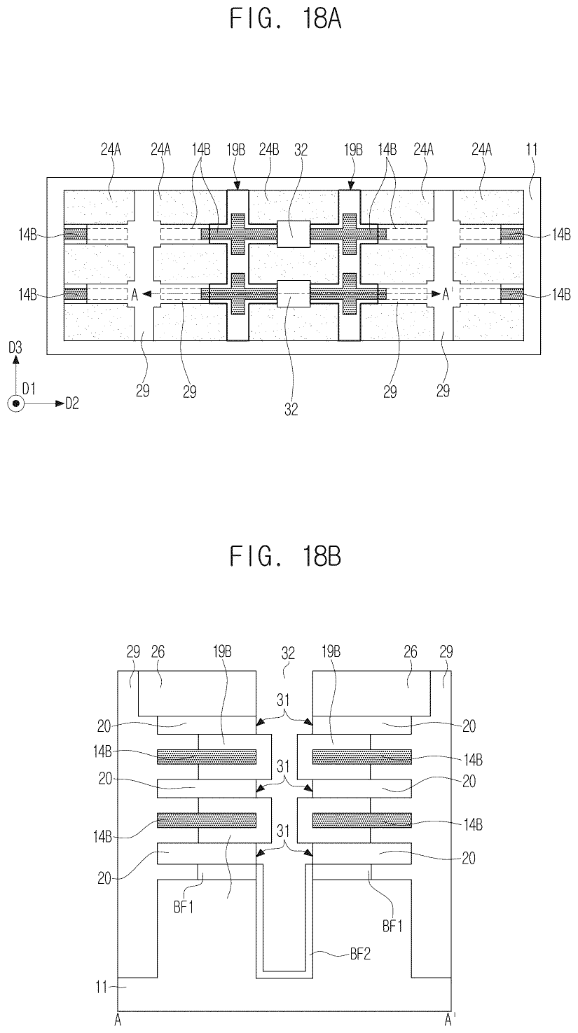

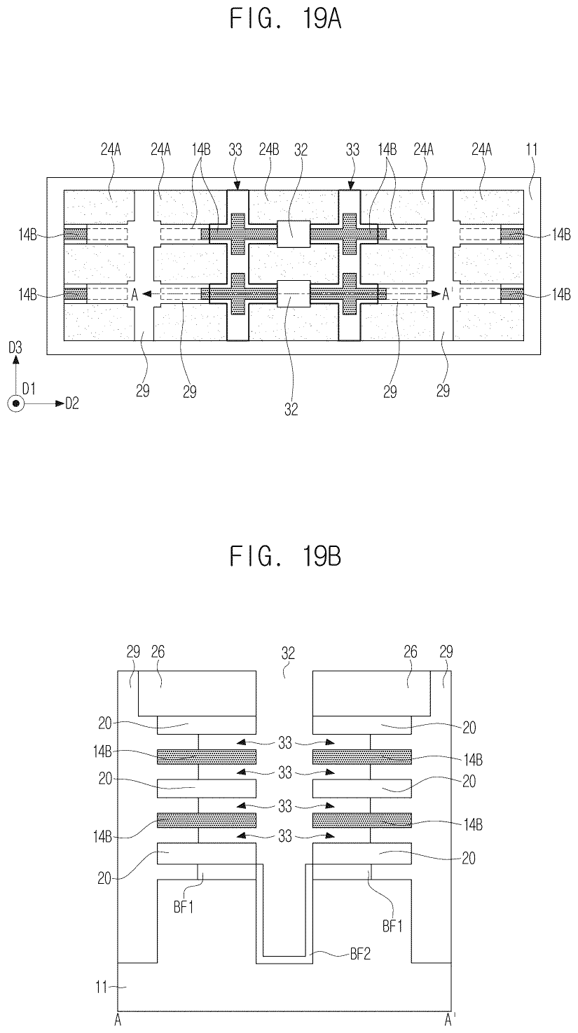

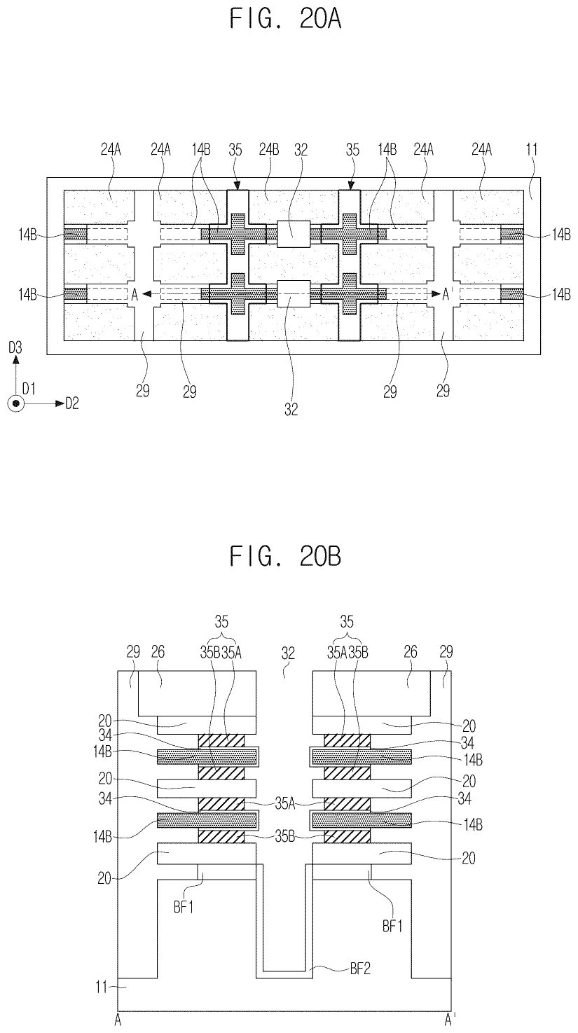

FIG. 20A is a plan view illustrating a structure with horizontal conductive lines 35 for describing a method for forming the horizontal conductive lines 35. FIG. 20B is a cross-sectional view illustrating a structure taken along line A-A′ illustrated in FIG. 20A.

As illustrated in FIGS. 20A and 20B, inter-level dielectric layers 34 may be formed on exposed portions of the horizontal layers 14B. The inter-level dielectric layers 34 may each include a gate dielectric layer. The inter-level dielectric layers 34 may be formed by oxidizing the surfaces of the horizontal layers 14B. According to another embodiment of the present disclosure, the inter-level dielectric layers 34 may be formed by a deposition process of silicon oxide.

The inter-level dielectric layers 34 may each include silicon oxide, silicon nitride, metal oxide, metal oxynitride, metal silicate, a high-k material, a ferroelectric material, an anti-ferroelectric material, or a combination thereof. The inter-level dielectric layers 34 may each include SiO₂, Si₃N₄, HfO₂, Al₂O₃, ZrO₂, AlON, HfON, HfSiO, HfSiON, or a combination thereof.

Subsequently, the horizontal conductive lines 35 may be formed to fill the horizontal level recesses 33 on the inter-level dielectric layers 34. Forming the horizontal conductive lines 35 may include depositing a conductive material filling the horizontal level recesses 33 on the inter-level dielectric layers 34 and etching back the conductive material. Each of the horizontal conductive lines 35 may include a pair of first and second horizontal conductive lines 35A and 35B that face each other with the horizontal layer 14B interposed therebetween. The first and second horizontal conductive lines 35A and 35B may include a metal-base material, a semiconductor material, or a combination thereof. The first and second horizontal conductive lines 35A and 35B may include titanium nitride, tungsten, polysilicon, molybdenum, molybdenum nitride, or a combination thereof. For example, the first and second horizontal conductive lines 35A and 35B may include a TiN/W stack in which titanium nitride and tungsten are sequentially stacked. The horizontal conductive lines 35A and 35B may include an N-type work function material or a P-type work function material. The N-type work function material may have a low work function of approximately 4.5 eV or lower, and the P-type work function material may have a high work function of approximately 4.5 eV or higher.

The horizontal conductive line 35 may correspond to the second conductive line DWL as illustrated in FIGS. 1A to 1D, and the first and second horizontal conductive lines 35A and 35B may correspond to the upper horizontal line G1 and the lower horizontal line G2, respectively. As illustrated in FIGS. 1A to 1D, each of the first and second horizontal conductive lines 35A and 35B may have a cross shape and include the channel overlapping portion WLP.

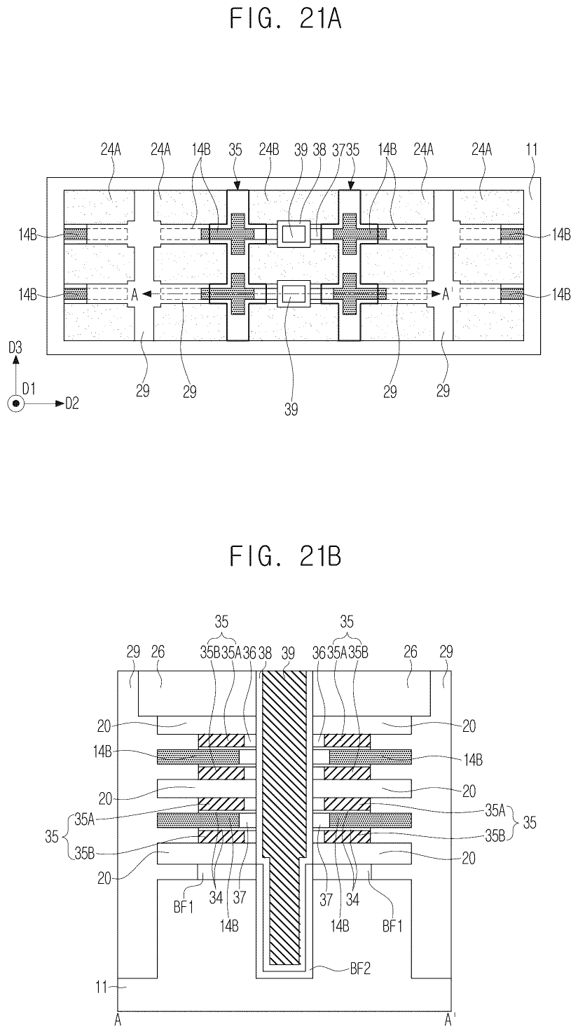

FIG. 21A is a plan view illustrating a structure with vertical conductive lines 39 for describing a method for forming the vertical conductive lines 39. FIG. 21B is a cross-sectional view illustrating a structure taken along line A-A′ illustrated in FIG. 21A.

As illustrated in FIGS. 21A and 21B, a first capping layer 36 may be formed on one side surface of each of the horizontal conductive lines 35. The first capping layer 36 may include silicon oxide, silicon nitride, or a combination thereof. A deposition process and an etch-back process of a capping material may be performed to form the first capping layer 36. While or after the first capping layer 36 is formed, a portion of the inter-level dielectric layer 34 may be removed, and a first edge portion of each of the horizontal layers 14B may be exposed.

Subsequently, the vertical conductive line 39 coupled to the first edge portion of each of the horizontal layers 14B may be formed. The vertical conductive line 39 may fill the hole-shape vertical opening 32. The vertical conductive line 39 may be coupled in common to the horizontal layers 14B. The vertical conductive line 39 may include titanium nitride, tungsten, or a combination thereof. The vertical conductive line 39 may include a bit line.

Before the vertical conductive line 39 is formed, a first doped region 37 and a first contact node 38 may be formed. The first doped region 37 may be formed in the first edge portion of each of the horizontal layers 14A. Forming the first doped region 37 may include depositing polysilicon that is doped with an N-type impurity, performing a heat treatment, and removing the doped polysilicon. The first doped region 37 may include an impurity diffused from the doped polysilicon. According to another embodiment of the present disclosure, the first doped region 37 may be formed by a process of doping an impurity.

The first contact node 38 may include doped polysilicon. The first doped region 37 may include an impurity diffused from the first contact node 38.

The vertical conductive line 39 may correspond to the first conductive line BL as illustrated in FIGS. 1A to 1D.

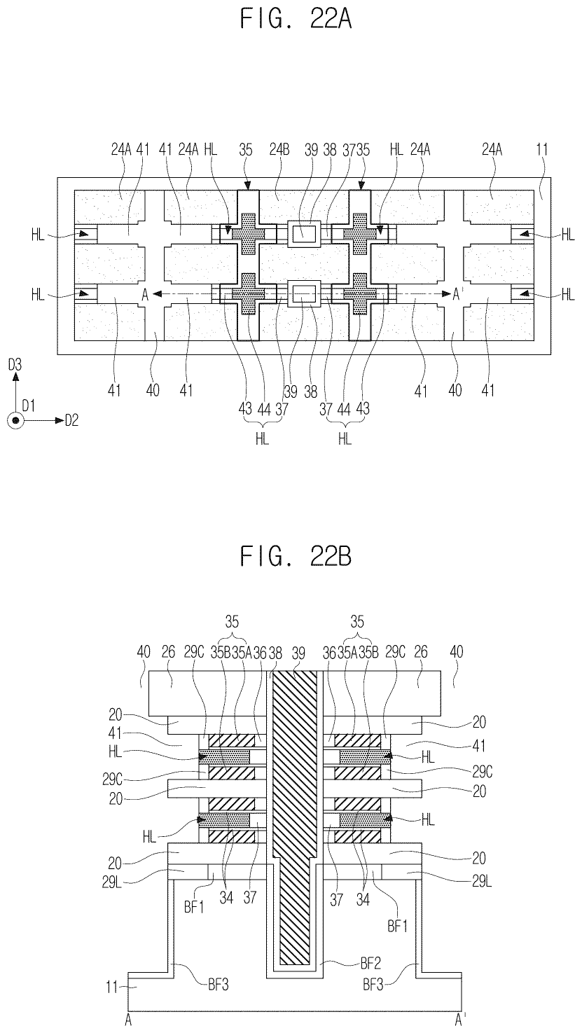

FIG. 22A is a plan view illustrating a structure with line-shape vertical openings 40 and storage openings 41 for describing a method for forming the line-shape vertical openings 40 and the storage openings 41. FIG. 22B is a cross-sectional view illustrating a structure taken along line A-A′ illustrated in FIG. 22A.

As illustrated in FIGS. 22A and 22B, a portion of the line-shape vertical sacrificial structure 29 may be removed to form the line-shape vertical openings 40 that expose second edge portions of the horizontal layers 14B. One side surfaces of the horizontal layers 14B may be exposed by the line-shape vertical openings 40. The line-shape vertical openings 40 may be identical in shape to the line-shape vertical sacrificial structure 29. That is, the line-shape vertical openings 40 may horizontally extend in the third direction D3.

Consequently, the line-shape vertical openings 40 may each have a structure formed by line patterning of the stack body.

Subsequently, a third passivation layer BF3 may be formed on the surface of the lower structure 11. The third passivation layer BF3 may include silicon oxide.

Subsequently, the second edge portions of the horizontal layers 14B may be horizontally recessed in the second direction D2. Accordingly, the horizontal layers may remain as indicated by reference numeral “HL”.

Subsequently, remaining line-shape vertical sacrificial structure 29 may be selectively recessed to form a second capping layer 29C. Accordingly, the line-shape vertical openings 40 may horizontally extend. The second capping layer 29C may include silicon oxide, silicon nitride, or a combination thereof. As the second capping layer 29C is formed, the storage openings 41 may be formed. The storage openings 41 may be referred to as capacitor openings.

Each of the horizontal layers HL may include a first edge and a second edge. The first edge may refer to a portion coupled to the first contact node 38 and the vertical conductive line 39, and the second edge may refer to a portion exposed by each of the storage openings 41.

The storage openings 41 may be disposed between the second dielectric layers 20. The second capping layers 29C may be disposed on the lower and upper portions of the horizontal layer HL, respectively. In particular, as shown in FIG. 22B, the second capping layers 29C may be disposed on the lower and upper end portions of the horizontal layer HL.

As described above, forming the horizontal layer HL and the storage openings 41 may include forming the line-shape vertical openings 40, recessing the horizontal layers 14B, and forming the second capping layer 29C.

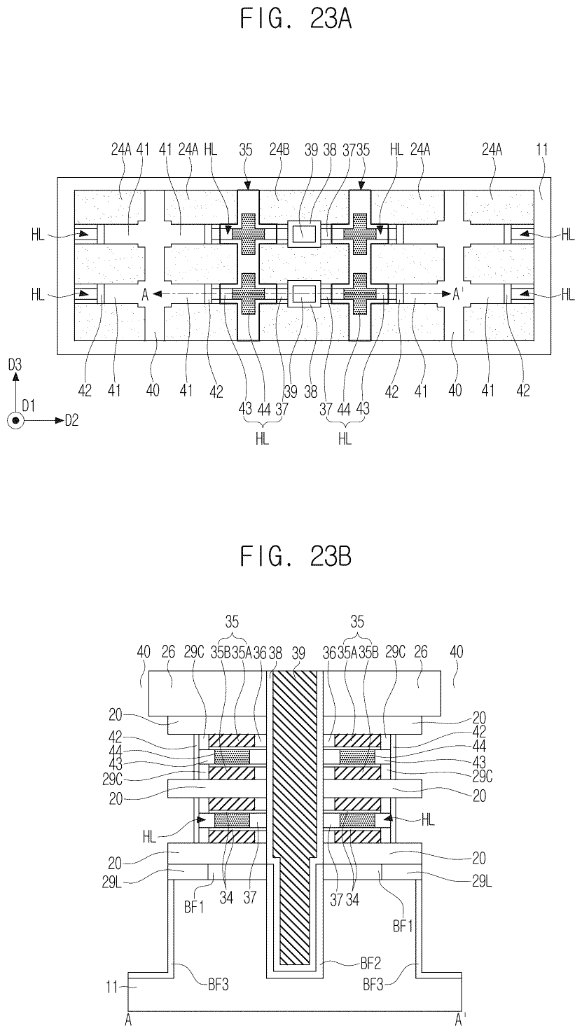

FIG. 23A is a plan view illustrating a structure with a second contact node 42 for describing a method for forming the second contact node 42. FIG. 23B is a cross-sectional view illustrating a structure taken along line A-A′ illustrated in FIG. 23A.

As illustrated in FIGS. 23A and 23B, a second doped region 43 may be formed in the second edge of the horizontal layer HL. Forming the second doped region 43 may include depositing polysilicon that is doped with an N-type impurity, performing a heat treatment, and removing the doped polysilicon. The second doped region 43 may include an impurity that is diffused from the doped polysilicon. According to another embodiment of the present disclosure, after the heat treatment, the doped polysilicon may remain.

Subsequently, the second contact node 42 may be formed on the second edge of the horizontal layer HL. The second contact node 42 may include doped polysilicon. The second doped region 43 may include an impurity that is diffused from the second contact node 42.

The horizontal layer HL may include the first doped region 37, the second doped region 43, and a channel 44 that are horizontally disposed in the second direction D2. The channel 44 may be defined between the first doped region 37 and the second doped region 43. The channel 44 may vertically overlap with the horizontal conductive line 35. As illustrated in FIGS. 1A to 1C, the horizontal layer HL may have a cross shape, and the channel 44 may also have a cross shape.

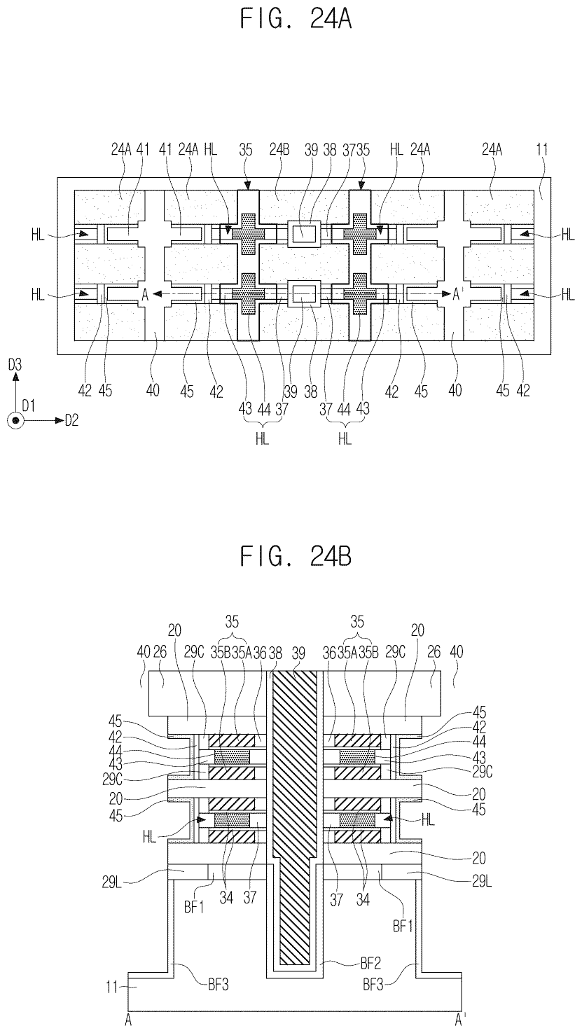

FIG. 24A is a plan view illustrating a structure with a first electrode 45 for describing a method for forming the first electrode 45. FIG. 24B is a cross-sectional view illustrating a structure taken along line A-A′ illustrated in FIG. 24A.

As illustrated in FIGS. 24A and 24B, the first electrode 45 of the data storage element may be formed on the second contact node 42. The first electrode 45 may have a horizontally oriented cylindrical shape.

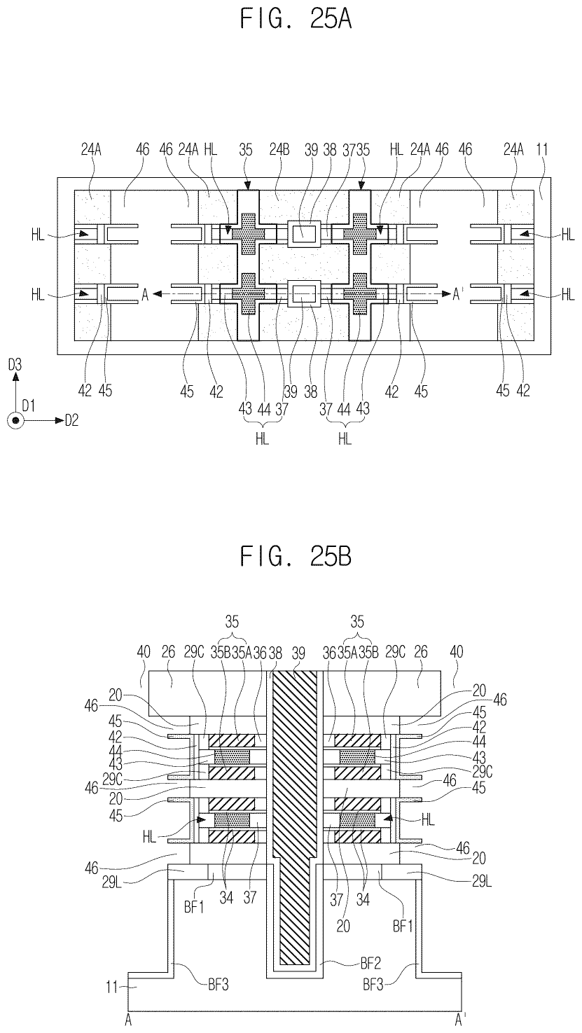

FIG. 25A is a plan view illustrating a structure with the first electrode 45 for describing a method for exposing the outer walls of the first electrode 45. FIG. 25B is a cross-sectional view illustrating a structure taken along line A-A′ illustrated in FIG. 25A.

As illustrated in FIGS. 25A and 25B, the second dielectric layers 20 may be horizontally recessed as indicated generally with numeral 46 to expose the outer walls of the first electrodes 45.

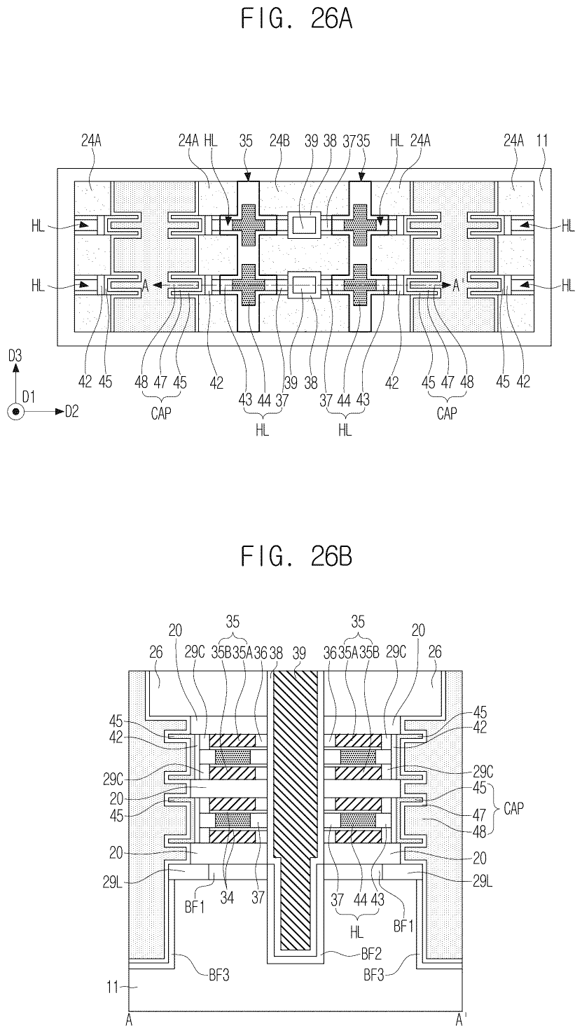

FIG. 26A is a plan view illustrating a structure with a dielectric layer 47 and a second electrode 48 for describing a method for forming the dielectric layer 47 and the second electrode 48. FIG. 26B is a cross-sectional view illustrating a structure taken along line A-A′ illustrated in FIG. 26A.

As illustrated in FIGS. 26A and 26B, the dielectric layer 47 and the second electrode 48 may be sequentially formed on the first electrode 45. The first electrode 45, the dielectric layer 47 and the second electrode 48 may become a data storage element CAP.

The first electrode 45 may include an inner space and a plurality of outer surfaces, and the inner space of the first electrode 45 may include a plurality of inner surfaces. The outer surfaces of the first electrode 45 may include a vertical outer surface and a plurality of horizontal outer surfaces. The vertical outer surface of the first electrode 45 may vertically extend in the first direction D1, and the horizontal outer surfaces of the first electrode 45 may horizontally extend in the second direction D2 or the third direction D3. The inner space of the first electrode 45 may be a three-dimensional space. The dielectric layer 47 may conformally cover the inner and outer surfaces of the first electrode 45. The second electrode 48 may be disposed in the inner space of the first electrode 45 on the dielectric layer 47. Some of the outer surfaces of the first electrode 45 may be electrically coupled to the second doped region 43 of the horizontal layer HL.

The first electrode 45 may have a cylindrical shape. The cylindrical shape of the first electrode 45 may include cylindrical inner surfaces and cylindrical outer surfaces. Some of the cylindrical outer surfaces of the first electrode 45 may be electrically coupled to the second doped region 43 of the horizontal layer HL. The dielectric layer 47 and the second electrode 48 may be disposed on the cylindrical inner surfaces of the first electrode 45.

The second electrode 48 may extend vertically in the first direction D1 and horizontally in the third direction D3.

The first electrode 45 and the second electrode 48 may include metal, noble metal, metal nitride, conductive metal oxide, conductive noble metal oxide, metal carbide, metal silicide, or a combination thereof. For example, the first electrode 45 and the second electrode 48 may include titanium (Ti), titanium nitride (TIN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TIN) stack, or a combination thereof. The second electrode 48 may include a combination of a metal, a metal-based material and a silicon-based material. For example, the second electrode 48 may be a stack (TiN/SiGe/WN) of titanium nitride/silicon germanium/tungsten nitride. In the titanium nitride/silicon germanium/tungsten nitride (TiN/SiGe/WN) stack, silicon germanium may be a gap-fill material that fills the inner space of the first electrode 45, and titanium nitride (TiN) may serve as the second electrode 48 of the data storage element CAP, and tungsten nitride may be a low-resistance material.

The dielectric layer 47 may be referred to as a capacitor dielectric layer or a memory layer. The dielectric layer 47 may include silicon oxide, silicon nitride, a high-k material, a ferroelectric material, an anti-ferroelectric material, a perovskite material, or a combination thereof. For example, the dielectric layer 47 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). For example, the dielectric layer 47 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack.

According to another embodiment of the present disclosure, an interface control layer may be further formed between the first electrode 45 and the dielectric layer 47 to reduce leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 48 and the dielectric layer 47.

According to an embodiment of the present disclosure, the line-shape vertical opening 40 may be formed in advance to form the storage opening 41 where the first electrode 45 is to be formed. Line patterning may be applied to form the line-shape vertical opening 40. Since the line patterning is applied, cleaning process loading and deposition process loading for forming the first electrode 45 may be reduced, which makes it possible to increase a yield.

According to another embodiment of the present disclosure, the first and second sacrificial openings V1′ and V2′ may be formed by the line patterning. As the first and second sacrificial openings V1′ and V2′ are formed by the line patterning, the vertical conductive line 39 may be formed to have a horizontally spaced double structure. That is, one memory cell may include one vertical conductive line 39, and the vertical conductive lines 39 of horizontally neighboring memory cells may be spaced apart from each other.

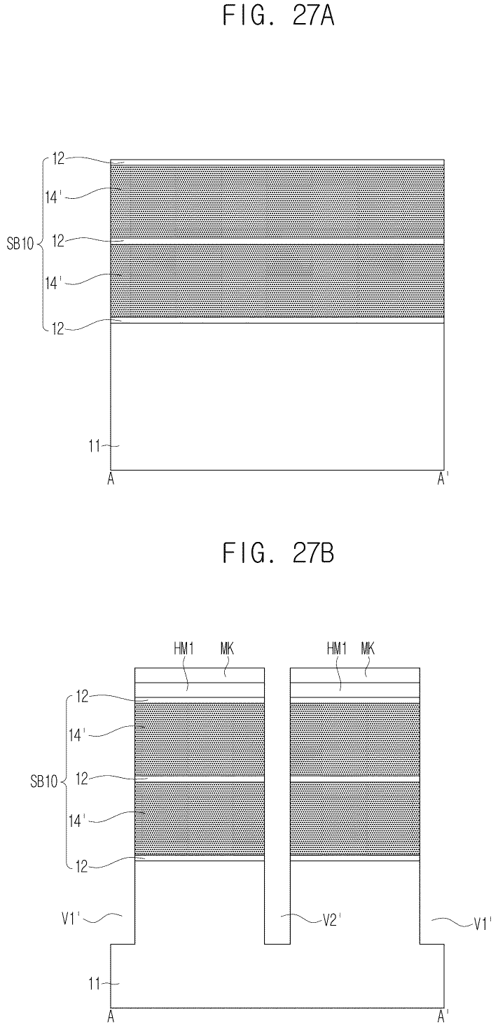

FIGS. 27A and 27b are cross-sectional views illustrating a semiconductor device formed according to a method for fabricating the semiconductor device in accordance with an embodiment of the present disclosure.

As illustrated in FIG. 27A, a stack body SB10 may be formed over a lower structure 11. The stack body SB10 may include an alternating stack of first semiconductor layers and second semiconductor layers. For example, the alternating stack may include a plurality of silicon germanium layers 12 that are alternately stacked on a plurality of monocrystalline silicon layers 14′ by an epitaxial growth process. The silicon germanium layers 12 may be sacrificial layers, and the monocrystalline silicon layers 14′ may be recess target layers. The silicon germanium layers 12 may correspond to the first layers 12A or the third layers 12B of FIGS. 4A and 4B, and the monocrystalline silicon layers 14′ may correspond to the fourth layers 14 of FIGS. 4A and 4B. Unlike the stack body SB of FIG. 4B, the stack body SB10 may be formed of an alternating stack of the silicon germanium layers 12 and the monocrystalline silicon layers 14′.

Subsequently, a series of processes as described above with reference to FIGS. 5A to 6C may be performed. Sacrificial isolation openings 15A and 15B and sacrificial cell isolation layers 16A′ and 16B may be formed in the stack body SB10.

As illustrated in FIGS. 7A to 7C and 27B, a first hard mask layer HM1 may be formed on the stack body SB10. Subsequently, a mask layer MK may be formed on the first hard mask layer HM1. The mask layer MK, which is an etch mask layer, may include a hard mask material, photoresist, or a combination thereof. As described with reference to FIGS. 7A, 7B, and 7C, the mask layer MK may include hole-shape opening patterns MH and line-shape opening patterns ML. The line-shape opening patterns ML may extend in the third direction D3 and intersect the preliminary first sacrificial cell isolation layers 16A′.

Subsequently, the stack body SB10 and the preliminary first sacrificial cell isolation layers 16A′ may be etched using the mask layer MK as an etch barrier. Accordingly, a plurality of sacrificial openings V1′ and V2′ may be formed in the stack body SB10. The sacrificial openings V1′ and V2′ may include first sacrificial openings V1′ and second sacrificial openings V2′. From a top view perspective, the first sacrificial openings V1′ may be line-shape openings, and the second sacrificial openings V2′ may be hole-shape openings. The first sacrificial openings V1′ may divide the preliminary first sacrificial cell isolation layers 16A′. Each of the preliminary first sacrificial cell isolation layers 16A′ may be divided into the first sacrificial cell isolation layers 16A by the first sacrificial openings V1′. Two second sacrificial openings V2′ may be disposed between the second sacrificial cell isolation layers 16B disposed adjacent to each other in the third direction D3.

As described above, line patterning and hole patterning may be performed simultaneously to form the sacrificial openings V1′ and V2′.

Subsequently to FIG. 27B, a series of processes as described with reference to FIGS. 8A to 8C may be performed to form the preliminary horizontal layer 14A. The preliminary horizontal layer 14A may be formed by a recess process of the monocrystalline silicon layers 14′ of FIG. 27B. After the silicon germanium layers 12 are removed, the recess process of the monocrystalline silicon layers 14′ may be performed.

Subsequently, a series of processes as described with reference to FIGS. 9A to 26B may be performed.

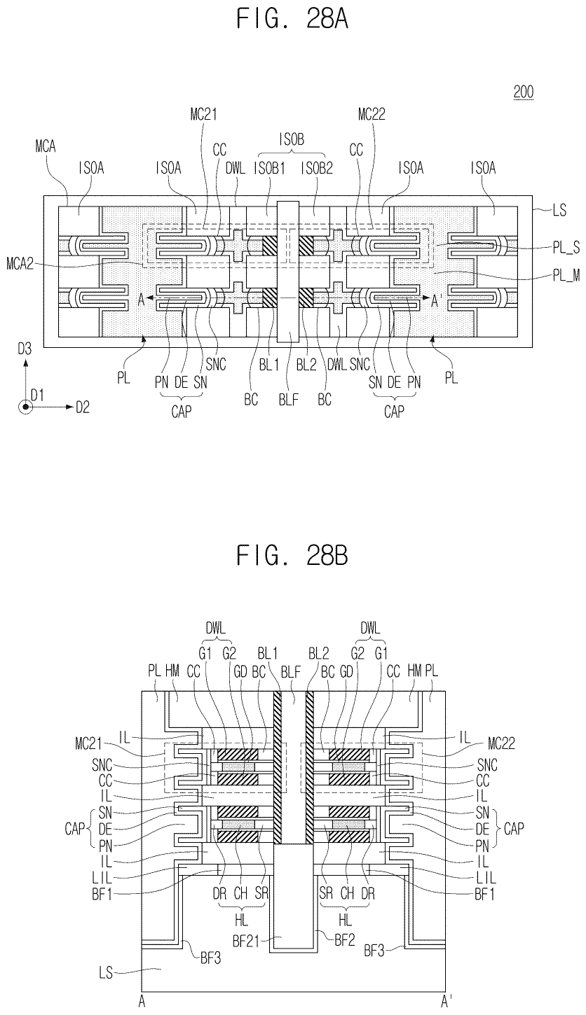

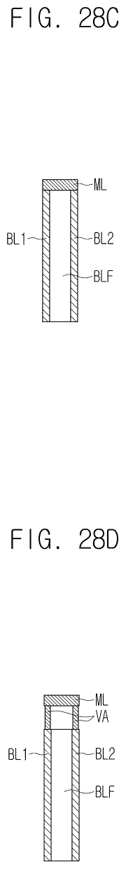

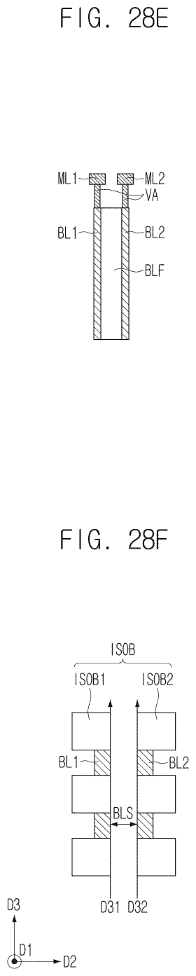

FIG. 28A is a schematic plan view illustrating a semiconductor device 200 in accordance with an embodiment of the present invention disclosure. FIG. 28B is a cross-sectional view illustrating the semiconductor device 200 taken along line A-A′ illustrated in FIG. 28A.

Referring to FIGS. 28A and 28B, the semiconductor device 200 may be similar to the semiconductor device 100 described above with reference to FIGS. 2, 3A and 3B. Hereinafter, detailed descriptions of overlapping components are provided with reference to FIGS. 2, 3A and 3B.

The semiconductor device 200 may include a memory cell array MCA. The memory cell array MCA may include a plurality of memory cells MC21 and MC22. The memory cells MC21 and MC22 may be the same as the memory cell MC described above with reference to FIGS. 1A to 1C.

The memory cell array MCA may include a three-dimensional array of the memory cells MC21 and MC22. The three-dimensional array of the memory cells MC21 and MC22 may include a column array of the memory cells MC21 and MC22 and a row array of the memory cells MC21 and MC22. The column array of the memory cells MC21 and MC22 may include the plurality of memory cells MC21 and MC22 stacked in a first direction D1, and the row array of the memory cells MC21 and MC22 may include the plurality of memory cells MC21 and MC22 horizontally disposed in a second direction D2 and a third direction D3. The memory cell array MCA may include sub-memory cell arrays MCA2 disposed adjacent to each other in the second direction D2. The sub-memory cell arrays MCA2 may include a three-dimensional array of first memory cells MC21 and a three-dimensional array of second memory cells MC22.

Each of the first memory cells MC21 may include a first vertical conductive line BL1, a horizontal layer HL, a second conductive line DWL, and a data storage element CAP. The horizontal layer HL may include a first doped region SR, a channel CH, and a second doped region DR. An inter-level dielectric layer GD may be disposed between the horizontal layer HL and the second conductive line DWL. The data storage element CAP may include a first electrode SN, a dielectric layer DE, and a second electrode PN. Each of the first memory cells MC21 may further include a second contact node SNC between the horizontal layer HL and the data storage element CAP. Although not illustrated, each of the first memory cells MC21 may further include a first contact node BLC between the horizontal layer HL and the first vertical conductive line BL1, as described with reference to FIG. 1B. The second electrodes PN of the first memory cells MC21 disposed adjacent to each other in the second direction D2 may be merged with each other and form a common plate PL.

The common plate PL may include a sharing portion PL_S that shares the first memory cells MC21 disposed adjacent to each other in the second direction D2 and a merge portion PL_M that is disposed between first cell isolation layers ISOA. The common plate PL may have a cross shape extending in the third direction D3 by a combination of a plurality of sharing portions PL_S and a plurality of merge portions PL_M. The first cell isolation layers ISOA may be disposed between the data storage elements CAP in the third direction D3. Second cell isolation layers ISOB may be disposed between the first vertical conductive lines BL1 in the third direction D3. The second conductive line DWL may be disposed between the first cell isolation layers ISOA and the second cell isolation layers ISOB in the second direction D2. The size of the first cell isolation layers ISOA may be larger than that of the second cell isolation layers ISOB.

The first cell isolation layers ISOA and the second cell isolation layers ISOB may be disposed between the first memory cells MC21 disposed adjacent to each other in the third direction D3. The first cell isolation layers ISOA may be disposed between the data storage elements CAP, and the second cell isolation layers ISOB may be disposed between the first vertical conductive lines BL1. Each of the first cell isolation layers ISOA may include first cell isolation segments ISOA1 and ISOA2. Each of the second cell isolation layers ISOB may include second cell isolation segments ISOB1 and ISOB2. The first electrode SN of the data storage element CAP may be disposed between the first cell isolation segments ISOA2. The first vertical conductive lines BL1 may be disposed between the second cell isolation segments ISOB1.

Each of the second memory cell MC22 may include a second vertical conductive line BL2, a horizontal layer HL, a second conductive line DWL, and a data storage element CAP. The horizontal layer HL may include a first doped region SR, a channel CH, and a second doped region DR. An inter-level dielectric layer GD may be disposed between the horizontal layer HL and the second conductive line DWL. The data storage element CAP may include a first electrode SN, a dielectric layer DE, and a second electrode PN. Each of the second memory cells MC22 may further include a second contact node SNC between the horizontal layer HL and the data storage element CAP. Although not illustrated, each of the second memory cells MC22 may further include a first contact node BLC between the horizontal layer HL and the second vertical conductive line BL2, as described with reference to FIG. 1B. The second electrodes PN of the second memory cells MC22 disposed adjacent to each other in the second direction D2 may be merged with each other and form a common plate PL.

The common plate PL may include a sharing portion PL_S that shares the second memory cells MC22 disposed adjacent to each other in the second direction D2 and a merge portion PL_M that is disposed between first cell isolation layers ISOA. The common plate PL may have a cross shape extending in the third direction D3 by a combination of a plurality of sharing portions PL_S and a plurality of merge portions PL_M. The first cell isolation layers ISOA may be disposed between the data storage elements CAP in the third direction D3. Second cell isolation layers ISOB may be disposed between the second vertical conductive lines BL2 in the third direction D3. The second conductive line DWL may be disposed between the first cell isolation layers ISOA and the second cell isolation layers ISOB in the second direction D2. The size of the first cell isolation layers ISOA may be larger than that of the second cell isolation layers ISOB.

The first cell isolation layers ISOA and the second cell isolation layers ISOB may be disposed between the second memory cells MC22 disposed adjacent to each other in the third direction D3. The first cell isolation layers ISOA may be disposed between the data storage elements CAP, and the second cell isolation layers ISOB may be disposed between the second vertical conductive lines BL2. Each of the first cell isolation layers ISOA may include first cell isolation segments ISOA1 and ISOA2. Each of the second cell isolation layers ISOB may include second cell isolation segments ISOB1 and ISOB2. The first electrode SN of the data storage element CAP may be disposed between the first cell isolation segments ISOA2. The second vertical conductive lines BL2 may be disposed between the second cell isolation segments ISOB1.

The three-dimensional array of the first memory cells MC21 may share the first vertical conductive line BL1, and the three-dimensional array of the second memory cells MC22 may share the second vertical conductive line BL2. For reference, the semiconductor device 100 described with reference to FIGS. 2, 3A, and 3B includes the first conductive line BL, and the memory cells MC disposed adjacent to each other in the second direction D2 share one first conductive line BL. That is, the first conductive line BL may be referred to as a “common first conductive line BL”. Each of the first and second vertical conductive lines BL1 and BL2 illustrated in FIGS. 28A and 28B may be referred to as an “individual first conductive line”.

A vertical isolation layer BLF may be disposed between the first vertical conductive line BL1 and the second vertical conductive line BL2. A second bottom passivation layer BF2 and an additional second bottom passivation layer BF21 may be disposed below the first vertical conductive line BL1 and the second vertical conductive line BL2.

A third bottom passivation layer BF3 may be coupled between a bottom portion of the data storage element CAP and a lower structure LS.

FIGS. 28C to 28E are views for describing electrical connection of the first vertical conductive line BL1 and the second vertical conductive line BL2.

As illustrated in FIG. 28C, the first vertical conductive line BL1 and the second vertical conductive line BL2 may be interconnected through an interconnection ML.

As illustrated in FIG. 28D, the first vertical conductive line BL1 and the second vertical conductive line BL2 may be interconnected through vias VA and an interconnection ML.

As illustrated in FIG. 28E, the first vertical conductive line BL1 may be coupled to a via VA and an interconnection ML1, and the second vertical conductive line BL2 may be coupled to the via VA and an interconnection ML2. As described above, the first vertical conductive line BL1 and the second vertical conductive line BL2 may be coupled to different interconnections ML1 and ML2, respectively, and thus, may be coupled to different sense amplifiers, respectively.

FIG. 28F is a view for describing an isolation structure of the first vertical conductive line BL1 and the second vertical conductive line BL2.

As illustrated in FIG. 28F, the first vertical conductive line BL1 and the second vertical conductive line BL2 may be spaced apart from each other with a line-shape trench BLS interposed therebetween. The second cell isolation layers ISOB may be divided into the second cell isolation segments ISOB1 and ISOB2 by the line-shape trench BLS. The second cell isolation segments ISOB1 of the second cell isolation layers ISOB may be disposed between the first vertical conductive lines BL1 in the third direction D3. The second cell isolation segments ISOB2 of the second cell isolation layers ISOB may be disposed between the second vertical conductive lines BL2 in the third direction D3.

The second cell isolation segments ISOB1 of the second cell isolation layers ISOB and the first vertical conductive lines BL1 may be self-aligned in a fourth direction D31. The second cell isolation segments ISOB2 of the second cell isolation layers ISOB and the second vertical conductive lines BL2 may be self-aligned in a fifth direction D32. In this way, the first and second vertical conductive lines BL1 and BL2 may be formed to be self-aligned on one side of the second cell isolation segments ISOB1 and ISOB2.

As described above, the semiconductor device 200 may include the horizontal layer HL disposed over the lower structure LS and may have a first edge and a second edge, the first cell isolation layers ISOA disposed on the periphery of the second edge of the horizontal layer HL and vertically extending from the lower structure LS, the second cell isolation layers ISOB disposed on the periphery of the first edge of the horizontal layer HL and vertically extending from the lower structure LS, the vertical conductive lines BL1 and BL2 coupled to the first edge of the horizontal layer HL and self-aligned on one side of the second cell isolation layers ISOB, and the data storage element CAP coupled to the second edge of the horizontal layer HL and disposed between the first cell isolation layers ISOA.

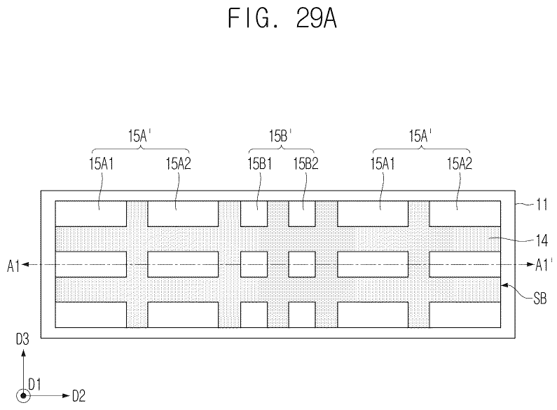

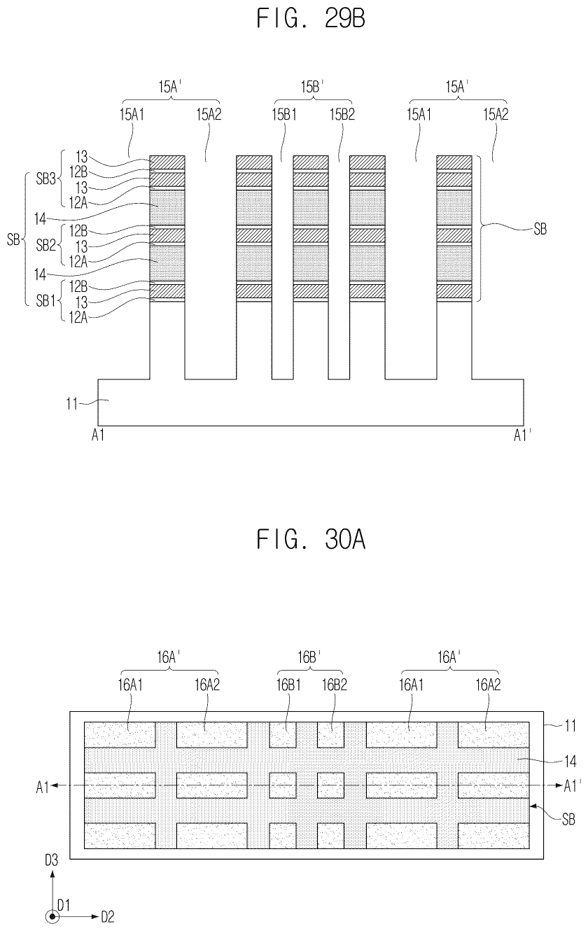

FIGS. 29A to 46B illustrate various views of a semiconductor device formed according to a method for fabricating the semiconductor device in accordance with an embodiment of the present disclosure. The method for fabricating the semiconductor device below may be similar to that described above with reference to FIGS. 4A to 27B.

FIG. 29A is a plan view illustrating a structure with a fourth layer 14 for describing a method for forming sacrificial isolation openings 15A′ and 15B′. FIG. 29B is a cross-sectional view illustrating a structure taken along line A1-A1′ illustrated in FIG. 29A.

Referring to FIGS. 29A and 29B, a stack body SB may be formed over a lower structure 11. The stack body SB may have a plurality of sub-stacks that are alternately stacked on one another. In each of the sub-stacks, a first layer 12A, a second layer 13, a third layer 12B and a fourth layer 14 may be sequentially stacked. The first layer 12A and the third layer 12B may be formed of the same material and each include silicon germanium. The second layer 13 may include monocrystalline silicon. The fourth layer 14 may include monocrystalline silicon. The first layer 12A, the second layer 13, the third layer 12B and the fourth layer 14 may be formed by epitaxial growth.

A portion of the stack body SB may be etched to form a plurality of sacrificial isolation openings 15A′ and 15B′. The sacrificial isolation openings 15A′ and 15B′, which are initial openings for cell isolation, may include large openings 15A′ and small openings 15B′. The size of the large openings 15A′ may be larger than that of the small openings 15B′. From a top view perspective, the large openings 15A′ and the small openings 15B′ may each have a rectangular shape. According to another embodiment of the present disclosure, the large openings 15A′ and the small openings 15B′ may each have a circular shape or an oval shape. The large openings 15A′ and the small openings 15B′ may vertically extend in a first direction D1. The large openings 15A′ may be alternately disposed with the small openings 15B′ in a second direction D2. A plurality of large openings 15A′ may be disposed in a third direction D3. A plurality of small openings 15B′ may be disposed in the third direction D3. The large openings 15A′ and the small openings 15B′ may pass through the stack body SB in the first direction D1.

After the sacrificial isolation openings 15A′ and 15B′ are formed, portions of the lower structure 11 exposed below the sacrificial isolation openings 15A′ and 15B′ may be etched. Accordingly, the bottom surfaces of the sacrificial isolation openings 15A′ and 15B′ may extend inside the lower structure 11. The bottom surfaces of the sacrificial isolation openings 15A′ and 15B′ may each include a U-shape profile. The fourth layer 14 may have a mesh-shape pattern formed by the sacrificial isolation openings 15A′ and 15B′.

Each of the large openings 15A′ may include two large segments 15A1 and 15A2, and each of the small openings 15B′ may include two small segments 15B1 and 15B2. As described above, the large segments 15A1 and 15A2 and the small segments 15B1 and 15B2 may be formed in the stack body SB.

FIG. 30A is a plan view illustrating a structure with the fourth layer 14 for describing a method for forming sacrificial cell isolation layers 16A′ and 16B′. FIG. 30B is a cross-sectional view illustrating a structure taken along line A1-A1′ illustrated in FIG. 30A.

As illustrated in FIGS. 30A and 30B, the sacrificial cell isolation layers 16A′ and 16B′ may be formed to fill the sacrificial isolation openings 15A′ and 15B′. The sacrificial cell isolation layers 16A′ and 16B′ may include first sacrificial cell isolation layers 16A′ and second sacrificial cell isolation layers 16B′. The first sacrificial cell isolation layers 16A′ may fill the large openings 15A′, and the second sacrificial cell isolation layers 16B′ may fill the small openings 15B′.

The first sacrificial cell isolation layers 16A′ and the second sacrificial cell isolation layers 16B′ may include the same material. The first sacrificial cell isolation layers 16A′ and the second sacrificial cell isolation layers 16B′ may be formed of a dielectric material. For example, the first sacrificial cell isolation layers 16A′ and the second sacrificial cell isolation layers 16B′ may include silicon oxide, silicon nitride, silicon carbon oxide, silicon carbon nitride, or a combination thereof. Forming the first sacrificial cell isolation layers 16A′ and the second sacrificial cell isolation layers 16B′ may include forming a dielectric material on the stack body SB to fill the sacrificial isolation openings 15A′ and 15B′ and planarizing the dielectric material so that the uppermost layer of the stack body SB is exposed. The first sacrificial cell isolation layers 16A′ and the second sacrificial cell isolation layers 16B′ may have different sizes or different volumes. For example, the size or volume of the first sacrificial cell isolation layers 16A′ may be larger than that of the second sacrificial cell isolation layers 16B′.

The first sacrificial cell isolation layers 16A′ and the second sacrificial cell isolation layers 16B′ may vertically extend in the first direction D1. The first sacrificial cell isolation layers 16A′ may be alternately disposed with the second sacrificial cell isolation layers 16B′ in the second direction D2. A plurality of first sacrificial cell isolation layers 16A′ may be disposed in the third direction D3. A plurality of second sacrificial cell isolation layers 16B′ may be disposed in the third direction D3. The first sacrificial cell isolation layers 16A′ and the second sacrificial cell isolation layers 16B′ may pass through the stack body SB in the first direction D1.

Each of the first sacrificial cell isolation layers 16A′ may include two first sacrificial segments 16A1 and 16A2, and each of the second sacrificial cell isolation layers 16B′ may include two second sacrificial segments 16B1 and 16B2.

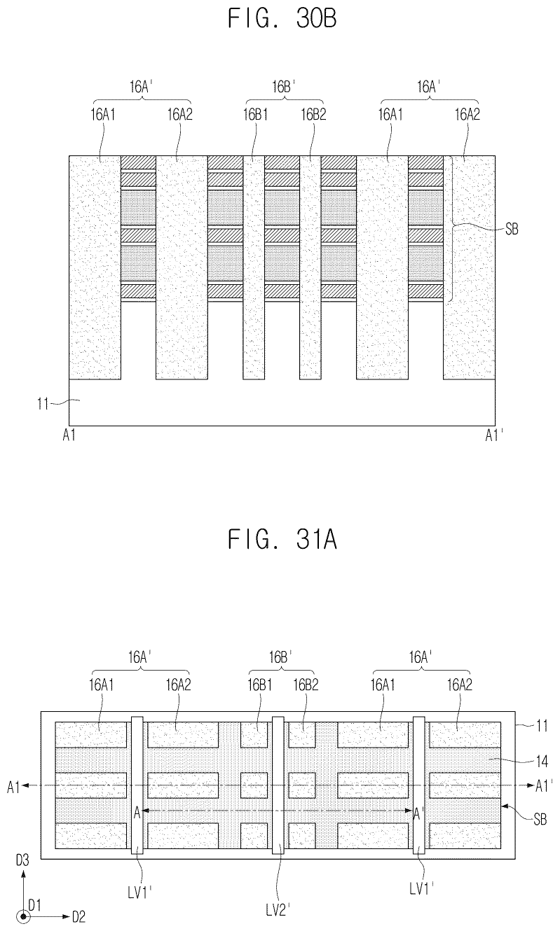

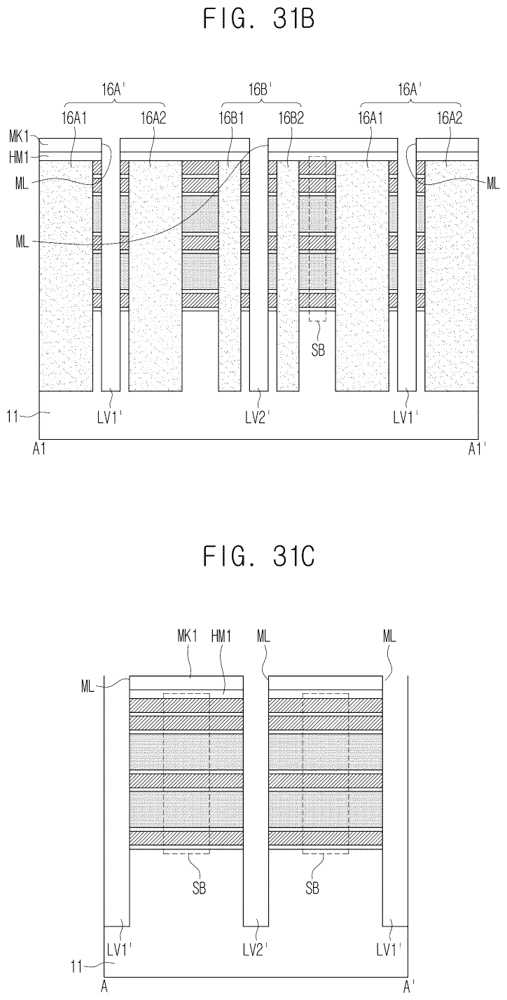

FIG. 31A is a plan view illustrating a structure with the fourth layer 14 for describing a method for forming line-shape sacrificial openings LV1′ and LV2′. FIG. 31B is a cross-sectional view illustrating a structure taken along line A1-A1′ illustrated in FIG. 31A. FIG. 31C is a cross-sectional view illustrating a structure taken along line A-A′ illustrated in FIG. 31A.

As illustrated in FIG. 31A to 31C, a first hard mask layer HM1 may be formed on the stack body SB, the first sacrificial cell isolation layers 16A′, and the second sacrificial cell isolation layers 16B′. The first hard mask layer HM1 may include silicon nitride.

Subsequently, a mask layer MK1 may be formed on the first hard mask layer HM1. The mask layer MK1, which is an etch mask layer, may include a hard mask material, photoresist, or a combination thereof. The mask layer MK1 may include line-shape opening patterns ML. The line-shape opening patterns ML may extend in the third direction D3.

Subsequently, the line-shape opening patterns ML of the mask layer MK1 may be transferred to the first hard mask layer HM1 and the stack body SB. For example, the first hard mask layer HM1 may be etched using the mask layer MK1 as an etch barrier, and then the stack body SB may be etched using the first hard mask layer HM1 as an etch barrier. Accordingly, a plurality of line-shape sacrificial openings LV1′ and LV2′ may be formed in the stack body SB. The line-shape sacrificial openings LV1′ and LV2′ may include first line-shape sacrificial openings LV1′ and second line-shape sacrificial openings LV2′. From a top view perspective, cross sections of the first line-shape sacrificial openings LV1′ and the second line-shape sacrificial openings LV2′ may be rectangles that extend lengthwise in the third direction D3.

The first line-shape sacrificial openings LV1′ may be formed by etching the stack body SB between the first sacrificial segments 16A1 and 16A2 of the first sacrificial cell isolation layers 16A′. The second line-shape sacrificial openings LV2′ may be formed by etching the stack body SB between the second sacrificial segments 16B1 and 16B2 of the second sacrificial cell isolation layers 16B′.

The first line-shape sacrificial openings LV1′ and the second line-shape sacrificial openings LV2′ may vertically extend in the first direction D1.

The first line-shape sacrificial openings LV1′ and the first sacrificial segments 16A1 and 16A2 of the first sacrificial cell isolation layers 16A′ may not contact each other. The second line-shape sacrificial openings LV2′ and the second sacrificial segments 16B1 and 16B2 of the second sacrificial cell isolation layers 16B′ may not contact each other.

As described above, line patterning using one mask layer MK1 may be performed to form the first and second line-shape sacrificial openings LV1′ and LV2′.

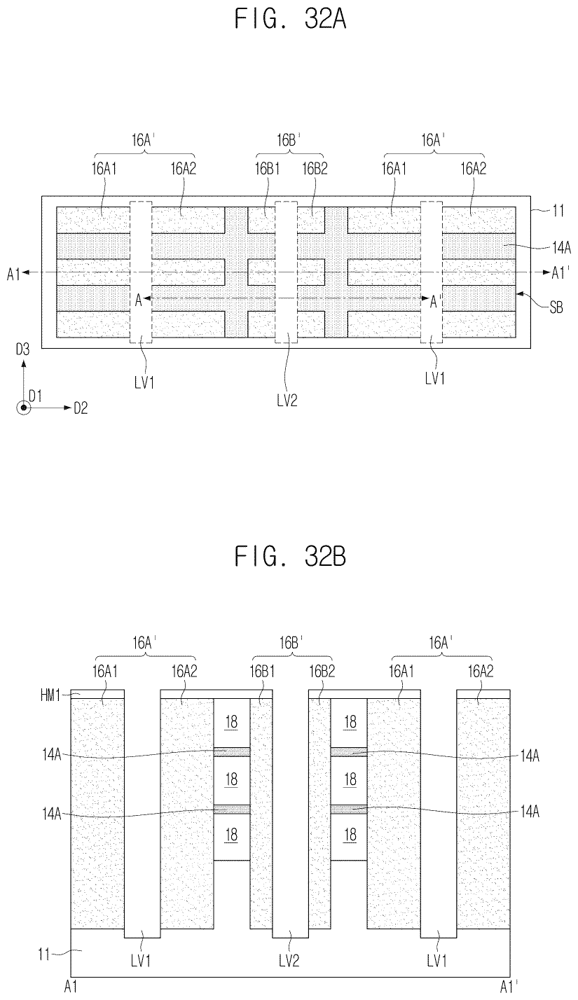

FIG. 32A is a plan view illustrating a structure with a preliminary horizontal layer 14A for describing a method for forming the preliminary horizontal layer 14A. FIG. 32B is a cross-sectional view illustrating a structure taken along line A1-A1′ illustrated in FIG. 32A. FIG. 32C is a cross-sectional view illustrating a structure taken along line A-A′ illustrated in FIG. 32A.

As illustrated in FIGS. 32A to 32C, the mask layer MK may be removed, and then a portion of the first hard mask layer HM1 may be trimmed.

Subsequently, the first and third layers 12A and 12B may be selectively removed through the first and second line-shape sacrificial openings LV1′ and LV2′.

Subsequently, the second layers 13 and the fourth layers 14 may be recessed. To recess the second layers 13 and the fourth layers 14, a wet etching process or a dry etching process may be used. According to an embodiment of the present disclosure, the fourth layers 14 may be partially etched while the second layers 13 are removed. As a result, the second layers 13 may be removed, and the fourth layers 14 may become thin, as indicated by reference numeral “14A”. The recess process of forming the thin fourth layers 14A, which are the preliminary horizontal layers 14A, may be referred to as a thinning process or a trimming process of the fourth layers 14. The preliminary horizontal layers 14A may be referred to as thin-body active layers. The preliminary horizontal layers 14A may each include a monocrystalline silicon layer.

The preliminary horizontal layers 14A may be formed by the recess process of the fourth layers 14 as described above, and horizontal recesses 18 may be formed between the preliminary horizontal layers 14A. Each of the upper and lower surfaces of the preliminary horizontal layers 14A may be flat.

From a top view perspective, the preliminary horizontal layers 14A may have a cross shape. The side surfaces of the preliminary horizontal layers 14A may have a bent shape or a round shape.

After the preliminary horizontal layers 14A are formed, the line-shape sacrificial openings may be expanded as indicated by reference numeral “LV1” and “LV2”. The preliminary horizontal layers 14A may be spaced apart from each other by the line-shape sacrificial openings LV1 and LV2 in the second direction D2. The preliminary horizontal layers 14A may have a shape in which a plurality of cross shapes are merged in the third direction D3.

While the preliminary horizontal layers 14A are formed, the surface of the lower structure 11 may be recessed to a predetermined depth. As a result, the depths of the line-shape sacrificial openings LV1 and LV2 may increase.

The first line-shape sacrificial openings LV1 may be alternately disposed with the second line-shape sacrificial openings LV2 between the preliminary horizontal layers 14A in the second direction D2. The first line-shape sacrificial openings LV1 may be disposed between the first sacrificial segments 16A1 and 16A2 in the second direction D2, and the second line-shape sacrificial openings LV2 may be disposed between the second sacrificial segments 16B1 and 16B2 in the second direction D2.

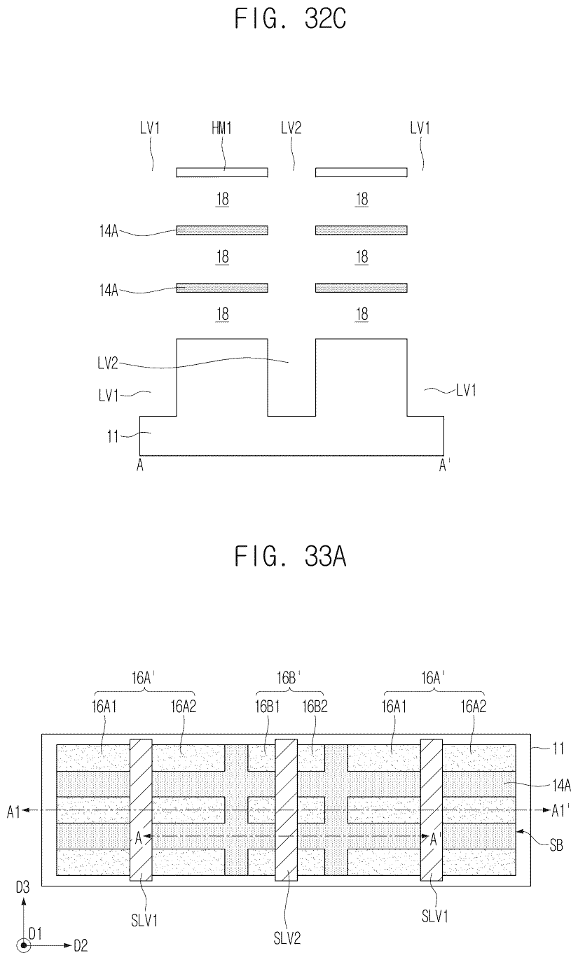

FIG. 33A is a plan view illustrating a structure for describing a method for forming a first dielectric layer 19 and a second dielectric layer 20. FIG. 33B is a cross-sectional view illustrating a structure taken along line A1-A1′ illustrated in FIG. 33A. FIG. 33C is a cross-sectional view illustrating a structure taken along line A-A′ illustrated in FIG. 33A.

As illustrated in FIGS. 33A to 33C, first dielectric layers 19 covering the preliminary horizontal layers 14A may be formed. The first dielectric layers 19 may each include silicon nitride. The first dielectric layers 19 may fully cover the upper surfaces, lower surfaces and side surfaces of the preliminary horizontal layers 14A.

While the first dielectric layers 19 are formed, a dummy dielectric layer 19D may be formed on the surface of the lower structure 11. A portion of each of the first dielectric layers 19 may fully cover the upper surface, lower surface and side surfaces of the first hard mask layer HM1.

Subsequently, second dielectric layers 20 may be formed on the first dielectric layers 19. Each of the second dielectric layers 20 may fill between the vertically neighboring first dielectric layers 19. The second dielectric layer 20 may include silicon oxide. A portion of the second dielectric layer 20 may be formed conformally on the surfaces of the line-shape sacrificial openings LV1 and LV2. The horizontal recesses 18 may be filled with the first dielectric layers 19 and the second dielectric layers 20.

Subsequently, sacrificial pillars 21 may be formed on the second dielectric layers 20 disposed in the line-shape sacrificial openings LV1 and LV2. Each of the sacrificial pillars 21, which is a sacrificial material, may include amorphous carbon. According to another embodiment of the present disclosure, a pillar capping layer may be further formed over the sacrificial pillar 21. The pillar capping layer may include a metal, a metal-based material, or a combination thereof. The pillar capping layer may include titanium nitride. Forming the sacrificial pillar 21 may include depositing a sacrificial material and planarizing the sacrificial material. The planarization process of forming the sacrificial pillar 21 may be performed until the uppermost-level first dielectric layer 19 is exposed. The sacrificial pillar 21 may not be formed between the first dielectric layers 19 that are vertically stacked.

The second dielectric layer 20 and the sacrificial pillar 21 may form first and second sacrificial pillar structures SLV1 and SLV2 that fill the line-shape sacrificial openings LV1 and LV2. The first sacrificial pillar structure SLV1 may fill the first line-shape sacrificial opening LV1, and the second sacrificial pillar structure SLV2 may fill the second line-shape sacrificial opening LV2. According to another embodiment of the present disclosure, the first and second sacrificial pillar structures SLV1 and SLV2 may include a dielectric material, a carbon-containing material, a metal, a metal-based material, or a combination thereof. According to another embodiment of the present disclosure, the first and second sacrificial pillar structures SLV1 and SLV2 may include silicon oxide, silicon nitride, titanium nitride, amorphous carbon, or a combination thereof. From a top view perspective, the first and second sacrificial pillar structures SLV1 and SLV2 may each be a line-shape sacrificial pillar extending in the third direction D3. According to another embodiment of the present disclosure, portions of the first dielectric layer 19 may be conformally formed on the surfaces of the first and second line-shape sacrificial openings LV1 and LV2, and thus the first and second sacrificial pillar structures SLV1 and SLV2 may further include the portions of the first dielectric layer 19.

Referring to FIG. 33B, the first dielectric layer 19 may be formed between the preliminary horizontal layers 14A, and the second dielectric layer 20 may be disposed in the first dielectric layer 19. The first dielectric layer 19 may surround the second dielectric layer 20.

As described above, by forming the preliminary horizontal layers 14A, the first dielectric layers 19 and the second dielectric layers 20, a cell mold structure may be formed. The cell mold structure may include a plurality of cell molds CM. Each of the cell molds CM may include a plurality of mold layers, e.g., the preliminary horizontal layers 14A, the first dielectric layers 19 and the second dielectric layers 20. Each of the cell molds CM may include an ONSN (Oxide-Nitride-Silicon-Nitride) stack. The ONSN stack may refer to a structure in which silicon oxide, first silicon nitride, a monocrystalline silicon layer, and second silicon nitride are sequentially stacked. The silicon oxide may correspond to the second dielectric layers 20, and the first and second silicon nitride may correspond to the first dielectric layers 19, and the monocrystalline silicon layer may correspond to the preliminary horizontal layers 14A. The cell mold structure including the plurality of cell molds CM may be referred to as a “vertical stack”. In another embodiment, the cell mold structure may include an ONSNO (Oxide-Nitride-Silicon-Nitride-Oxide) stack. The ONSNO stack may refer to a structure in which first silicon oxide, first silicon nitride, a monocrystalline silicon layer, second silicon nitride, and second silicon oxide are sequentially stacked.

Through a series of the processes according to FIGS. 28A to 33C, the sub-stacks SB1, SB2, SB3 of the stack body SB may be replaced with cell molds CM. The first layers 12A, the second layers 13, and the third layers 12B may be replaced with the first dielectric layers 19 and the second dielectric layers 20. The fourth layers 14 may become the preliminary horizontal layers 14A. The first dielectric layers 19 may be referred to as “trimming target layers”.

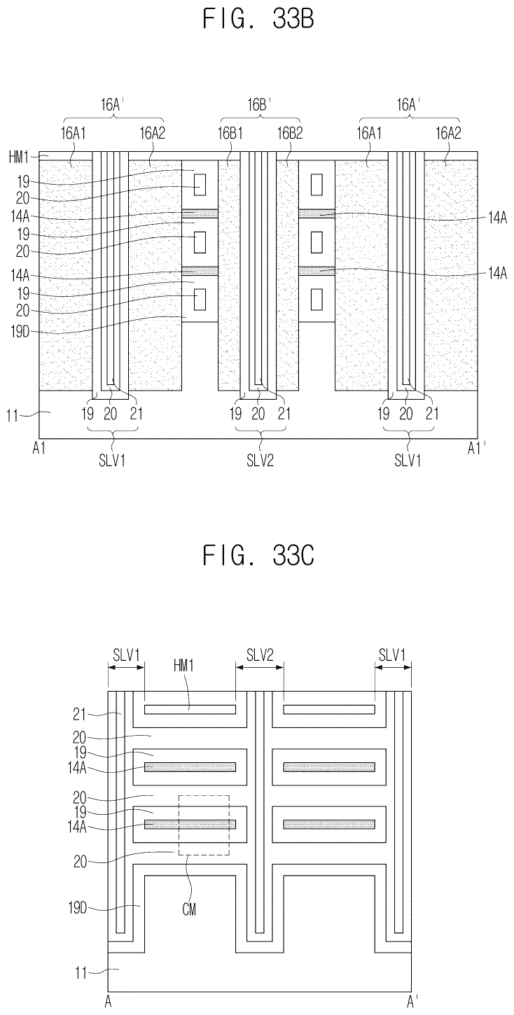

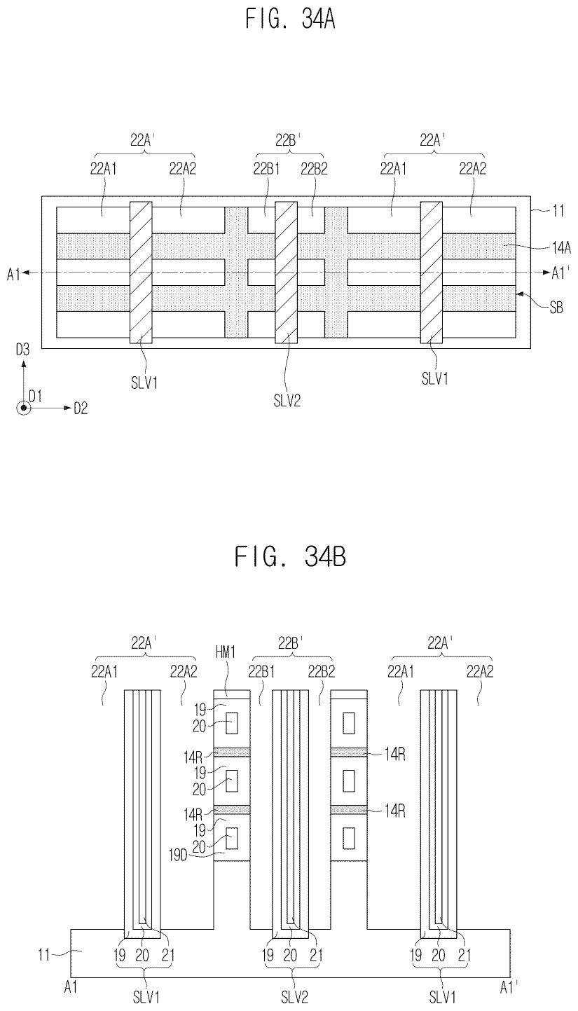

FIG. 34A is a plan view illustrating a structure with cell isolation openings 22A′ and 22B′ for describing a method for forming the cell isolation openings 22A′ and 22B′. FIG. 34B is a cross-sectional view illustrating a structure taken along line A1-A1′ illustrated in FIG. 34A.

As illustrated in FIGS. 34A and 34B, the first and second sacrificial cell isolation layers 16A′ and 16B′ may be removed to form the cell isolation openings 22A′ and 22B′. While the first and second sacrificial cell isolation layers 16A′ and 16B′ are removed, the first and second sacrificial pillar structures SLV1 and SLV2 may be covered by a mask layer (not illustrated). The side surfaces of the preliminary horizontal layers 14A and first dielectric layers 19 may be exposed by the cell isolation openings 22A′ and 22B′ in the third direction D3.

Each of the first cell isolation openings 22A′ may include two first cell isolation opening segments 22A1 and 22A2, and each of the second cell isolation openings 22B′ may include two second cell isolation opening segments 22B1 and 22B2. The first sacrificial pillar structure SLV1 may be disposed between the first cell isolation opening segments 22A1 and 22A2 in the second direction D2. The second sacrificial pillar structure SLV2 may be disposed between the second cell isolation opening segments 22B1 and 22B2 in the second direction D2.

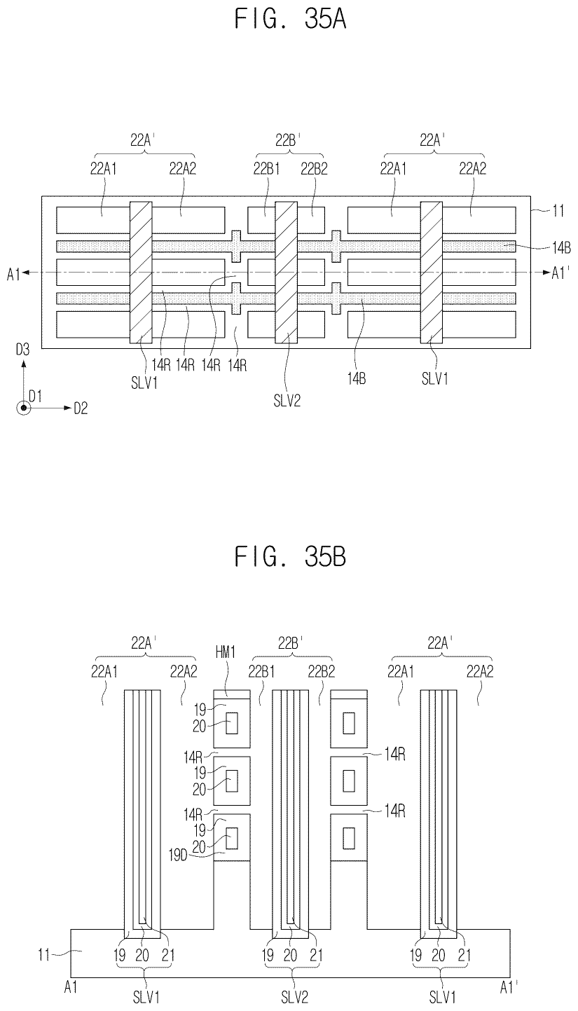

FIG. 35A is a plan view illustrating a structure with horizontal layers 14B for describing a method for forming the horizontal layers 14B. FIG. 35B is a cross-sectional view illustrating a structure taken along line A1-A1′ illustrated in FIG. 35A.

As illustrated in FIGS. 35A and 35B, the side surfaces of the preliminary horizontal layers 14A may be trimmed through the cell isolation openings 22A′ and 22B′. Accordingly, the horizontal layers 14B may be formed. Horizontal layer level gaps 14R may be formed on both sides of the horizontal layers 14B. The horizontal layer level gaps 14R and the horizontal layers 14B may be disposed between the first dielectric layers 19. The horizontal layers 14B may be referred to as “trimmed horizontal layer patterns”.

While the horizontal layers 14B are formed, the surface of the lower structure 11, for example, the bottom surfaces of the cell isolation openings 22A′ and 22B′, may be recessed to a predetermined depth.

The horizontal layers 14B may be disposed between the sacrificial pillar structures SLV1 and SLV2 in the second direction D2. From a top view perspective, the horizontal layers 14B may each have a cross shape. The horizontal layers 14B may each have a cross shape with a smaller size than the preliminary horizontal layers 14A. The preliminary horizontal layers 14A may each have a shape in which a plurality of cross shapes are merged, and the horizontal layers 14B may each have a shape in which the cross shapes are individually isolated in the third direction D3. The horizontal layer level gaps 14R may be formed between the horizontal layers 14B disposed in the third direction D3. The first and second sacrificial pillar structures SLV1 and SLV2 may be disposed between the horizontal layers 14B in the second direction D2.

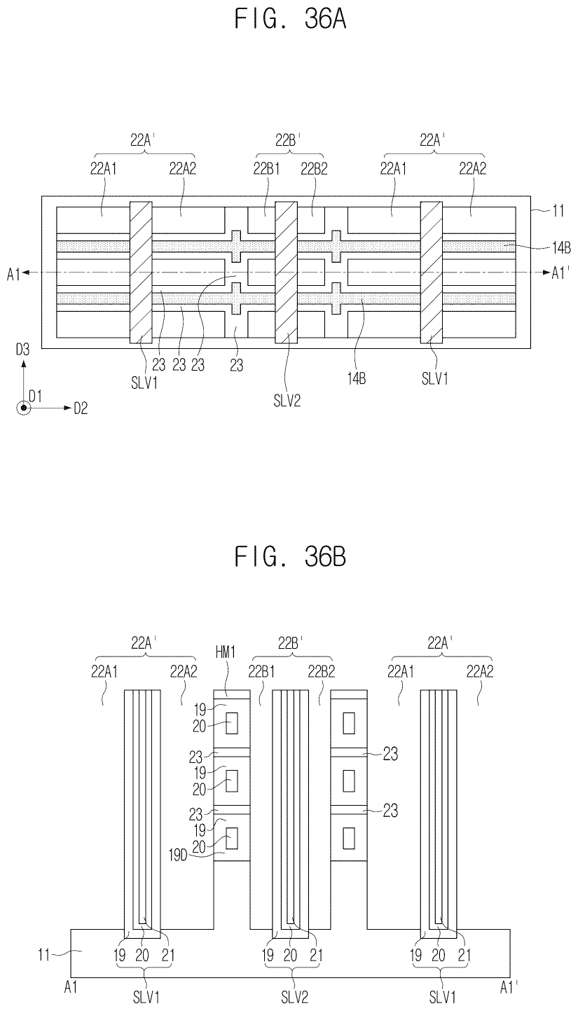

FIG. 36A is a plan view illustrating a structure with a horizontal layer level spacer 23 for describing a method for forming the horizontal layer level spacer 23. FIG. 36B is a cross-sectional view illustrating a structure taken along line A1-A1′ illustrated in FIG. 36A.

As illustrated in FIGS. 36A and 36B, the horizontal layer level spacer 23 may be formed on the sidewalls of the horizontal layers 14B. Forming the horizontal layer level spacer 23 may include forming a spacer material on the side surfaces of the horizontal layers 14B, and etching the spacer material. The horizontal layer level spacer 23 may include a dielectric material, for example, silicon oxide. The horizontal layer level spacer 23 may fill the horizontal layer level gap 14R. The horizontal layers 14B disposed in the third direction D3 may be isolated from each other by the horizontal layer level spacer 23.

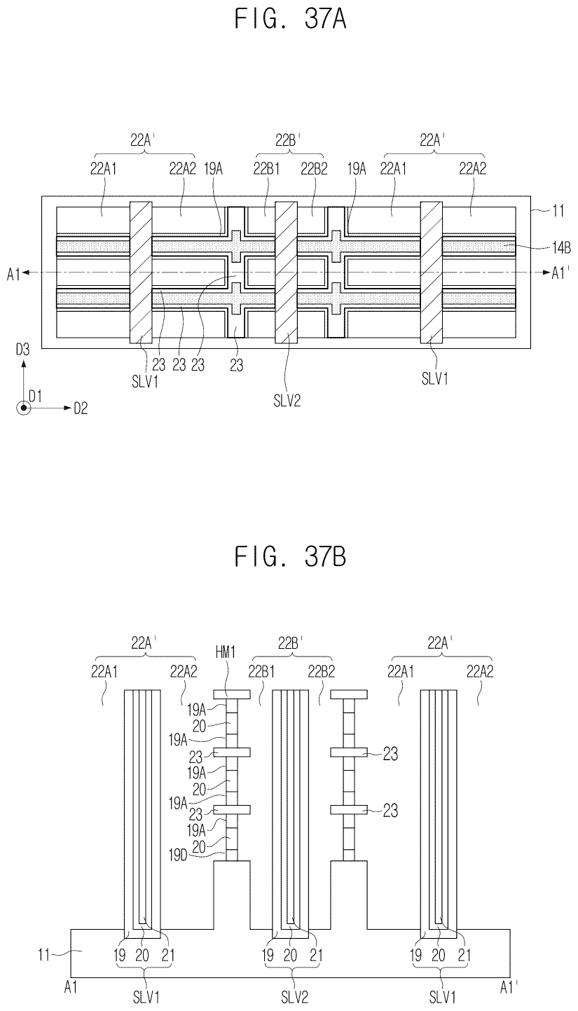

FIG. 37A is a plan view illustrating a structure with first dielectric layers 19A for describing a method for trimming the first dielectric layers 19A. FIG. 37B is a cross-sectional view illustrating a structure taken along line A1-A1′ illustrated in FIG. 37A.

As illustrated in FIGS. 37A and 37B, a portion of each of the first dielectric layers 19 may be horizontally trimmed through the cell isolation openings 22A′ and 22B′. After the trimming process, the first dielectric layers 19 may remain as indicated by reference numeral “19A”. Accordingly, when viewed from the third direction D3, the second dielectric layer 20 may be disposed between the first dielectric layers 19A, and one second dielectric layer 20 may be disposed between a pair of first dielectric layers 19A.

According to FIGS. 35A to 37C, the width of each of the first dielectric layers 19A in the third direction D3 between the first cell isolation openings 22A′ and the second cell isolation openings 22B′ may be greater than that of each of the horizontal layers 14B. Specifically, the trimming depth of each of the first dielectric layers 19 in the third direction D3 may be smaller than that of each of the preliminary horizontal layers 14A.

A pair of first dielectric layers 19A may vertically overlap with one horizontal layer 14B. The first dielectric layers 19A which are trimmed may be referred to as “trimmed first dielectric layers”.

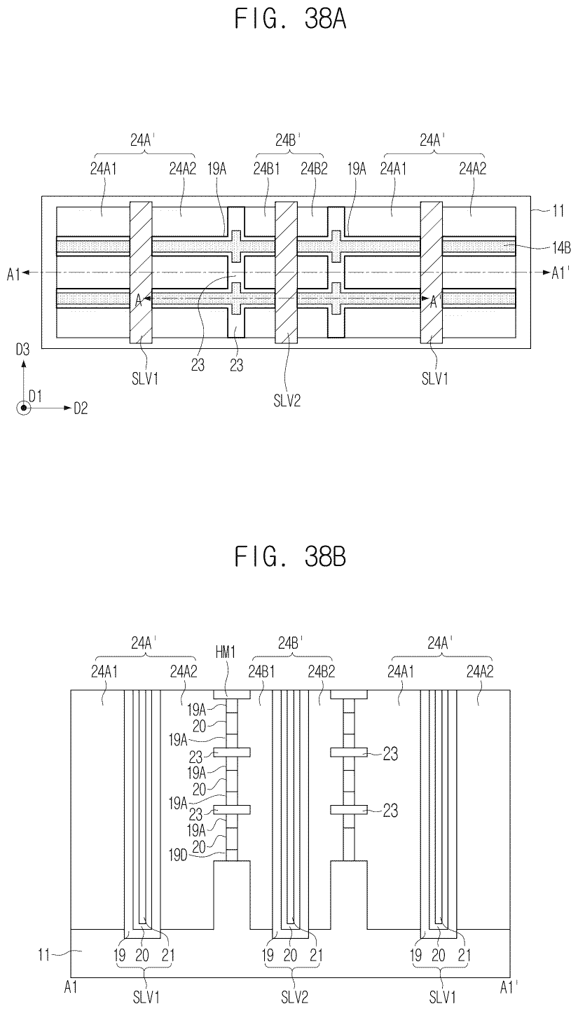

FIG. 38A is a plan view illustrating a structure with cell isolation layers 24A′ and 24B′ for describing a method for forming the cell isolation layers 24A′ and 24B′. FIG. 38B is a cross-sectional view illustrating a structure taken along line A1-A1′ illustrated in FIG. 38A. FIG. 38C is a cross-sectional view illustrating a structure taken along line A-A′ illustrated in FIG. 38A. FIG. 38A is a plan view illustrating a structure with the first dielectric layers 19A to describe the method for forming the cell isolation layers 24A′ and 24B′.

As illustrated in FIGS. 38A to 38C, the cell isolation layers 24A′ and 24B′ may be formed to fill the isolation openings 22A′ and 22B′. The cell isolation layers 24A′ and 24B′ may include first cell isolation layers 24A′ and second cell isolation layers 24B′. The first cell isolation layers 24A′ and the second cell isolation layers 24B′ may include the same material. The first cell isolation layers 24A′ and the second cell isolation layers 24B′ may each be formed of a dielectric material. For example, the first cell isolation layers 24A′ and the second cell isolation layers 24B′ may each include silicon oxide, silicon nitride, silicon carbon oxide, silicon carbon nitride, or a combination thereof. From a top view perspective, the outermost material of the first cell isolation layers 24A′ and second cell isolation layers' 24B may include silicon carbon oxide.

Forming the first cell isolation layers 24A′ and the second cell isolation layers 24B′ may include forming a dielectric material that fills the cell isolation openings 22A′ and 22B′ and planarizing the dielectric material so that the surface of the uppermost-level first dielectric layer 19 is exposed. The first cell isolation layers 24A′ and the second cell isolation layers 24B′ may have different sizes or volumes. The first cell isolation layers 24A′ and the second cell isolation layers 24B′ may have a dual structure of silicon oxide and silicon carbon oxide. For example, silicon carbon oxide may be deposited after silicon oxide is deposited. According to another embodiment of the present disclosure, the first and second cell isolation layers 24A′ and 24B′ may include an embedded air gap. The first cell isolation layers 24A′ and the second cell isolation layers 24B′ may vertically extend in the first direction D1.

Each of the first isolation layers 24A′ may include two first cell isolation segments 24A1 and 24A2, and each of the second cell isolation layers 24B′ may include two second cell isolation segments 24B1 and 24B2. The first sacrificial pillar structure SLV1 may be disposed between the first cell isolation segments 24A1 and 24A2. The second sacrificial pillar structure SLV2 may be disposed between the second cell isolation segments 24B1 and 24B2.

The first and second cell isolation layers 24A′ and 24B′ may correspond to the cell isolation layers ISOA and ISOB described with reference to FIGS. 28A and 28B. Each of the first and second cell isolation layers 24A′ and 24B′ may include a stack of a cell isolation liner layer and a cell isolation gap-fill layer. The cell isolation liner layer may include silicon oxide, and the cell isolation gap-fill layer may include silicon carbon oxide. According to another embodiment of the present disclosure, the first and second cell isolation layers 24A′ and 24B′ may include an embedded air gap, and the embedded air gap may be provided when the cell isolation gap-fill layer is formed.

The first and second cell isolation layers 24A′ and 24B′ and the first dielectric layers 19A may be in direct contact with one another. The horizontal layer level spacer 23 may be disposed between the horizontal layers 14B and the first and second cell isolation layers 24A′ and 24B′.

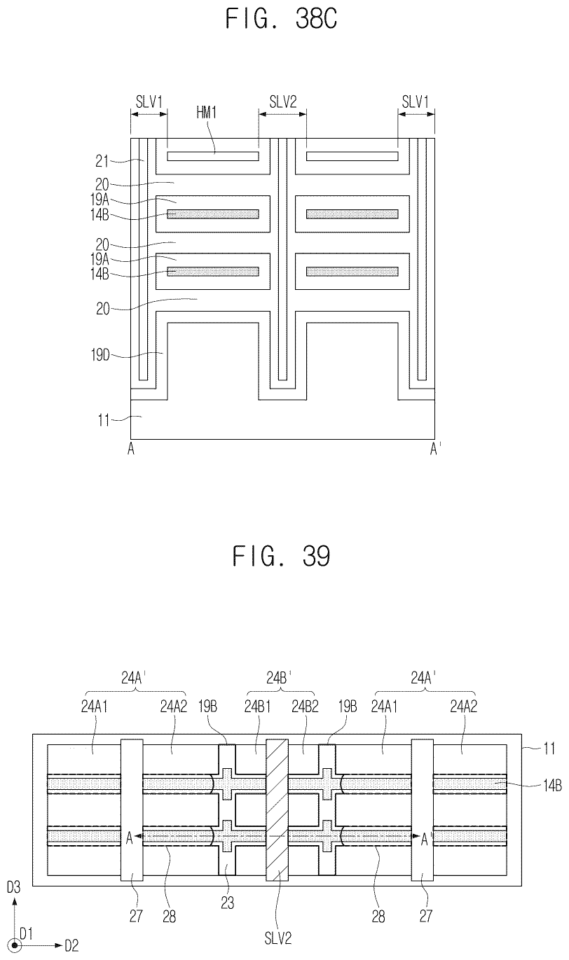

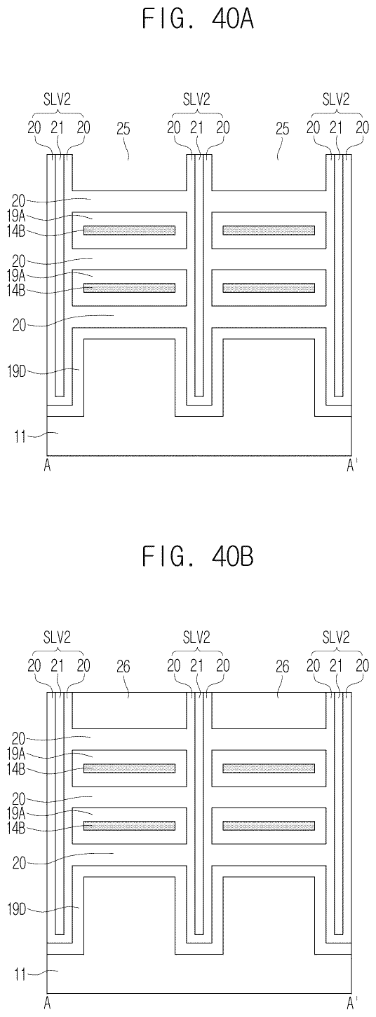

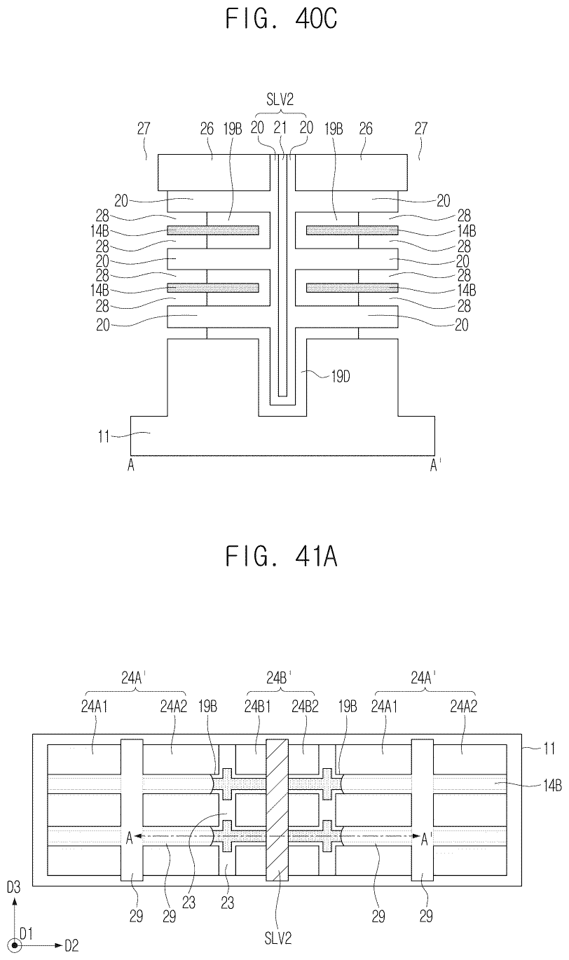

FIG. 39 is a plan view illustrating a structure with initial line-shape vertical openings 27 for describing a method for forming the initial line-shape vertical openings 27, and FIGS. 40A to 40C are cross-sectional views illustrating the structure taken along line A-A′ illustrated in FIG. 39.

As illustrated in FIG. 40A, the first hard mask layer HM1 and the uppermost-level first dielectric layer 19A may be removed to form a hard mask layer level recess 25.

As illustrated in FIG. 40B, a top dielectric layer 26 may be formed to fill the hard mask layer level recess 25. The top dielectric layer 26 may include silicon oxide.

As illustrated in FIG. 40C, the first sacrificial pillar structures SV1 may be removed, and the initial line-shape vertical openings 27 may be formed. The first dielectric layers 19A and the dummy dielectric layer 19D may be exposed by the initial line-shape vertical openings 27.

Subsequently, the second dielectric layers 20 may be horizontally recessed. The first dielectric layers 19A and the dummy dielectric layer 19D may be exposed by the initial line-shape vertical openings 27.

Subsequently, the first dielectric layers 19A and the dummy dielectric layer 19D may be selectively and horizontally recessed. Accordingly, first dielectric layer patterns 19B and dielectric layer level recesses 28 may be formed. Portions of the horizontal layers 14B may be exposed by the dielectric layer level recesses 28.

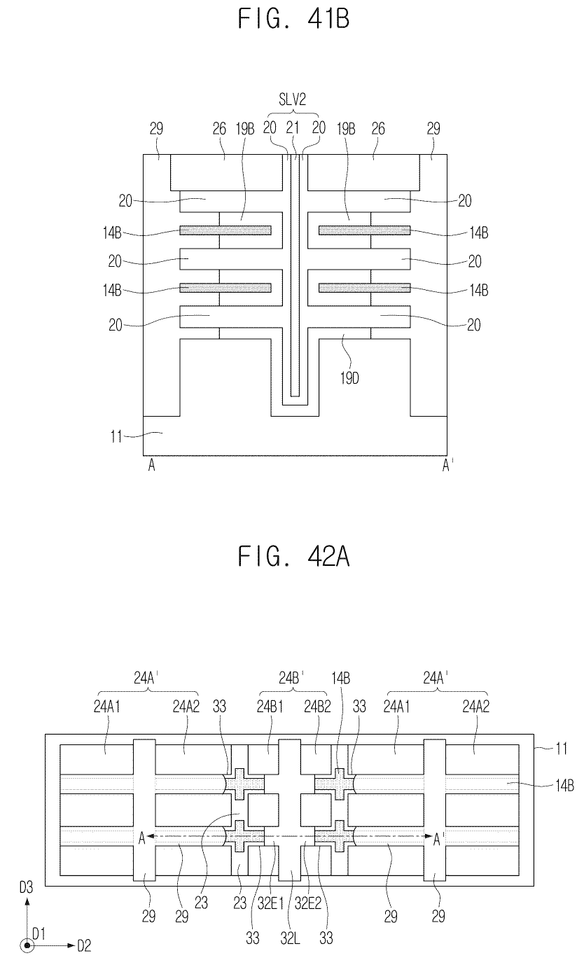

FIG. 41A is a plan view illustrating a structure with line-shape vertical sacrificial structures 29 for describing a method for forming the line-shape sacrificial structures 29. FIG. 41B is a cross-sectional view illustrating a structure taken along line A-A′ illustrated in FIG. 41A.

As illustrated in FIGS. 41A and 41B, the line-shape vertical sacrificial structures 29 may be formed to fill the dielectric layer level recesses 28 and the initial line-shape vertical openings 27. The line-shape vertical sacrificial structures 29 may each include a dielectric material. The line-shape vertical sacrificial structures 29 may each include silicon oxide, silicon nitride, titanium nitride, amorphous carbon, or a combination thereof.

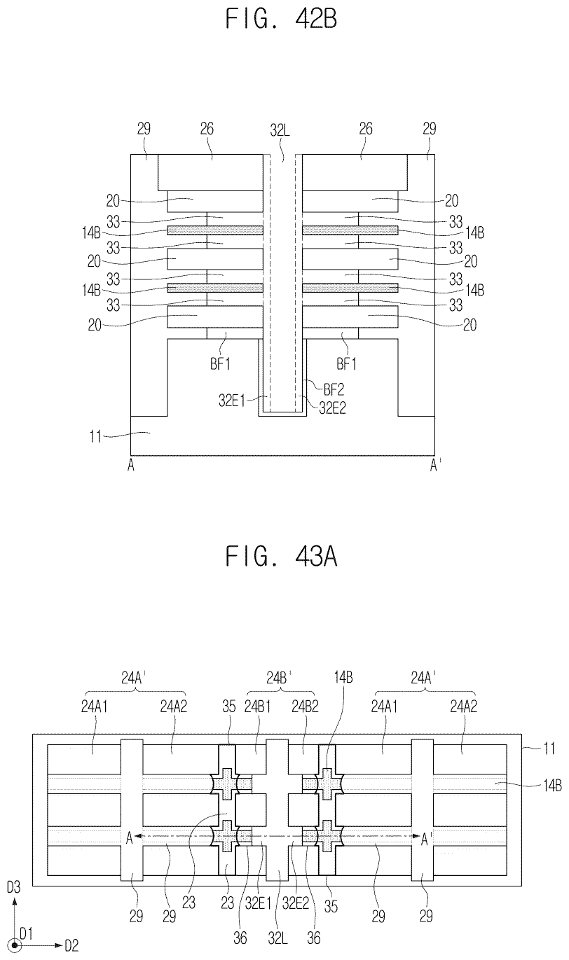

FIG. 42A is a plan view illustrating a structure with a first line-shape vertical opening 32L and horizontal level recesses 33 for describing a method for forming the first line-shape vertical opening 32L and the horizontal level recesses 33. FIG. 42B is a cross-sectional view illustrating a structure taken along line A-A′ illustrated in FIG. 42A.

As illustrated in FIGS. 42A and 42B, the first line-shape vertical opening 32L may be formed between the second cell isolation segments 24B1 and 24B2. Forming the first line-shape vertical opening 32L may include removing the sacrificial pillar 21 of the second sacrificial pillar structure SLV2, replacing the dummy dielectric layer 19D with a first passivation layer BF1, and cutting the second dielectric layers 20.

The replacing of the dummy dielectric layer 19D with the first passivation layer BF1 is described above with reference to FIGS. 17A to 18B.

A second passivation layer BF2 may be formed in a lower region of the first line-shape vertical opening 32L. For example, the surface of the lower structure 11 may be oxidized to form the second passivation layer BF2.

The first line-shape vertical opening 32L may include first and second vertical extension portions 32E1 and 32E2 extending in the second direction D2. The first and second vertical extension portions 32E1 and 32E2 of the first line-shape vertical opening 32L may be formed by cutting first sides of the horizontal layers 14B. The cutting of the horizontal layers 14B may be performed after the cutting of the second dielectric layers 20. From a top view perspective, the first and second vertical extension portions 32E1 and 32E2 of the first line-shape vertical opening 32L may have a shape that is horizontally recessed from first sides of the second cell isolation segments 24B1 and 24B2. The first vertical extension portions 32E1 of the first line-shape vertical opening 32L may be disposed between the second cell isolation segments 24B1 in the third direction D3. The second vertical extension portions 32E2 of the first line-shape vertical opening 32L may be disposed between the second cell isolation segments 24B2 in the third direction D3. The first vertical extension portions 32E1 and the second vertical extension portions 32E2 may be symmetrical and spaced apart from each other in the second direction D2.

Subsequently, the first dielectric layer patterns 19B may be removed through the first line-shape vertical opening 32L to form the horizontal level recesses 33. Portions of the horizontal layers 14B may be exposed by the horizontal level recesses 33. Each of the horizontal level recesses 33 may be disposed between the second dielectric layer 20 and the horizontal layer 14B. Two horizontal level recesses 33 may face each other with one horizontal layer 14B interposed therebetween.

FIG. 43A is a plan view illustrating a structure with horizontal conductive lines 35 for describing a method for forming the horizontal conductive lines 35. FIG. 43B is a cross-sectional view illustrating a structure taken along line A-A′ illustrated in FIG. 43A.

As illustrated in FIGS. 43A and 43B, inter-level dielectric layers 34 may be formed on exposed portions of the horizontal layers 14B. The inter-level dielectric layers 34 may each include a gate dielectric layer. The inter-level dielectric layers 34 may correspond to the inter-level dielectric layers GD described above with reference to FIGS. 1A to 3B.

The inter-level dielectric layers 34 may be formed by oxidizing the surfaces of the horizontal layers 14B. According to another embodiment of the present disclosure, the inter-level dielectric layers 34 may be formed by a deposition process of silicon oxide.

The inter-level dielectric layers 34 may each include silicon oxide, silicon nitride, metal oxide, metal oxynitride, metal silicate, a high-k material, a ferroelectric material, an anti-ferroelectric material, or a combination thereof. The inter-level dielectric layers 34 may each include SiO₂, Si₃N₄, HfO₂, Al₂O₃, ZrO₂, AlON, HfON, HfSiO, HfSiON, or a combination thereof.

The horizontal conductive lines 35 may be formed to fill the horizontal level recesses 33 on the inter-level dielectric layers 34. Forming the horizontal conductive lines 35 may include depositing a conductive material filling the horizontal level recesses 33 on the inter-level dielectric layers 34 and etching back the conductive material. Each of the horizontal conductive lines 35 may include a pair of first and second horizontal conductive lines 35A and 35B that face each other with the horizontal layer 14B interposed therebetween. The first and second horizontal conductive lines 35A and 35B may include a metal, a metal-base material, a semiconductor material, or a combination thereof. The first and second horizontal conductive lines 35A and 35B may include titanium nitride, tungsten, polysilicon, molybdenum, molybdenum nitride, or a combination thereof. For example, the first and second horizontal conductive lines 35A and 35B may include a TiN/W stack in which titanium nitride and tungsten are sequentially stacked. The horizontal conductive lines 35A and 35B may include an N-type work function material or a P-type work function material. The N-type work function material may have a low work function of approximately 4.5 eV or lower, and the P-type work function material may have a high work function of approximately 4.5 eV or higher.

Each of the horizontal conductive lines 35 may correspond to the second conductive line DWL described with reference to FIGS. 1A to 1D, and the first and second horizontal conductive lines 35A and 35B may correspond to the upper horizontal line G1 and the lower horizontal line G2, respectively. As illustrated in FIGS. 1A to 1D, each of the first and second horizontal conductive lines 35A and 35B may have a cross shape and include a channel overlapping portion WLP and channel non-overlapping portions NOL.

A first capping layer 36 may be formed on one side of the horizontal conductive line 35. The first capping layer 36 may include silicon oxide, silicon nitride, or a combination thereof. Deposition and etch-back processes of a capping material may be performed to form the first capping layer 36.

During or after the first capping layer 36 is formed, a portion of the inter-level dielectric layer 34 may be removed, and a first edge portion of each of the horizontal layers 14B may be exposed.

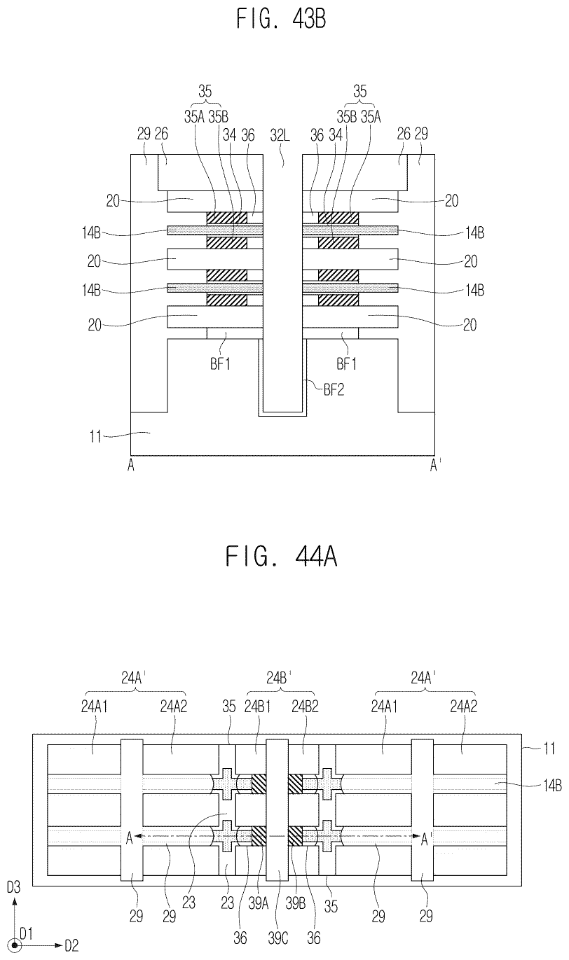

FIG. 44A is a plan view illustrating a structure with vertical conductive lines 39 for describing a method for forming the vertical conductive lines 39. FIG. 44B is a cross-sectional view illustrating a structure taken along line A-A′ illustrated in FIG. 44A.

As illustrated in FIGS. 44A and 44B, first and second vertical conductive lines 39A and 39B coupled to the first edge portion of each of the horizontal layers 14B may be formed. The first and second vertical conductive lines 39A and 39B may fill the first and second vertical extension portions 32E1 and 32E2 (see FIG. 42B), respectively. The first and second vertical conductive lines 39A and 39B may be coupled in common to the horizontal layers 14B. The first and second vertical conductive lines 39A and 39B may each include titanium nitride, tungsten, or a combination thereof. The first and second vertical conductive lines 39A and 39B may each include a bit line. Forming the first and second vertical conductive lines 39A and 39B may include depositing a conductive material to fill the first and second vertical extension portions 32E1 and 32E2 of the first line-shape vertical opening 32L and etching back the conductive material. The first vertical conductive lines 39A may fill the first vertical extension portions 32E1. The second vertical conductive lines 39B may fill the second vertical extension portions 32E2. The first vertical conductive lines 39A and the second vertical conductive lines 39B may be electrically isolated from each other.

From a top view perspective, the first vertical conductive lines 39A may be disposed between the second cell isolation segments 24B1 in the third direction D3. The second vertical conductive lines 39B may be disposed between the second cell isolation segments 24B2 in the third direction D3. The first vertical conductive lines 39A and the second vertical conductive lines 39B may be symmetrical and spaced apart from each other in the second direction D2. First sides of the second cell isolation segments 24B1 and first sides of the first vertical conductive lines 39A may be self-aligned in the third direction D3. First sides of the second cell isolation segments 24B2 and first sides of the second vertical conductive lines 39B may be self-aligned in the third direction D3.

As described above, the first and second vertical conductive lines 39A and 39B may be individual vertical conductive lines that fill the first and second vertical extension portions 32E1 and 32E2 of the first line-shape vertical opening 32L, respectively. The first and second vertical conductive lines 39A and 39B may be formed to be self-aligned to first sides of the second cell isolation segments 24B2. Since they are formed to be self-aligned to first sides of the second cell isolation segments 24B2, a sufficient gap between the neighboring first vertical conductive lines 39A and the second vertical conductive lines 39B may be secured, thereby reducing parasitic capacitance.

Before the first and second vertical conductive lines 39A and 39B are formed, an additional second bottom passivation layer BF21 may be formed on the second bottom passivation layer BF2. The additional second bottom passivation layer BF21 may include silicon oxide.

Before the first and second vertical conductive lines 39A and 39B are formed, first doped regions 37 may be formed. The first doped regions 37 may be formed in the first edge portion of the horizontal layers 14B. Forming the first doped regions 37 may include depositing polysilicon doped with an N-type impurity, performing a heat treatment, and removing the doped polysilicon. The first doped regions 37 may include an impurity diffused from the doped polysilicon. According to another embodiment of the present disclosure, the first doped regions 37 may be formed by a process of doping an impurity.

As described with reference to FIGS. 21A and 21B, a first contact node 38 may be further formed. The first contact node 38 may include doped polysilicon. The first doped region 37 may include an impurity diffused from the first contact node 38. A metal silicide layer may be further formed between the first and second vertical conductive lines 39A and 39B and the first contact node 38.

The first and second vertical conductive lines 39A and 39B may correspond to the first and second vertical conductive lines BLA and BLB described above with reference to FIGS. 28A to 28E.

After the first and second vertical conductive lines 39A and 39B are formed, a vertical isolation layer 39C may be formed between each pair of the first and second vertical conductive lines 39A and 39B to electrically isolate them. The vertical isolation layer 39C may include a dielectric material. The vertical isolation layer 39C may be disposed between the first vertical conductive lines 39A and the second vertical conductive lines 39B.

FIG. 45A is a plan view illustrating a structure with line-shape vertical openings 40 and storage openings 41 for describing a method for forming the line-shape vertical openings 40 and the storage openings 41. FIG. 45B is a cross-sectional view illustrating a structure taken along line A-A′ illustrated in FIG. 45A.

As illustrated in FIGS. 45A and 45B, a portion of the line-shape vertical sacrificial structure 29 may be removed to form the line-shape vertical openings 40 that expose second edge portions of the horizontal layers 14B. One side surfaces of the horizontal layers 14B may be exposed by the line-shape vertical openings 40. The line-shape vertical openings 40 may horizontally extend in the third direction D3.

Consequently, the line-shape vertical openings 40 may each have a structure formed by line patterning of the stack body SB.

A third passivation layer BF3 may be formed on the surface of the lower structure 11. The third passivation layer BF3 may include silicon oxide.

The second edge portions of the horizontal layers 14B may be horizontally recessed in the second direction D2. Accordingly, the horizontal layers may remain as indicated by reference numeral “HL”.

Remaining line-shape vertical sacrificial structure 29 may be selectively recessed to form a second capping layer 29C. Accordingly, the line-shape vertical openings 40 may horizontally extend. The second capping layer 29C may include silicon oxide, silicon nitride, or a combination thereof. As the second capping layer 29C is formed, the storage openings 41 may be formed. The storage openings 41 may be referred to as “capacitor openings”.

While the second capping layer 29C is formed, a lowermost-level dielectric layer 29L may be formed on the side surface of the first passivation layer BF1 as a portion of the line-shape vertical sacrificial structure 29 is removed.

Each of the horizontal layers HL may include a first edge and a second edge. The first edge may refer to a portion coupled to the first and second vertical conductive lines 39A and 39B, and the second edge may refer to a portion exposed by each of the storage openings 41.

The storage openings 41 may be disposed between the second dielectric layers 20. The second capping layers 29C may be disposed on the lower and upper portions of the horizontal layer HL, respectively. The second capping layers 29C may be disposed on the lower and upper end portions of the horizontal layer HL, respectively.

As described above, forming the horizontal layer HL and the storage openings 41 may include forming the line-shape vertical openings 40, recessing the horizontal layers 14B, and forming the second capping layer 29C.

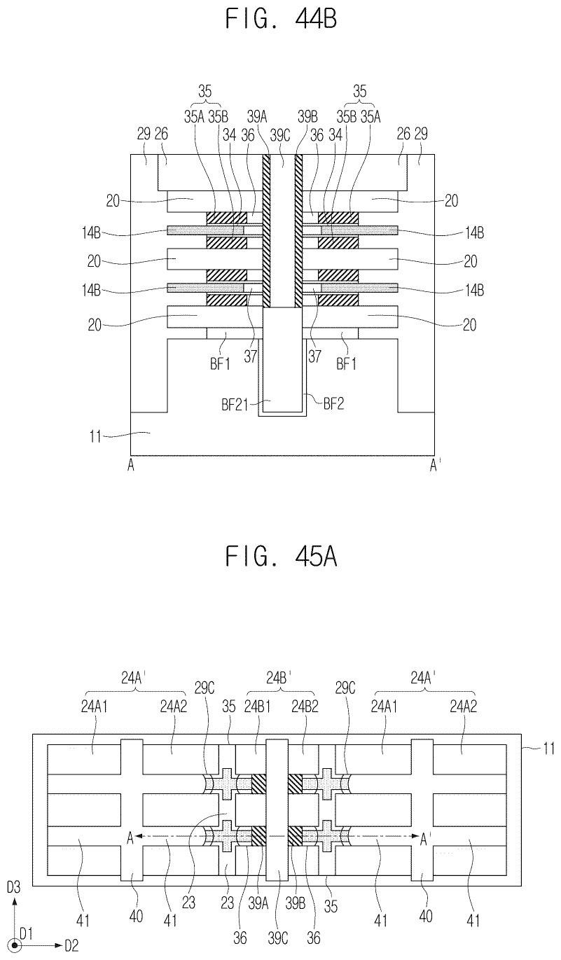

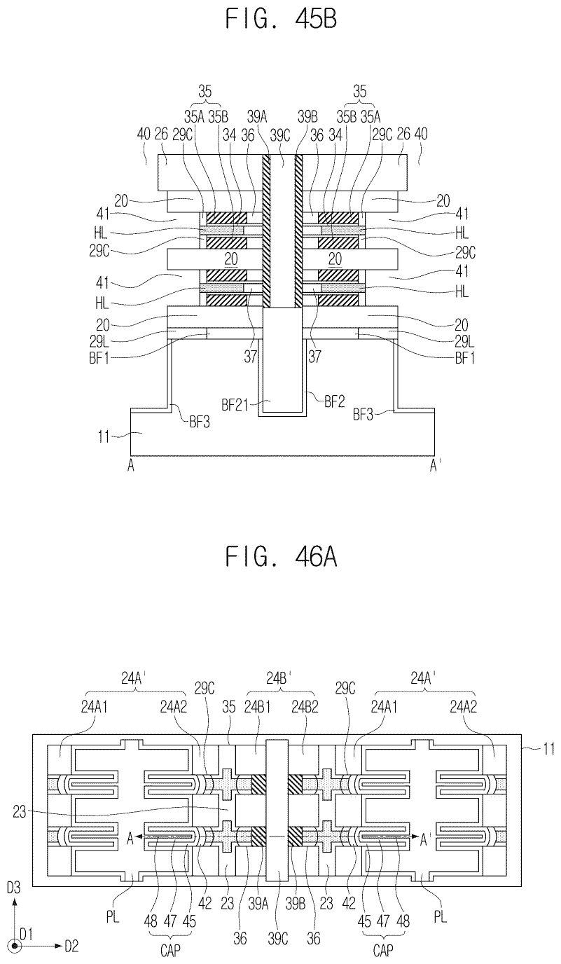

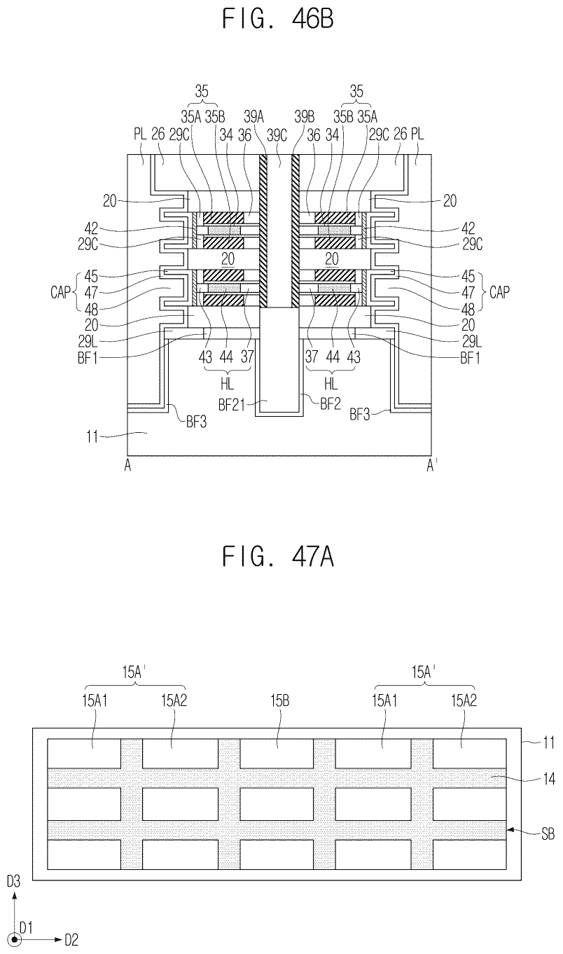

FIG. 46A is a plan view illustrating a structure with a second contact node 42 for describing a method for forming the second contact node 42. FIG. 46B is a cross-sectional view illustrating a structure taken along line A-A′ illustrated in FIG. 46A.

As illustrated in FIGS. 46A and 46B, a second doped region 43 may be formed in the second edge of the horizontal layer HL. Forming the second doped region 43 may include depositing polysilicon that is doped with an N-type impurity, performing a heat treatment, and removing the doped polysilicon. The second doped region 43 may include an impurity that is diffused from the doped polysilicon. According to another embodiment of the present disclosure, after the heat treatment, the doped polysilicon may remain.

Subsequently, the second contact node 42 may be formed on the second edge of the horizontal layer HL. The second contact node 42 may be formed also on the second capping layer 29C. The second contact node 42 may include doped polysilicon. The second doped region 43 may include an impurity that is diffused from the second contact node 42.

The horizontal layer HL may include the first doped region 37, the second doped region 43, and a channel 44 that are horizontally disposed in the second direction D2. The channel 44 may be defined between the first doped region 37 and the second doped region 43. The channel 44 may vertically overlap with the horizontal conductive line 35. As illustrated in FIGS. 1A to 1C, the horizontal layer HL may have a cross shape, and the channel 44 may also have a cross shape.

A first electrode 45 of the data storage element may be formed on the second contact node 42. The first electrode 45 may have a horizontally oriented cylindrical shape. The first electrodes 45 may be disposed in the storage openings 41. The first electrodes 45 disposed adjacent to each other in the second direction D2 may be spaced apart from each other by the line-shape vertical openings 40. The first electrodes 45 disposed adjacent to each other in the third direction D3 may be spaced apart from each other by the second cell isolation layers 24A.

Subsequently, as illustrated in FIGS. 25A and 25B, the second dielectric layers 20 may be horizontally recessed. Accordingly, the outer walls of the first electrodes 45 may be exposed. The recessed second dielectric layers 20 may correspond to the inter-cell dielectric layers IL described above with reference to FIG. 3B. While the second dielectric layers 20 may be horizontally recessed, portions of the cell isolation layers 24A′ and 24B′ may be horizontally recessed. Accordingly, the outer walls of the first electrodes 45 disposed adjacent to each other in the third direction D3 may be exposed. The first electrodes 45 may each have a semi-cylindrical shape.

A dielectric layer 47 and a second electrode 48 may be sequentially formed on the first electrode 45. The first electrode 45, the dielectric layer 47 and the second electrode 48 may become a data storage element CAP.

The first electrode 45 may include an inner space and a plurality of outer surfaces, and the inner space of the first electrode 45 may include a plurality of inner surfaces. The outer surfaces of the first electrode 45 may include a vertical outer surface and a plurality of horizontal outer surfaces. The vertical outer surface of the first electrode 45 may vertically extend in the first direction D1, and the horizontal outer surfaces of the first electrode 45 may horizontally extend in the second direction D2 or the third direction D3. The inner space of the first electrode 45 may be a three-dimensional space. The dielectric layer 47 may conformally cover the inner and outer surfaces of the first electrode 45. The second electrode 48 may be disposed in the inner space of the first electrode 45 on the dielectric layer 47. Some of the outer surfaces of the first electrode 45 may be electrically coupled to the second doped region 43 of the horizontal layer HL.

The first electrode 45 may have a cylindrical shape. The cylindrical shape of the first electrode 45 may include cylindrical inner surfaces and cylindrical outer surfaces. Some of the cylindrical outer surfaces of the first electrode 45 may be electrically coupled to the second doped region 43 of the horizontal layer HL. The dielectric layer 47 and the second electrode 48 may be disposed on the cylindrical inner surfaces of the first electrode 45.

The second electrode 48 may extend vertically in the first direction D1 and horizontally in the third direction D3.

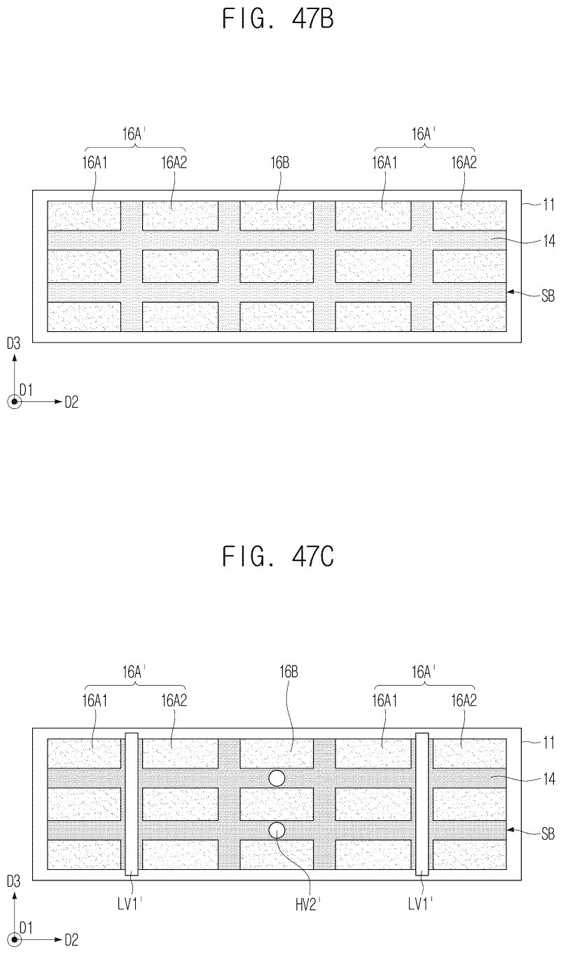

FIGS. 47A to 47C illustrate various views of a semiconductor device formed according to a method for fabricating the semiconductor device in accordance with an embodiment of the present disclosure. FIGS. 47A to 47C may represent a modified example of the sacrificial openings V1′ and V2′ described above with reference to FIGS. 7A to 7C. In addition, FIGS. 47A to 47C may represent a modified example of the sacrificial openings LV1′ and LV2′ described above with reference to FIGS. 31A to 31C.

FIG. 47A is a plan view illustrating a structure with a fourth layer 14 for describing a method for forming sacrificial isolation openings 15A′ and 15B.

Referring to FIGS. 5A, 5, 5C, 29A, 29B and 47A, a stack body SB may be formed over a lower structure 11. In the stack body SB, a plurality of sub-stacks may be alternately stacked. In each of the sub-stacks, a first layer 12A, a second layer 13, a third layer 12B, and a fourth layer 14 may be sequentially stacked. The first layer 12A and the third layer 12B may be formed of the same material and each include silicon germanium. The second layer 13 may include monocrystalline silicon. The fourth layer 14 may include monocrystalline silicon. The first layer 12A, the second layer 13, the third layer 12B, and the fourth layer 14 may be formed by epitaxial growth.

A portion of the stack body SB may be etched to form a plurality of sacrificial isolation openings 15A′ and 15B. The sacrificial isolation openings 15A′ and 15B, which are initial openings for cell isolation, may include large openings 15A′ and small openings 15B.

Each of the large openings 15A′ may include two large segments 15A1 and 15A2, and each of the small openings 15B may not include small segments. The large segments 15A1 and 15A2 and the small openings 15B may have the same size.

As described above, the large openings 15A′ of the sacrificial isolation openings may be formed by being divided into the large segments 15A1 and 15A2, and the small openings 15B may be formed in an undivided form in which segments are merged.

FIG. 47B is a plan view illustrating a structure with the fourth layer 14 for describing a method for forming sacrificial cell isolation layers 16A′ and 16B.

As illustrated in FIGS. 6A, 6B, 6C, 30A, 30B and 47B, the sacrificial cell isolation layers 16A′ and 16B may be formed to fill the sacrificial isolation openings 15A′ and 15B. The sacrificial cell isolation layers 16A′ and 16B may include first sacrificial cell isolation layers 16A′ and second sacrificial cell isolation layers 16B. The first sacrificial cell isolation layers 16A′ may fill the large openings 15A′, and the second sacrificial cell isolation layers 16B may fill the small openings 15B.

Each of the first sacrificial cell isolation layers 16A′ may include two first sacrificial segments 16A1 and 16A2, and each of the second sacrificial cell isolation layers 16B may not include segments.

FIG. 47C is a plan view illustrating a structure with the fourth layer 14 for describing a method for forming sacrificial openings LV1′ and HV2′.

As illustrated in FIGS. 7A, 7B, 7C, 31A, 31B, and 47C, a first hard mask layer HM1 may be formed on the stack body SB, the first sacrificial cell isolation layers 16A′, and the second sacrificial cell isolation layers 16B. The first hard mask layer HM1 may include silicon nitride.

Subsequently, a mask layer MK1 may be formed on the first hard mask layer HM1. The mask layer MK1, which is an etch mask layer, may include a hard mask material, photoresist, or a combination thereof. The mask layer MK1 may include line-shape opening patterns ML and hole-shape opening patterns MH. The line-shape opening patterns ML may extend in a third direction D3.

Subsequently, the line-shape opening patterns ML and the hole-shape opening patterns MH of the mask layer MK1 may be transferred to the first hard mask layer HM1 and the stack body SB. For example, the first hard mask layer HM1 may be etched using the mask layer MK1 as an etch barrier, and then the stack body SB may be etched using the first hard mask layer HM1 as an etch barrier. Accordingly, a plurality of line-shape sacrificial openings LV1′ and a plurality of hole-shape sacrificial openings HV2′ may be formed in the stack body SB. From a top view perspective, cross sections of the line-shape sacrificial openings LV1′ may be rectangles that extend lengthwise in the third direction D3.

The line-shape sacrificial openings LV1′ may be formed by etching the stack body SB between the first sacrificial segments 16A1 and 16A2 of the first sacrificial cell isolation layers 16A′. The line-shape sacrificial openings LV1′ may be disposed between the first sacrificial segments 16A1 and 16A2 disposed adjacent to each other in the second direction D2. The hole-shape sacrificial openings HV2′ may be formed by etching the stack body SB between the second sacrificial cell isolation layers 16B. The hole-shape sacrificial openings HV2′ may be disposed between the second sacrificial cell isolation layers 16B disposed adjacent to each other in the third direction D3.

The line-shape sacrificial openings LV1′ and the hole-shape sacrificial openings HV2′ may vertically extend in a first direction D1.

The line-shape sacrificial openings LV1′ and the first sacrificial segments 16A1 and 16A2 of the first sacrificial cell isolation layers 16A′ may not contact each other. The hole-shape sacrificial openings HV2′ and the second sacrificial cell isolation layers 16B may not contact each other.

As described above, line patterning and hole patterning using one mask layer MK1 may be simultaneously performed to form the line-shape sacrificial openings LV1′ and the hole-shape sacrificial openings HV2′.

Subsequently, a series of processes described with reference to FIGS. 8A to 26B may be performed.

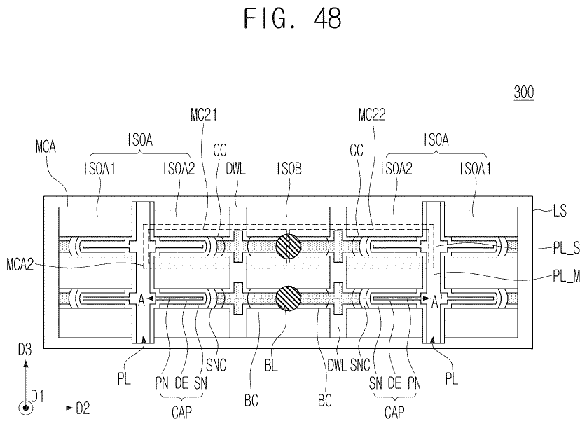

FIG. 48 is a schematic plan view illustrating a semiconductor device 300 in accordance with an embodiment of the present disclosure. The semiconductor device 300 illustrated in FIG. 48 may be formed using the processes described with reference to FIGS. 47A to 47C.

The semiconductor device 300 illustrated in FIG. 48 may be similar to the semiconductor device 100 illustrated in FIGS. 2, 3A, and 3B and the semiconductor device 200 illustrated in FIG. 28A. Detailed descriptions of overlapping components are provided with reference to FIGS. 2, 3A, 3B, 28A, and 28B.

As illustrated in FIG. 48, the semiconductor device 300 may include a memory cell array MCA. The memory cell array MCA may include a plurality of memory cells MC21 and MC22. The memory cells MC21 and MC22 may be the same as the memory cells MC illustrated in FIGS. 2, 3A, and 3B.

The memory cell array MCA may include a three-dimensional array of the memory cells MC21 and MC22. The three-dimensional array of the memory cells MC21 and MC22 may include a column array of the memory cells MC21 and MC22 and a row array of the memory cells MC21 and MC22. The column array of the memory cells MC21 and MC22 may include a plurality of memory cells MC21 and MC22 that are stacked in a first direction D1, and the row array of the memory cells MC21 and MC22 may include a plurality of memory cells MC21 and MC22 that are horizontally disposed in a second direction D2 and a third direction D3. The memory cell array MCA may include sub-memory cell arrays MCA2 disposed adjacent to one another in the second direction D2. The sub-memory cell arrays MCA2 may include a three-dimensional array of first memory cells MC21 and a three-dimensional array of second memory cells MC22.

Each of the first and second memory cells MC21 and MC22 may include a first conductive line BL, a horizontal layer HL, a second conductive line DWL, and a data storage element CAP. The horizontal layer HL may include a first doped region SR, a channel CH, and a second doped region DR. An inter-level dielectric layer GD may be disposed between the horizontal layer HL and the second conductive line DWL. The data storage element CAP may include a first electrode SN, a dielectric layer DE, and a second electrode PN. Each of the first and second memory cells MC21 and MC22 may further include a second contact node SNC between the horizontal layer HL and the data storage element CAP. Although not illustrated, each of the first and second memory cells MC21 and MC22 may further include a first contact node BLC between the horizontal layer HL and the first conductive line BL, as described above with reference to FIG. 1B. The second electrodes PN of the first and second memory cells MC21 and MC22 disposed adjacent in the second direction D2 may be merged with each other to form a common plate PL.

The common plate PL may include a sharing portion PL_S sharing the first memory cells MC21 disposed adjacent to each other in the second direction D2 and a merging portion PL_M disposed between first cell isolation layers ISOA. The common plate PL may have a cross shape extending in the third direction D3 by a combination of a plurality of sharing portions PL_S and a plurality of merging portions PL_M. The first cell isolation layers ISOA may be disposed between the data storage elements CAP in the third direction D3. Second cell isolation layers ISOB may be disposed between the first conductive lines BL in the third direction D3. The second conductive lines DWL may be disposed between the first cell isolation layers ISOA and the second cell isolation layers ISOB in the second direction D2. The first cell isolation layers ISOA may each have a larger size than the second cell isolation layers ISOB.

The first cell isolation layers ISOA and the second cell isolation layers ISOB may be disposed between the first memory cells MC21 disposed adjacent to each other in the third direction D3. The first cell isolation layers ISOA may be disposed between the data storage elements CAP, and the second cell isolation layers ISOB may be disposed between the first conductive lines BL. Each of the first cell isolation layers ISOA may include first cell isolation segments ISOA1 and ISOA2. Each of the second cell isolation layers ISOB may include second cell isolation segments ISOB1 and ISOB2. The first electrodes SN of the data storage elements CAP may be disposed between the first cell isolation segments ISOA2. The first conductive lines BL may be disposed between the second cell isolation segments ISOB1.

The first and second cell isolation layers ISOA and ISOB may be disposed between the second memory cells MC22 disposed adjacent to each other in the third direction D3. The first cell isolation layers ISOA may be disposed between the data storage elements CAP. The second cell isolation layers ISOB may be disposed between the first conductive lines BL. Each of the first cell isolation layers ISOA may include first cell isolation segments ISOA1 and ISOA2. Each of the second cell isolation layers ISOB may include second cell isolation segments ISOB1 and ISOB2. The first electrodes SN of the data storage elements CAP may be disposed between the first cell isolation segments ISOA2. The first conductive lines BL may be disposed between the second cell isolation segments ISOB1.

The three-dimensional array of the first memory cells MC21 may share the first conductive line BL, and the three-dimensional array of the second memory cells MC22 may also share the first conductive line BL. Thus, the first memory cell MC21 and the second memory cell MC22 disposed adjacent to each other in the second direction D2 may share one first conductive line BL. Hence, the first conductive line BL may be referred to as a “common first conductive line BL”.

The first conductive lines BL may be formed by a hole patterning method. For example, as described with reference to FIGS. 7A and 47C, the hole-shape sacrificial openings V2′ and HV2′ may be applied.

The semiconductor device illustrated in FIGS. 47A to 47C may also form a first conductive line using the hole patterning method.

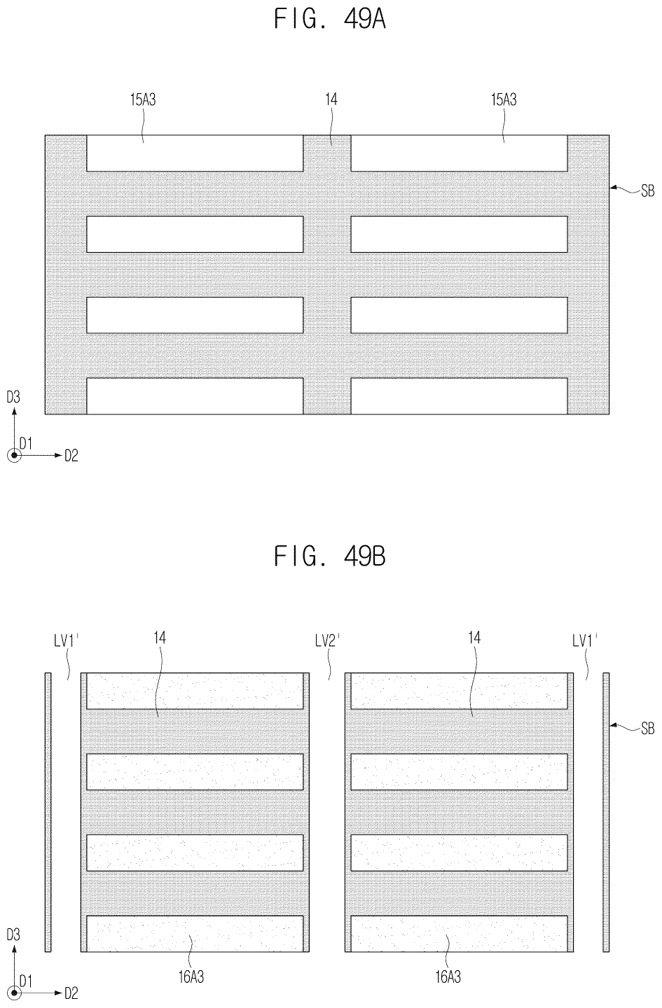

FIGS. 49A and 49B illustrate various views of a semiconductor device formed according to a method for fabricating the semiconductor device in accordance with an embodiment of the present disclosure. FIGS. 49A and 49B may represent another embodiment of the line-shape sacrificial openings LV1′ and LV2′ described with reference to FIGS. 29A to 31C.

FIG. 49A is a plan view illustrating a structure with a fourth layer 14 for describing a method for forming sacrificial isolation openings 15A3.

Referring to FIGS. 29A, 29B and 49A, a stack body SB may be formed over a lower structure 11. The stack body SB may have a plurality of sub-stacks that are alternately stacked on one another. In each of the sub-stacks, a first layer 12A, a second layer 13, a third layer 12B and a fourth layer 14 may be sequentially stacked. The first layer 12A and the third layer 12B may be formed of the same material and each include silicon germanium. The second layer 13 may include monocrystalline silicon. The fourth layer 14 may include monocrystalline silicon. The first layer 12A, the second layer 13, the third layer 12B and the fourth layer 14 may be formed by epitaxial growth.

A portion of the stack body SB may be etched to form a plurality of sacrificial isolation openings 15A3. The sacrificial isolation openings 15A3, which are initial openings for cell isolation, may have the same size.

FIG. 49B is a plan view illustrating a structure with the fourth layer 14 for describing a method for forming line-shape sacrificial openings LV1′ and LV2′.

As illustrated in FIGS. 30A, 30B and 49B, sacrificial cell isolation layers 16A3 may be formed to fill the sacrificial isolation openings 15A3. The sacrificial cell isolation layers 16A3 may have the same size.

Subsequently, a portion of the stack body SB may be etched. Accordingly, a plurality of line-shape sacrificial openings LV1′ and LV2′ may be formed between the sacrificial cell isolation layers 16A3. The line-shape sacrificial openings LV1′ and LV2′ may include a first line-shape sacrificial opening LV1′ and a second line-shape sacrificial opening LV2′. From a top view perspective, the first line-shape sacrificial opening LV1′ and the second line-shape sacrificial opening LV2′ may be line-shape openings extending in a third direction D3. The first line-shape sacrificial opening LV1′ and the second line-shape sacrificial opening LV2′ may vertically extend in a first direction D1. The sacrificial cell isolation layers 16A3 may be disposed between the first line-shape sacrificial opening LV1′ and the second line-shape sacrificial opening LV2′ in a second direction D2. From a top view perspective, cross sections of the first line-shape sacrificial opening LV1′ and the second line-shape sacrificial opening LV2′ may each have a rectangular shape. According to another embodiment of the present disclosure, the cross sections of the first line-shape sacrificial opening LV1′ and the second line-shape sacrificial opening LV2′ may each have a circular shape or an oval shape. The first line-shape sacrificial opening LV1′ and the second line-shape sacrificial opening LV2′ may have a width in the second direction D2 smaller than a width in the third direction D3.

Data storage elements may be formed using the first line-shape sacrificial opening LV1′, and a vertical conductive line may be formed using the second line-shape sacrificial opening LV2′.

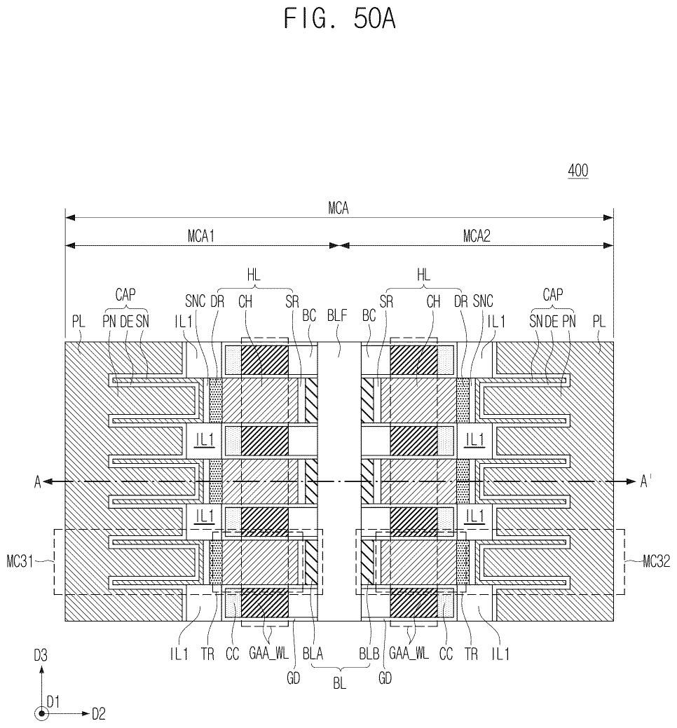

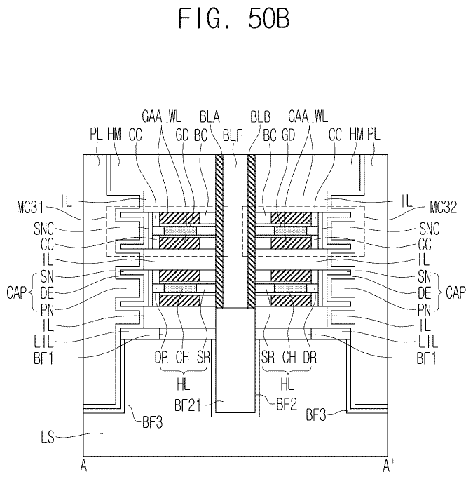

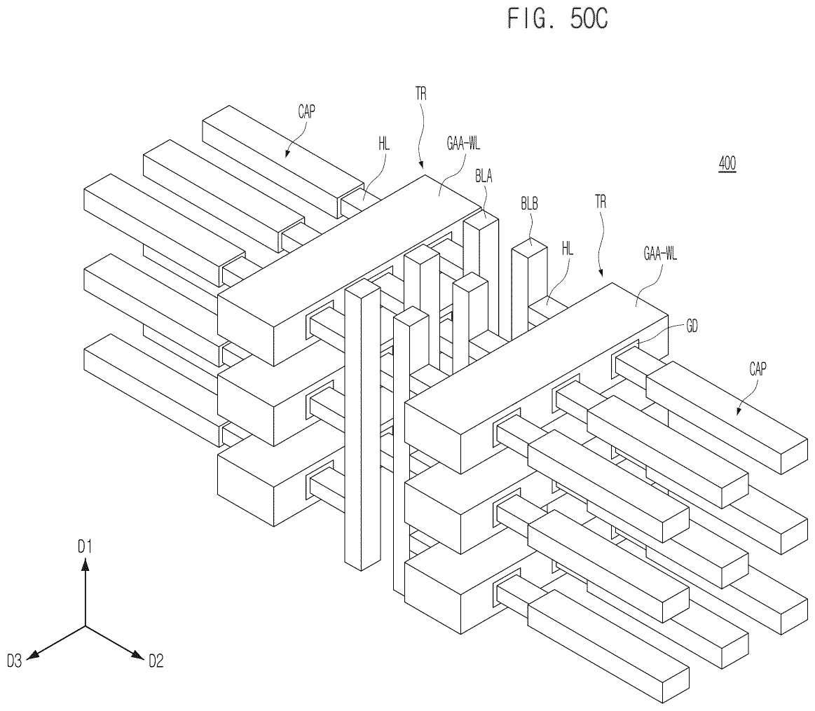

FIG. 50A is a schematic plan view illustrating a semiconductor device 400 in accordance with an embodiment of the present disclosure. FIG. 50B is a cross-sectional view illustrating the semiconductor device 400 taken along line A-A′ illustrated in FIG. 50A. FIG. 50C is a schematic perspective view illustrating the semiconductor device 400 illustrated in FIG. 50A. The semiconductor device 400 illustrated in FIGS. 50A to 50C may be formed by the processes described with reference to FIGS. 49A to 49C.

Referring to FIGS. 50A to 50C, the semiconductor device 400 may include a memory cell array MCA, and the memory cell array MCA may include a three-dimensional array of memory cells MC31 and MC32. The memory cell array MCA may include a first sub-cell array MCA1 and a second sub-cell array MCA2 positioned adjacent to each other in the second direction D2.

The memory cell array MCA may include a plurality of memory cells MC31 vertically stacked in a first direction D1. The memory cell array MCA may also include a plurality of memory cells MC32 vertically stacked in a first direction D1. The memory cells MC31 and MC32 may have a similar configuration to the memory cell MC described with reference to FIGS. 1A and 1B. The memory cell array MCA may include the plurality of memory cells MC31 and MC32 horizontally disposed in a second direction D2. The memory cell array MCA may include the plurality of memory cells MC31 and MC32 horizontally disposed in a third direction D3. The memory cell array MCA may include a plurality of first conductive lines BL, and each of the first conductive lines BL may include a first vertical conductive line BLA and a second vertical conductive line BLB. A bottom portion of the first vertical conductive line BLA and a bottom portion of the second vertical conductive line BLB may be spaced apart from each other.

The first memory cell MC31 of the first sub-cell array MCA1 may include the first vertical conductive line BLA, a switching element TR, and a data storage element CAP. The switching element TR may include a second conductive line GAA_WL and a horizontal layer HL. The second memory cell MC32 of the second sub-cell array MCA2 may include the second vertical conductive line BLB, a switching element TR, and a data storage element CAP. The switching element TR may include a second conductive line GAA_WL and a horizontal layer HL. The second conductive line GAA_WL may have a gate all around structure (GAA). For example, the second conductive line GAA_WL may surround the horizontal layers HL disposed at the same horizontal level and extend in the third direction D3.

The first conductive line BL may vertically extend in the first direction D1, the horizontal layer HL may extend in the second direction D2, and the second conductive line GAA_WL may horizontally extend in the third direction D3.

First inter-cell dielectric layers IL1 may be disposed between the data storage elements CAP which are disposed adjacent to each other in the third direction D3. Second inter-cell dielectric layers IL may be disposed between the second conductive lines GAA_WL which are stacked in the first direction D1.

The memory cells MC31 and MC32 may further include a contact node SNC. The contact node SNC may be disposed between the horizontal layer HL and a first electrode SN. The contact node SNC may include doped polysilicon, and a second doped region DR may include an impurity diffused from the contact node SNC.

The memory cells MC31 and MC32 may each further include a first capping layer BC and a second capping layer CC. The first vertical conductive lines BLA disposed adjacent to each other in the third direction D3 may be formed by being self-aligned by the first capping layers BC. The second vertical conductive lines BLB disposed adjacent to each other in the third direction D3 may be formed by being self-aligned by the first capping layers BC.

The memory cell array MCA may include a hard mask layer HM disposed at a level higher than the uppermost-level second conductive line GAA_WL.

The memory cell array MCA may include a plurality of bottom passivation layers BF2, BF21, and BF3.

A vertical isolation layer BLF may be disposed between the first vertical conductive line BLA and the second vertical conductive line BLB of the first conductive lines BL. The vertical isolation layer BLF may include a dielectric material.

The horizontal layers HL of the switching elements TR horizontally disposed in the third direction D3 may share one second conductive line GAA_WL. The horizontal layers HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line GAA_WL.

Second electrodes PN of the data storage elements CAP may be coupled to a common plate PL.

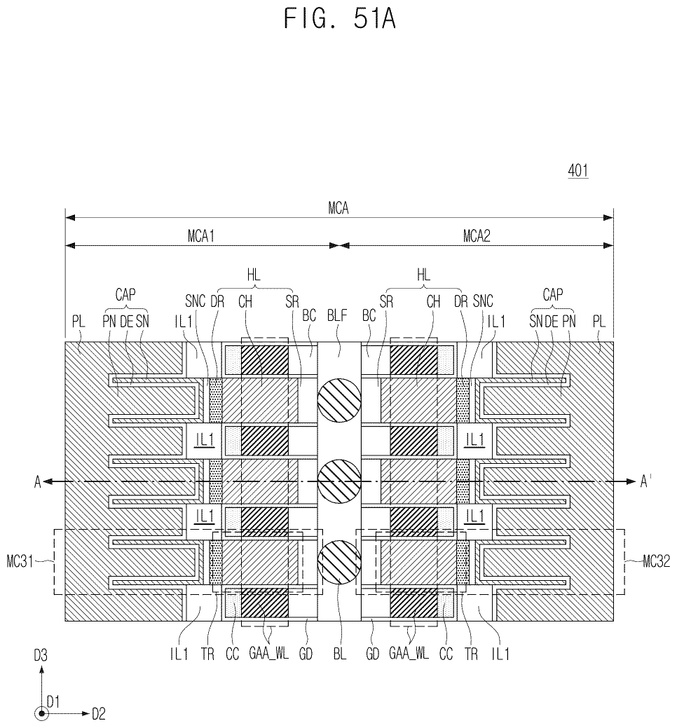

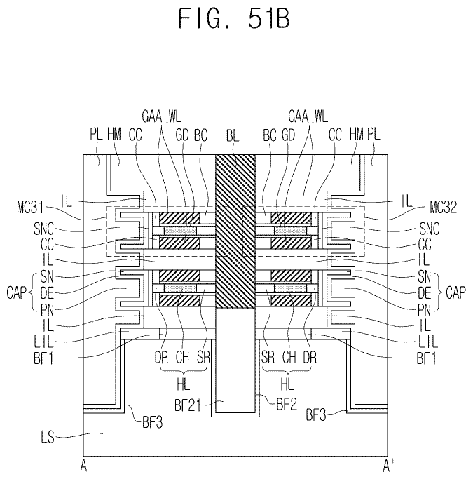

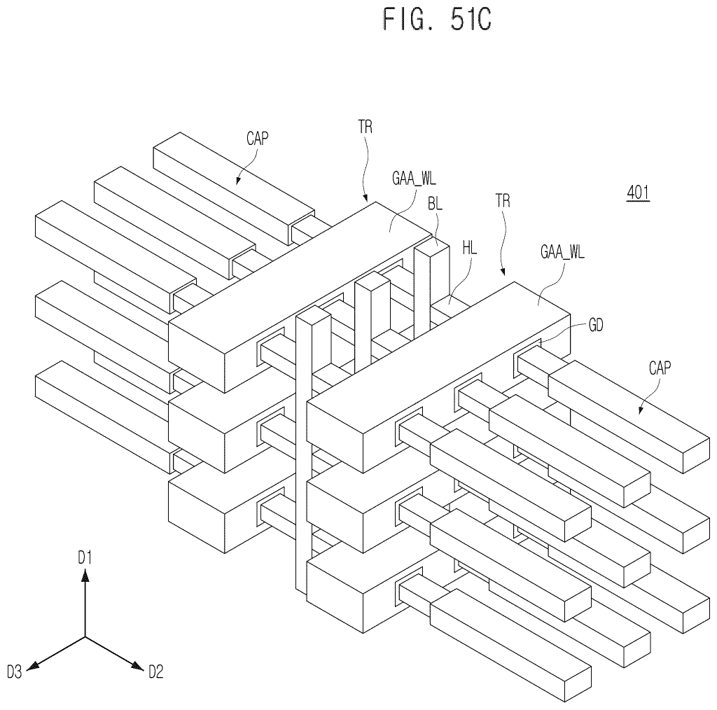

FIG. 51A is a schematic plan view illustrating a semiconductor device 401 in accordance with an embodiment of the present disclosure. FIG. 51B is a cross-sectional view illustrating the semiconductor device 401 taken along line A-A′ illustrated in FIG. 51A. FIG. 51C is a schematic perspective view illustrating the semiconductor device 401 illustrated in FIG. 51A. The semiconductor device 401 illustrated in FIGS. 51A to 51C may be formed by the processes described with reference to FIGS. 49A to 49C.

Referring to FIGS. 51A to 51C, the semiconductor device 401 may include a memory cell array MCA, and the memory cell array MCA may include a three-dimensional array of memory cells MC31 and MC32. The memory cell array MCA may include a first sub-cell array MCA1 and a second sub-cell array MCA2 positioned adjacent to each other in the second direction D2.

The memory cell array MCA may include a plurality of memory cells MC31 vertically stacked in a first direction D1. The memory cell array MCA may include a plurality of memory cells MC32 vertically stacked in a first direction D1. The memory cells MC31 and MC32 may have a similar configuration to the memory cell MC described with reference to FIGS. 1A and 1B. The memory cell array MCA may include the plurality of memory cells MC31 and MC32 horizontally disposed in a second direction D2. The memory cell array MCA may include the plurality of memory cells MC31 and MC32 horizontally disposed in a third direction D3. The memory cell array MCA may include a plurality of first conductive lines BL. The first sub-cell array MCA1 and the second sub-cell array MCA2 may share one first conductive line BL.

The first memory cell MC31 of the first sub-cell array MCA1 may include the first conductive line BL, a switching element TR, and a data storage element CAP. The switching element TR may include a second conductive line GAA_WL and a horizontal layer HL. The second memory cell MC32 of the second sub-cell array MCA2 may include the first conductive line BL, a switching element TR, and a data storage element CAP. The switching element TR may include a second conductive line GAA_WL and a horizontal layer HL. The second conductive line GAA_WL may have a gate all around structure (GAA). For example, the second conductive line GAA_WL may surround the horizontal layers HL disposed at the same horizontal level and extend in the third direction D3.

The first conductive line BL may vertically extend in the first direction D1, the horizontal layer HL may extend in the second direction D2, and the second conductive line GAA_WL may horizontally extend in the third direction D3.

First inter-cell dielectric layers IL1 may be disposed between the data storage elements CAP which are disposed adjacent to each other in the third direction D3. Second inter-cell dielectric layers IL may be disposed between the second conductive lines GAA_WL which are stacked in the first direction D1.

The memory cells MC31 and MC32 may further include a contact node SNC. The contact node SNC may be disposed between the horizontal layer HL and a first electrode SN. The contact node SNC may include doped polysilicon, and a second doped region DR may include an impurity diffused from the contact node SNC.

The memory cells MC31 and MC32 may each further include a first capping layer BC and a second capping layer CC.

The memory cell array MCA may include a hard mask layer HM disposed at a level higher than the uppermost-level second conductive line GAA_WL.

The memory cell array MCA may include a plurality of bottom passivation layers BF2, BF21, and BF3.

A vertical isolation layer BLF may be disposed between the first conductive lines BL. The vertical isolation layer BLF may include a dielectric material. The first conductive lines BL disposed adjacent to each other in the third direction D3 may be spaced apart from each other with the vertical isolation layer BLF interposed therebetween.

The horizontal layers HL of the switching elements TR horizontally disposed in the third direction D3 may share one second conductive line GAA_WL. The horizontal layers HL of the switching elements TR horizontally disposed in the second direction D2 may share one first conductive line BL. The horizontal layers HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line GAA_WL.

Second electrodes PN of the data storage elements CAP may be coupled to a common plate PL.

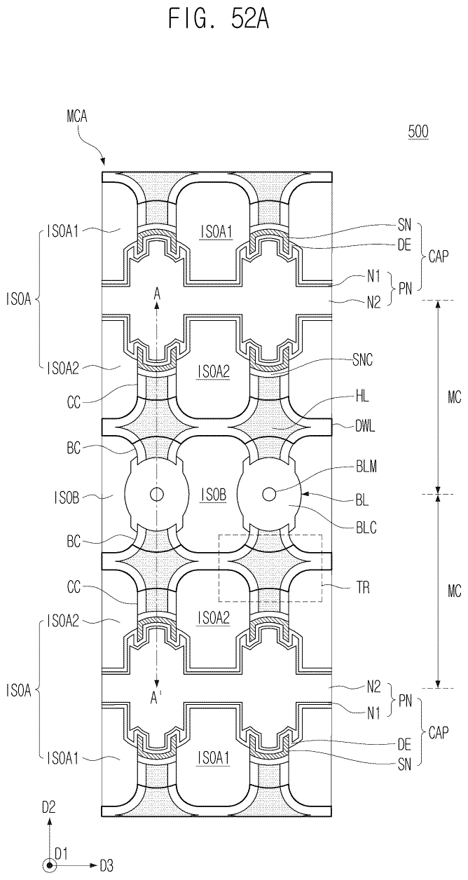

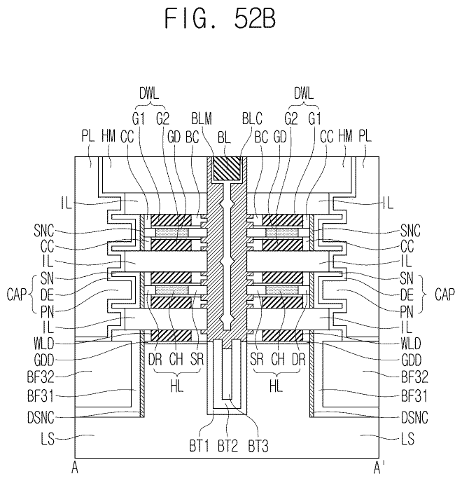

FIG. 52A is a schematic plan view illustrating a semiconductor device 500 in accordance with an embodiment of the present disclosure. FIG. 52B is a schematic cross-sectional view illustrating the semiconductor device 500 taken along line A-A′ illustrated in FIG. 52A. The semiconductor device 500 illustrated in FIGS. 52A and 52B may be similar to the semiconductor device 100 illustrated in FIGS. 2, 3A, and 3B. Hereinafter, detailed descriptions of overlapping components are omitted.

Referring to FIGS. 52A and 52B, the semiconductor device 500 may include a memory cell array MCA. The memory cell array MCA may include a plurality of memory cells MC. Each of the memory cells MC may include a first conductive line BL, a switching element TR, and a data storage element CAP. The first conductive line BL, the switching element TR, and the data storage element CAP may be formed using a line patterning method, a hole patterning method, or a combination thereof, as referenced in the above-described embodiments.

The memory cell array MCA may include a three-dimensional array of the memory cells MC. The memory cell array MCA may have a mirror-type structure in which two memory cells MC share the first conductive line BL.

Inter-cell dielectric layers IL may be disposed between the memory cells MC that are stacked in a first direction D1. Cell isolation layers ISOA and ISOB may be disposed between the memory cells MC disposed adjacent to each other in a third direction D3. The cell isolation layers ISOA and ISOB may include first cell isolation layers ISOA and second cell isolation layers ISOB. The first and second cell isolation layers ISOA and ISOB may vertically extend in the first direction D1. The first and second cell isolation layers ISOA and ISOB may have a pillar structure vertically extending in the first direction D1. The first and second cell isolation layers ISOA and ISOB may be alternately and repeatedly disposed in a second direction D2. The first cell isolation layers ISOA may be disposed between the data storage elements CAP in the third direction D3. The second cell isolation layers ISOB may be disposed between the first conductive lines BL in the third direction D3. Second conductive lines DWL may be disposed between the first cell isolation layers ISOA and the second cell isolation layers ISOB in the second direction D2.

The memory cell array MCA may be disposed over a lower structure LS.

The memory cell array MCA may include a plurality of second conductive lines DWL that are vertically stacked in the first direction D1. The memory cell array MCA may include a plurality of horizontal layers HL that are vertically stacked in the first direction D1. The memory cell array MCA may include a plurality of data storage elements CAP that are vertically stacked in the first direction D1. The memory cell array MCA may include a plurality of first conductive lines BL that are spaced apart from one another in the third direction D3.

Each of the second conductive lines DWL may include a channel overlapping portion WLP as illustrated in FIG. 1C. The channel overlapping portion WLP may have a cross shape or a rhombus shape. The channel overlapping portion WLP may fully overlap with a channel CH. The second conductive line DWL extending in the third direction D3 may include a plurality of channel overlapping portions WLP. As the channel overlapping portions WLP and channel non-overlapping portions (reference numeral omitted) are alternately repeated in the third direction D3, the second conductive line DWL may have notch-shape sidewalls. The notch-shape sidewalls of the second conductive line DWL may be asymmetrical to each other.

Dummy conductive lines WLD and dummy dielectric layers GDD may be disposed between a lowermost second conductive line DWL among the plurality of second conductive lines DWL and the lower structure LS. First passivation layer stacks BT1, BT2, and BT3 may be disposed between the first conductive line BL and the lower structure LS. The first passivation layer stacks BT1, BT2, and BT3 may include silicon oxide, silicon nitride, and silicon oxide, respectively. Second passivation layer stacks BF31 and BF32 may be disposed between the data storage element CAP and the lower structure LS. The second passivation layer stacks BF31 and BF32 may include silicon oxide and silicon nitride, respectively.

A first contact node BLC may vertically extend in the first direction D1 over the lower structure LS. Horizontal layers HL may extend in the second direction D2 that intersects with the first direction D1. The second conductive lines DWL may extend in the third direction D3 that intersects with the first direction D1 and the second direction D2. A barrier metal BLM may be formed on the first contact node BLC, and the first conductive line BL may be formed on the barrier metal BLM. The first contact node BLC may include doped polysilicon, and the barrier metal BLM may include a titanium/titanium nitride stack.

From a top view perspective, the horizontal layers HL may each have a cross shape or rhombus shape. According to another embodiment of the present disclosure, the side surfaces of the horizontal layer HL may have a bent shape or a rounded shape. As illustrated in FIG. 1B, the horizontal layer HL may include the channel CH, a first doped region SR between the channel CH and the first conductive line BL, and a second doped region DR between the channel CH and the data storage element CAP.

A first capping layer BC may be disposed between the second conductive line DWL and the first conductive line BL. A second capping layer CC may be disposed between the second conductive line DWL and a first electrode SN of the data storage element CAP. The first capping layer BC may be disposed between an upper horizontal line G1 and the first conductive line BL. In addition, the first capping layer BC may be disposed between a lower horizontal line G2 and the first conductive line BL. The second capping layer CC may be disposed between the upper horizontal line G1 and the first electrode SN of the data storage element CAP. In addition, the second capping layer CC may be disposed between the lower horizontal line G2 and the first electrode SN of the data storage element CAP. One memory cell MC may include a pair of first capping layers BC and a pair of second capping layers CC.

The first and second capping layers BC and CC may each include a dielectric material. The first and second capping layers BC and CC may each include silicon oxide, silicon nitride, silicon carbon oxide, an air gap, or a combination thereof. The first capping layer BC may include silicon oxide, and the second capping layer CC may include a stack of silicon oxide and silicon nitride.

The horizontal layers HL of switching elements TR horizontally disposed in the third direction D3 may share one second conductive line DWL. The horizontal layers HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line DWL.

The first cell isolation layers ISOA may be disposed between the first electrodes SN of the data storage elements CAP in the third direction D3. The first electrodes SN may be isolated from one another by the first cell isolation layers ISOA. The second electrodes PN of the data storage elements CAP may be coupled to a common plate PL.

Portions of the second electrodes PN may divide the first cell isolation layer ISOA. The second electrodes PN of the data storage elements CAP may be merged to become the common plate PL. The second electrodes PN of the data storage elements CAP horizontally disposed in the third direction D3 may be merged with each other. The second electrodes PN of the data storage elements CAP vertically disposed in the first direction D1 may be merged with each other. The common plate PL may horizontally extend in the third direction D3 and vertically extend in the first direction D1. The common plate PL may have a cross shape extending in the third direction D3. The first cell isolation layers ISOA may be divided into two first cell isolation segments ISOA1 and ISOA2 by the common plate PL. The first cell isolation segments ISOA1 and ISOA2 may each have the same size or a smaller size than the second cell isolation layers ISOB. The first electrodes SN of the data storage element CAP may be disposed between the first cell isolation segments ISOA1 in the third direction D3. The first electrodes SN of the data storage element CAP may be disposed between the first cell isolation segments ISOA2 in the third direction D3.

The first cell isolation layers ISOA may be disposed between the data storage elements CAP in the third direction D3. The second cell isolation layers ISOB may be disposed between the first conductive be disposed between the first cell isolation layers ISOA and the second cell isolation layers ISOB in the second direction D2. The first cell isolation layers ISOA may each have a larger size than the second cell isolation layers ISOB.

The lower structure LS may include a semiconductor substrate, a metal interconnection structure, a dielectric structure, a conductive structure, a bonding pad structure, another memory, or a peripheral circuit portion.

The second electrodes PN of data storage element CAP may include a stack of metal nitride liner N1 and polysilicon layer N2.

According to various embodiments of the present disclosure, it is possible to improve a yield because a line patterning method is applied to form a three-dimensional data storage element.

While the embodiments of the present disclosure have been illustrated and described with respect to specific embodiments and drawings, the disclosed embodiments are not intended to be restrictive. Further, it is noted that the embodiments of the present disclosure may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A method for fabricating a semiconductor device, the method comprising:
forming a cell mold in which a plurality of mold layers are stacked, over a lower structure;
forming a line-shape vertical opening in the cell mold, which is vertically oriented in a stack direction of the cell mold;
forming a storage opening that horizontally extends from the line-shape vertical opening; and
forming a data storage element in the storage opening.

2. The method of claim 1, wherein forming the line-shape vertical opening includes:
forming a mask layer having a line-shape opening pattern defined on the cell mold;
forming a line-shape sacrificial opening by etching the cell mold by using the mask layer as an etch barrier;
forming a sacrificial structure that fills the line-shape sacrificial opening; and
forming the line-shape vertical opening by removing the sacrificial structure.

3. The method of claim 1, wherein forming the storage opening includes horizontally recessing the mold layers from the line-shape vertical opening.

4. The method of claim 1, wherein forming the data storage element includes:
forming a first electrode on inner surfaces of the storage opening;
forming a dielectric layer on the first electrode; and
forming a second electrode that fills the storage opening on the dielectric layer.

5. The method of claim 1, wherein the first electrode includes a cylindrical shape.

6. The method of claim 1, wherein the data storage element includes a capacitor.

7. The method of claim 1, wherein the mold layers each include a stack of sacrificial layers and semiconductor layers, and the semiconductor layers each include monocrystalline silicon or an oxide semiconductor material.

8. The method of claim 1, further comprising forming a contact node on an inner surface of the storage opening, before forming the data storage element.

9. The method of claim 1, further comprising:
forming a switching element including horizontal conductive lines in the cell mold; and
forming a vertical conductive line coupled to the switching element,
after forming the cell mold.

10. The method of claim 9, wherein
the mold layers each include a stack of a first sacrificial layer, a semiconductor layer, and a second sacrificial layer, and
forming the switching element includes:
forming a hole-shape vertical opening by etching the cell mold; and
replacing portions of the first and second sacrificial layers from the hole-shape vertical opening with the respective horizontal conductive lines.

11. A method for fabricating a semiconductor device, the method comprising:
forming a cell mold in which a first sacrificial layer, a semiconductor layer and a second sacrificial layer are sequentially stacked, over a lower structure;
forming a line-shape vertical opening, which is vertically oriented in a stack direction of the cell mold, by removing a first part of the cell mold;
forming a hole-shape vertical opening, which is vertically oriented in the stack direction of the cell mold, by removing a second part of the cell mold;
forming a switching element that is horizontally oriented from the hole-shape vertical opening;
forming a vertical conducive line coupled to the switching element in the hole-shape vertical opening;
forming a storage opening that horizontally extends from the line-shape vertical opening; and
forming a data storage element in the storage opening.

12. The method of claim 11, wherein forming the line-shape vertical opening includes:
forming a mask layer having a line-shape opening pattern defined on the cell mold;
forming a line-shape sacrificial opening by etching the first part of the cell mold by using the mask layer as an etch barrier;
forming a sacrificial structure that fills the line-shape sacrificial opening; and
forming the line-shape vertical opening by removing the sacrificial structure.

13. The method of claim 11, wherein
forming the storage opening includes horizontally recessing the first sacrificial layer, the semiconductor layer and the second sacrificial layer from the line-shape vertical opening, and
wherein the recessed semiconductor layer forms a horizontal layer, and the recessed first and second sacrificial layers form a capping layer.

14. The method of claim 11, wherein forming the data storage element includes:
forming a first electrode on inner surfaces of the storage opening;
forming a dielectric layer on the first electrode; and
forming a second electrode that fills the storage opening on the dielectric layer.

15. The method of claim 11, wherein the semiconductor layer includes monocrystalline silicon or an oxide semiconductor material.

16. The method of claim 11, further comprising forming a contact node on an inner surface of the storage opening, before forming the data storage element.

17. The method of claim 11, wherein forming the line-shape vertical opening and forming the hole-shape vertical opening include:
forming a mask layer having a line-shape opening pattern and a hole-shape opening pattern defined on the cell mold;
forming a line-shape sacrificial opening and a hole-shape sacrificial opening by etching the first and second parts of the cell mold by using the mask layer as an etch barrier;
forming a line-shape sacrificial structure and a hole-shape sacrificial structure that fill the line-shape sacrificial opening and the hole-shape sacrificial opening, respectively;
forming the line-shape vertical opening by removing the line-shape sacrificial structure; and
forming the hole-shape vertical opening by removing the hole-shape sacrificial structure.
